(19) United States
(12) Patent Application Publication
(10) Pub. No.: US 2022/0327370 A1
(43) Pub. Date: Oct. 13, 2022

(54) Hybrid Low Power Analog to Digital Converter (ADC) Based Artificial Neural Network (ANN) with Analog Based Multiplication and Addition

(71) Applicant: SigmaSense, LLC., Wilmington, DE (US)

(72) Inventor: Phuong Huynh, Fairfax, VA (US)

(73) Assignee: SigmaSense, LLC., Wilmington, DE (US)

(21) Appl. No.: 17/227,694

(22) Filed: Apr. 12, 2021

(51) Int. Cl. G06N 3/063; G06N 3/04; H03M 3/00; H03M 1/66; H03M 1/34; H03M 1/20

(52) U.S. Cl. CPC G06N 3/0635; G06N 3/0481; H03M 3/50; H03M 3/458; H03M 1/662; H03M 1/34; H03M 1/20

(57) ABSTRACT

An Artificial Neural Network (ANN) processing system includes artificial neurons (processing elements) and an analog to digital converter (ADC). An artificial neuron includes a digital to analog converter (DAC) and a low pass filter (LPF) configured to generate a first filtered analog current signal. Also, the artificial neuron includes a delta-sigma DAC configured to generate an M-bit current signal based on a digital weight value. The artificial neuron also includes a multiplier configured to generate a first output current source signal based on the first filtered analog current signal and the M-bit current signal. The ADC is operably coupled to a common node via a single line and configured to generate a digital output signal based on an input voltage of the ADC. The digital output signal is representative of a summation of output analog current signals at a common node to which the ADC is operably coupled.

### CROSS REFERENCE TO RELATED PATENTS/PATENT APPLICATIONS

### Incorporation by Reference

The U.S. Utility application Ser. No. 17/132,241, “Single-ended direct interface dual DAC feedback photo-diode sensor,” filed Dec. 23, 2020, pending, is hereby incorporated herein by reference in its entirety and made part of the present U.S. Utility Patent Application for all purposes. Also, the U.S. Utility application Ser. No. 17/132,241, “Single-ended direct interface dual DAC feedback photo-diode sensor,” filed Dec. 23, 2020, pending, claims priority pursuant to 35 U.S.C. § 120 as a continuation-in-part (CIP) of U.S. Utility application Ser. No. 17/078,187, entitled “High Resolution Analog to Digital Converter (ADC) with Improved Bandwidth,” filed Oct. 23, 2020, pending, which claims priority pursuant to 35 U.S.C. § 120 as a continuation-in-part (CIP) of U.S. Utility application Ser. No. 16/678,793, entitled “Current Operative Analog to Digital Converter (ADC),” filed Nov. 8, 2019, now issued as U.S. Pat. No. 10,862,492 on Dec. 8, 2020, all of which are also hereby incorporated herein by reference in their entirety and made part of the present U.S. Utility Patent Application for all purposes.

### STATEMENT REGARDING FEDERALLY SPONSORED RESEARCH OR DEVELOPMENT

Not Applicable.

### INCORPORATION-BY-REFERENCE OF MATERIAL SUBMITTED ON A COMPACT DISC

Not Applicable.

### BACKGROUND OF THE INVENTION

### Technical Field of the Invention

This invention relates generally to analog to data communication systems and more particularly to sensed data collection and/or communication.

### Description of Related Art

Within many electrical and electronic systems, conversion of signals between the analog domain and the digital domain, and vice versa, is performed. For example, sensors may be implemented to detect one or more conditions such as environmental conditions, operating conditions, device conditions, etc. Sensors are used in a wide variety of applications ranging from in-home automation, to industrial systems, to health care, to transportation, and so on. For example, sensors are placed in bodies, automobiles, airplanes, boats, ships, trucks, motorcycles, cell phones, televisions, touch-screens, industrial plants, appliances, motors, checkout counters, etc. for the variety of applications.

In general, a sensor converts a physical quantity into an electrical or optical signal. For example, a sensor converts a physical phenomenon, such as a biological condition, a chemical condition, an electric condition, an electromagnetic condition, a temperature, a magnetic condition, mechanical motion (position, velocity, acceleration, force, pressure), an optical condition, and/or a radioactivity condition, into an electrical signal.

A sensor includes a transducer, which functions to convert one form of energy (e.g., force) into another form of energy (e.g., electrical signal). There are a variety of transducers to support the various applications of sensors. For example, a transducer is capacitor, a piezoelectric transducer, a piezoresistive transducer, a thermal transducer, a thermal-couple, a photoconductive transducer such as a photoresistor, a photodiode, and/or phototransistor.

A sensor circuit is coupled to a sensor to provide the sensor with power and to receive the signal representing the physical phenomenon from the sensor. The sensor circuit includes at least three electrical connections to the sensor: one for a power supply; another for a common voltage reference (e.g., ground); and a third for receiving the signal representing the physical phenomenon. The signal representing the physical phenomenon will vary from the power supply voltage to ground as the physical phenomenon changes from one extreme to another (for the range of sensing the physical phenomenon).

The sensor circuits provide the received sensor signals to one or more computing devices for processing. A computing device is known to communicate data, process data, and/or store data. The computing device may be a cellular phone, a laptop, a tablet, a personal computer (PC), a work station, a video game device, a server, and/or a data center that support millions of web searches, stock trades, or on-line purchases every hour.

The computing device processes the sensor signals for a variety of applications. For example, the computing device processes sensor signals to determine temperatures of a variety of items in a refrigerated truck during transit. As another example, the computing device processes the sensor signals to determine a touch on a touchscreen. As yet another example, the computing device processes the sensor signals to determine various data points in a production line of a product.

In addition, within the operation of many devices and systems, conversion between the analog domain and the digital domain, and vice versa, is performed in accordance with the operation of such devices and systems. For example, many devices and systems operate using one or more digital signal processors (DSPs), microcontrollers, processors, etc. that operate within the digital domain. However, within certain devices and systems, one or more signals are received being in analog or continuous-time format. In order to utilize such one or more signals, they must be converted to being in digital or discrete-time format. Prior art analog to digital converters (ADCs) have many deficiencies including being highly consumptive of power, providing relatively low resolution, etc. There continues to be many applications that may not be appropriately service and provide high levels of performance using prior art ADCs. For example, certain applications do not have adequate power budget to facilitate effective operation of prior art ADCs. Also, certain applications cannot operate with high levels of performance based on the level of resolution and accuracy provided by prior art ADCs.

Artificial Neural Network (ANN) processing is employed in a variety of applications. However, prior art implementations of Artificial Neural Networks (ANNs) typically require significant computational resources and are highly power consumptive. The high power consumption of prior art implementations of Artificial Neural Networks (ANNs) prohibits their implementation in a variety of applications including those that do not or cannot operate in very high powered applications.

### BRIEF DESCRIPTION OF THE SEVERAL VIEWS OF THE DRAWING(S)

FIG. 1 is a schematic block diagram of an embodiment of a communication system in accordance with the present disclosure;

FIG. 2 is a schematic block diagram of an embodiment of a computing device in accordance with the present disclosure;

FIG. 3 is a schematic block diagram showing various embodiments of analog to digital conversion as may be performed in accordance with the present disclosure;

FIG. 4 is a schematic block diagram of an embodiment of an analog to digital converter (ADC) in accordance with the present disclosure;

FIG. 5A is a schematic block diagram showing alternative embodiments of various components may be implemented within an ADC in accordance with the present disclosure;

FIG. 5B is a schematic block diagram showing alternative embodiments of servicing differential signaling using ADCs in accordance with the present disclosure;

FIG. 6 is a schematic block diagram of another embodiment of an ADC that includes one or more decimation filters in accordance with the present disclosure;

FIG. 7 is a schematic block diagram showing alternative embodiments of one or more decimation filters and/or processing modules that may be implemented to perform digital domain processing within an ADC in accordance with the present disclosure;

FIG. 8 is a schematic block diagram of another embodiment of an ADC in accordance with the present disclosure;

FIG. 9 is a schematic block diagram of another embodiment of an ADC in accordance with the present disclosure;

FIG. 10 is a schematic block diagram of another embodiment of an ADC in accordance with the present disclosure;

FIG. 11 is a schematic block diagram of an embodiment of an ADC that is operative to process an analog differential signal in accordance with the present disclosure;

FIG. 12 is a schematic block diagram of another embodiment of an ADC that is operative to process an analog differential signal in accordance with the present disclosure;

FIG. 13 is a schematic block diagram of another embodiment of an ADC that is operative to process an analog differential signal in accordance with the present disclosure;

FIG. 14A is a schematic block diagram of an embodiment an ADC that is operative to perform voltage measurement in accordance with the present disclosure;

FIG. 14B is a schematic block diagram of an embodiment an transimpedance amplifier that may be implemented within an ADC that is operative to perform voltage measurement in accordance with the present disclosure;

FIG. 15 is a schematic block diagram showing an embodiment of digital domain filtering within an ADC in accordance with the present disclosure;

FIG. 16 is a schematic block diagram showing an embodiment of digital domain filtering using cascaded filters within an ADC in accordance with the present disclosure;

FIG. 17 is a schematic block diagram showing another embodiment of digital domain filtering using configurable/adjustable cascaded filters within an ADC in accordance with the present disclosure;

FIG. 18 is a schematic block diagram showing an embodiment of one or more processing modules implemented to perform digital domain filtering within an ADC in accordance with the present disclosure;

FIG. 19 is a schematic block diagram of an embodiment of an ADC that includes a non-linear N-bit digital to analog converter (DAC) in accordance with the present disclosure;

FIG. 20 is a schematic block diagram of another embodiment of an ADC that includes a non-linear N-bit DAC in accordance with the present disclosure;

FIG. 21 is a schematic block diagram of another embodiment of an ADC that includes a non-linear N-bit DAC in accordance with the present disclosure;

FIG. 22 is a schematic block diagram of another embodiment of an ADC that includes a non-linear N-bit DAC in accordance with the present disclosure;

FIG. 23 is a schematic block diagram of an embodiment of an ADC that includes a non-linear N-bit DAC that is operative to process an analog differential signal in accordance with the present disclosure;

FIG. 24 is a schematic block diagram of another embodiment of an ADC that includes a non-linear N-bit DAC that is operative to process an analog differential signal in accordance with the present disclosure;

FIG. 25 is a schematic block diagram of an embodiment an ADC that includes a non-linear N-bit DAC and that is operative to perform voltage measurement in accordance with the present disclosure;

FIG. 26A is a schematic block diagram of an embodiment an ADC that includes a PNP transistor (alternatively, Positive-Negative-Positive Bipolar Junction Transistor (BJT)) implemented to source current in accordance with the present disclosure;

FIG. 26B is a schematic block diagram of an embodiment an ADC that includes an NPN transistor (alternatively, Negative-Positive-Positive BJT) implemented to sink current in accordance with the present disclosure;

FIG. 27 is a schematic block diagram of an embodiment an ADC that includes both a PNP transistor implemented to source current and an NPN transistor implemented to sink current in accordance with the present disclosure;

FIG. 28A is a schematic block diagram of an embodiment an ADC that includes diodes implemented to source and/or sink current in accordance with the present disclosure;

FIG. 28B is a schematic block diagram of an embodiment a PNP transistor diode configuration operative to generate a full scale voltage signal in accordance with the present disclosure;

FIG. 28C is a schematic block diagram of an embodiment an NPN transistor diode configuration operative to generate a full scale voltage signal in accordance with the present disclosure;

FIG. 29A is a schematic block diagram of an embodiment an ADC that includes a P-channel or P-type metal-oxide-semiconductor field-effect transistor (MOSFET) (alternatively, PMOS transistor) implemented to source current in accordance with the present disclosure;

FIG. 29B is a schematic block diagram of an embodiment an ADC that includes an N-channel or N-type metal-oxide-semiconductor field-effect transistor (MOSFET) (alternatively, NMOS transistor) implemented to sink current in accordance with the present disclosure;

FIG. 30 is a schematic block diagram of an embodiment an ADC that includes both a PMOS transistor implemented to source current and an NMOS transistor implemented to sink current in accordance with the present disclosure;

FIG. 31 is a schematic block diagram showing an embodiment of digital domain filtering within an ADC that includes a non-linear N-bit DAC in accordance with the present disclosure;

FIG. 32 is a schematic block diagram showing an embodiment of digital domain filtering using cascaded filters within an ADC that includes a non-linear N-bit DAC in accordance with the present disclosure;

FIG. 33 is a schematic block diagram showing another embodiment of digital domain filtering using configurable/adjustable cascaded filters within an ADC that includes a non-linear N-bit DAC in accordance with the present disclosure;

FIG. 34 is a schematic block diagram showing an embodiment of one or more processing modules implemented to perform digital domain filtering within an ADC that includes a non-linear N-bit DAC in accordance with the present disclosure;

FIGS. 35A, 35B, and 35C are schematic block diagrams showing various embodiments of analog to digital converters (ADCs) with improved bandwidth in accordance with the present disclosure;

FIGS. 35D, 35E, 35F, 35G, 35H, 35I, 35J, and 35K are schematic block diagrams showing various embodiments of current sensor circuitry that may be implemented in accordance with the present disclosure;

FIG. 35L shows multiple performance diagrams of ADC output expressed as power spectral density (PSD [dB]) as a function of frequency (kilo-Hertz [kHz]) in accordance with the present disclosure;

FIG. 36A is a schematic block diagram showing an embodiment of an ADC implemented with a thermometer decoder in accordance with the present disclosure;

FIGS. 36B and 36C are schematic block diagrams showing embodiments of one or more PNP BJTs (alternatively, Positive-Negative-Positive Bipolar Junction Transistors) and NPN BJTs (alternatively, Negative-Positive-Positive BJT) implemented to sink and source current within embodiments of ADCs implemented with a thermometer decoder in accordance with the present disclosure;

FIG. 36D is a schematic block diagram showing an alternative embodiment of an ADC implemented with a thermometer decoder in accordance with the present disclosure;

FIGS. 36E and 36F are schematic block diagrams showing embodiments of one or more metal-oxide-semiconductor field-effect transistors (MOSFETs) including one or more PMOS transistors and NMOS transistors implemented to sink and source current within embodiments of ADCs implemented with a thermometer decoder in accordance with the present disclosure;

FIG. 36G is a schematic block diagram showing an alternative embodiment of an ADC implemented with a thermometer decoder in accordance with the present disclosure;

FIG. 37A is a schematic block diagram showing an embodiment of a biological model of a structure of neurons operative within neural network processing in accordance with the present disclosure;

FIG. 37B is a schematic block diagram showing an embodiment of a model of an artificial neuron (processing element) operative within Artificial Neural Network (ANN) processing in accordance with the present disclosure;

FIG. 37C is a schematic block diagram showing an embodiment of a set of artificial neurons (processing elements) artificial neuron and weighted connections with adjustable strengths operative within Artificial Neural Network (ANN) processing in accordance with the present disclosure;

FIG. 37D is a schematic block diagram showing another embodiment of a model of an artificial neuron (processing element) operative within Artificial Neural Network (ANN) processing in accordance with the present disclosure;

FIG. 37E is a schematic block diagram showing the embodiment of the previous diagram with labeling that corresponds functional blocks with physical elements and hardware components within an artificial neuron (processing element) operative within Artificial Neural Network (ANN) processing in accordance with the present disclosure;

FIG. 37F is a schematic block diagram showing various embodiments of activation functions operative within Artificial Neural Network (ANN) processing in accordance with the present disclosure;

FIG. 37G is a schematic block diagram showing an embodiment of a model of an Artificial Neural Network (ANN) processing in accordance with the present disclosure;

FIG. 37H is a schematic block diagram showing another embodiment of a model of an Artificial Neural Network (ANN) processing in accordance with the present disclosure;

FIG. 37I is a schematic block diagram showing an embodiment of an artificial neuron (processing element) operative within Artificial Neural Network (ANN) processing in accordance with the present disclosure;

FIG. 37J is a schematic block diagram showing an embodiment of a sigma-delta digital to analog converter (DAC) operative within Artificial Neural Network (ANN) processing in accordance with the present disclosure;

FIG. 37K is a schematic block diagram showing an embodiment of a sigma-delta analog to digital converter (ADC) operative within Artificial Neural Network (ANN) processing in accordance with the present disclosure;

FIG. 37L is a schematic block diagram showing an embodiment of a first-order sigma-delta analog to digital converter (ADC) operative within Artificial Neural Network (ANN) processing in accordance with the present disclosure;

FIG. 37M is a schematic block diagram showing an embodiment of a second-order sigma-delta analog to digital converter (ADC) operative within Artificial Neural Network (ANN) processing in accordance with the present disclosure;

FIG. 37N is a schematic block diagram showing an embodiment of an Artificial Neural Network (ANN) processing in accordance with the present disclosure;

FIG. 38A is a schematic block diagram showing another embodiment of an artificial neuron (processing element) operative within Artificial Neural Network (ANN) processing in accordance with the present disclosure;

FIG. 38B is a schematic block diagram showing an embodiment of an Artificial Neural Network (ANN) processing in accordance with the present disclosure;

FIG. 39A is a schematic block diagram showing an embodiment of 1-bit multiplication circuitry having a single-ended configuration operative within Artificial Neural Network (ANN) processing in accordance with the present disclosure;

FIG. 39B is a schematic block diagram showing an embodiment of 1-bit multiplication circuitry having a differential configuration operative within Artificial Neural Network (ANN) processing in accordance with the present disclosure;

FIG. 40A is a schematic block diagram showing an embodiment of M-bit multiplication circuitry based on a single-ended configuration operative within Artificial Neural Network (ANN) processing in accordance with the present disclosure;

FIG. 40B is a schematic block diagram showing an embodiment of M-bit multiplication circuitry based on a differential configuration operative within Artificial Neural Network (ANN) processing in accordance with the present disclosure;

FIG. 40C is a schematic block diagram showing an embodiment of M-bit multiplication circuitry based on a P-type metal-oxide-semiconductor field-effect transistor (MOSFET) configuration operative within Artificial Neural Network (ANN) processing in accordance with the present disclosure;

FIG. 41 is a schematic block diagram showing an embodiment of analog current summation circuitry and analog to digital converter (ADC) circuitry operative within Artificial Neural Network (ANN) processing in accordance with the present disclosure;

FIG. 42 is a schematic block diagram showing an embodiment of current mode analog to digital converter (ADC) (IADC) and associated circuitry that is configured to perform an identity activation function or a hard hyperbolic tangent activation function within Artificial Neural Network (ANN) processing in accordance with the present disclosure;

FIG. 43 is a schematic block diagram showing an embodiment of current mode analog to digital converter (ADC) (IADC) and associated circuitry that is configured to perform an step activation function or a bipolar activation function within Artificial Neural Network (ANN) processing in accordance with the present disclosure;

FIG. 44 is a schematic block diagram showing an embodiment of current mode analog to digital converter (ADC) (IADC) and associated circuitry that is configured to perform a Rectified Linear Unit (ReLU) activation function within Artificial Neural Network (ANN) processing in accordance with the present disclosure;

FIG. 45 is a schematic block diagram showing an embodiment of current mode analog to digital converter (ADC) (IADC) and associated circuitry that is configured to perform a Leaky Rectified Linear Unit (ReLU) activation function within Artificial Neural Network (ANN) processing in accordance with the present disclosure; and

FIG. 46 is a schematic block diagram showing an embodiment of configurable current mode analog to digital converter (ADC) (IADC) and associated circuitry that is configured to perform a variety of activation functions within Artificial Neural Network (ANN) processing in accordance with the present disclosure.

### DETAILED DESCRIPTION OF THE INVENTION

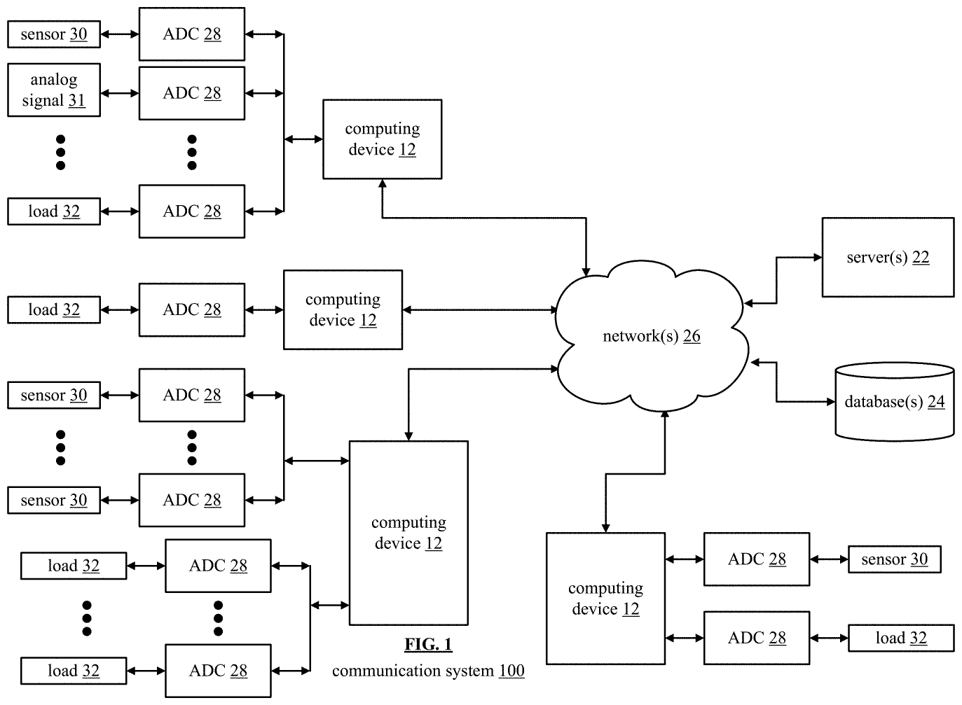

FIG. 1 is a schematic block diagram of an embodiment of a communication system 100 that includes a plurality of computing devices 12, one or more servers 22, one or more databases 24, one or more networks 26, a plurality of analog to digital converters (ADCs) 28, a plurality of sensors 30, and a plurality of loads 32. Generally speaking, an ADC 28 is configured to convert an analog signal 31 into a digital signal. In some examples, such an analog signal may be provided from and/or correspond a signal associated with a sensor 30, or generally speaking, a load 32 (e.g., such as which is consumptive of current, voltage, and/or power, and/or such as which produces a current, voltage, and/or power signal). Also, in some examples, note that any one of the computing devices 12 includes a touch screen with sensors 30, a touch & tactic screen that includes sensors 30, loads 32, and/or other components.

A sensor 30 functions to convert a physical input into an output signal (e.g., an electrical output, an optical output, etc.). The physical input of a sensor may be one of a variety of physical input conditions. For example, the physical condition includes one or more of, but is not limited to, acoustic waves (e.g., amplitude, phase, polarization, spectrum, and/or wave velocity); a biological and/or chemical condition (e.g., fluid concentration, level, composition, etc.); an electric condition (e.g., charge, voltage, current, conductivity, permittivity, eclectic field, which includes amplitude, phase, and/or polarization); a magnetic condition (e.g., flux, permeability, magnetic field, which amplitude, phase, and/or polarization); an optical condition (e.g., refractive index, reflectivity, absorption, etc.); a thermal condition (e.g., temperature, flux, specific heat, thermal conductivity, etc.); and a mechanical condition (e.g., position, velocity, acceleration, force, strain, stress, pressure, torque, etc.). For example, piezoelectric sensor converts force or pressure into an eclectic signal. As another example, a microphone converts audible acoustic waves into electrical signals.

There are a variety of types of sensors to sense the various types of physical conditions. Sensor types include, but are not limited to, capacitor sensors, inductive sensors, accelerometers, piezoelectric sensors, light sensors, magnetic field sensors, ultrasonic sensors, temperature sensors, infrared (IR) sensors, touch sensors, proximity sensors, pressure sensors, level sensors, smoke sensors, and gas sensors. In many ways, sensors function as the interface between the physical world and the digital world by converting real world conditions into digital signals that are then processed by computing devices for a vast number of applications including, but not limited to, medical applications, production automation applications, home environment control, public safety, and so on.

The various types of sensors have a variety of sensor characteristics that are factors in providing power to the sensors, receiving signals from the sensors, and/or interpreting the signals from the sensors. The sensor characteristics include resistance, reactance, power requirements, sensitivity, range, stability, repeatability, linearity, error, response time, and/or frequency response. For example, the resistance, reactance, and/or power requirements are factors in determining drive circuit requirements. As another example, sensitivity, stability, and/or linear are factors for interpreting the measure of the physical condition based on the received electrical and/or optical signal (e.g., measure of temperature, pressure, etc.).

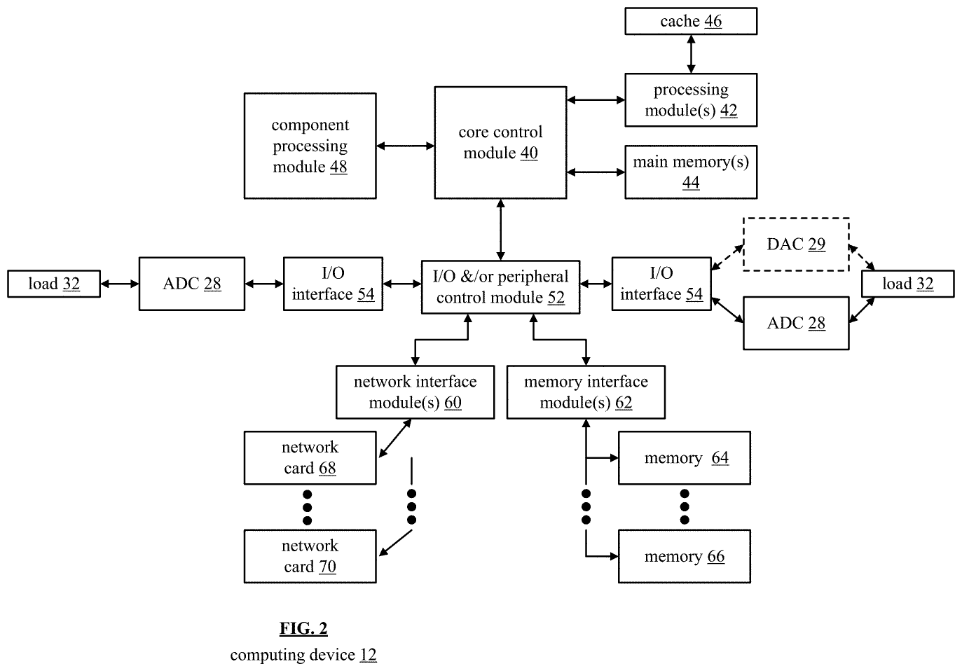

Any of the computing devices 12 may be a portable computing device and/or a fixed computing device. A portable computing device may be a social networking device, a gaming device, a cell phone, a smart phone, a digital assistant, a digital music player, a digital video player, a laptop computer, a handheld computer, a tablet, a video game controller, and/or any other portable device that includes a computing core. A fixed computing device may be a computer (PC), a computer server, a cable set-top box, a satellite receiver, a television set, a printer, a fax machine, home entertainment equipment, a video game console, and/or any type of home or office computing equipment. An example of the computing devices 12 is discussed in greater detail with reference to one or more of FIG. 2.

A server 22 is a special type of computing device that is optimized for processing large amounts of data requests in parallel. A server 22 includes similar components to that of the computing devices 12 with more robust processing modules, more main memory, and/or more hard drive memory (e.g., solid state, hard drives, etc.). Further, a server 22 is typically accessed remotely; as such it does not generally include user input devices and/or user output devices. In addition, a server may be a standalone separate computing device and/or may be a cloud computing device.

A database 24 is a special type of computing device that is optimized for large scale data storage and retrieval. A database 24 includes similar components to that of the computing devices 12 with more hard drive memory (e.g., solid state, hard drives, etc.) and potentially with more processing modules and/or main memory. Further, a database 24 is typically accessed remotely; as such it does not generally include user input devices and/or user output devices. In addition, a database 24 may be a standalone separate computing device and/or may be a cloud computing device.

The network 26 includes one more local area networks (LAN) and/or one or more wide area networks WAN), which may be a public network and/or a private network. A LAN may be a wireless-LAN (e.g., Wi-Fi access point, Bluetooth, ZigBee, etc.) and/or a wired network (e.g., Firewire, Ethernet, etc.). A WAN may be a wired and/or wireless WAN. For example, a LAN may be a personal home or business's wireless network and a WAN is the Internet, cellular telephone infrastructure, and/or satellite communication infrastructure.

In an example of operation, computing device 12 communicates with ADCs 28, that are in communication with a plurality of sensors 30. In some examples, the sensors 30 and/or ADCs 28 are within the computing device 12 and/or external to it. For example, the sensors 30 may be external to the computing device 12 and the ADCs 28 are within the computing device 12. As another example, both the sensors 30 and the ADCs 28 are external to the computing device 12. In some examples, when the ADCs 28 are external to the computing device, they are coupled to the computing device 12 via wired and/or wireless communication links.

The computing device 12 communicates with the ADCs 28 to; (a) turn them on, (b) obtain data from the sensors 30, loads 32, one or more analog signals 31, etc. individually and/or collectively), (c) instruct the ADC 28 on how to process the analog signals associated with the sensors 30, loads 32, one or more analog signals 31, etc. and to provide digital signals and/or information to the computing device 12, and/or (d) provide other commands and/or instructions.

In an example of operation and implementation, a computing device 12 is coupled to ADC 28 that is coupled to a senor 30. The sensor 30 and/or the ADC 28 may be internal and/or external to the computing device 12. In this example, the sensor 30 is sensing a condition that is particular to the computing device 12. For example, the sensor 30 may be a temperature sensor, an ambient light sensor, an ambient noise sensor, etc. As described above, when instructed by the computing device 12 (which may be a default setting for continuous sensing or at regular intervals), the ADC 28 is configured to generate a digital signal and/or information associated with the sensor 30 and to provide that digital signal and/or information to the computing device 12.

FIG. 2 is a schematic block diagram of an embodiment of a computing device 12 (e.g., any of the computing devices 12 in FIG. 1). The computing device 12 includes a core control module 40, one or more processing modules 42, one or more main memories 44, cache memory 46, an Input-Output (I/O) peripheral control module 52, one or more I/O interfaces 54, one or more ADCs 28 coupled to the one or more I/O interfaces 54 and one or more loads 32, optionally one or more digital to analog converters (DACs) 29 one or more I/O interfaces 54, one or more input interface modules 56, one or more output interface modules 58, one or more network interface modules 60, and one or more memory interface modules 62. In some examples, the computing device 12 also includes a component processing module 48. In an example of operation and implementation, such a component processing module 48 is implemented to facilitate operations associated with video graphics that may include any one or more of video graphics, display, a touch screen, a camera, audio output, audio input, and/or any other one or more computing device components, etc.

A processing module 42 is described in greater detail at the end of the detailed description of the invention section and, in an alternative embodiment, has a direction connection to the main memory 44. In an alternate embodiment, the core control module 40 and the I/O and/or peripheral control module 52 are one module, such as a chipset, a quick path interconnect (QPI), and/or an ultra-path interconnect (UPI).

Each of the main memories 44 includes one or more Random Access Memory (RAM) integrated circuits, or chips. For example, a main memory 44 includes four DDR4 (4^{th} generation of double data rate) RAM chips, each running at a rate of 2,400 MHz. In general, the main memory 44 stores data and operational instructions most relevant for the processing module 42. For example, the core control module 40 coordinates the transfer of data and/or operational instructions from the main memory 44 and the memory 64-66. The data and/or operational instructions retrieve from memory 64-66 are the data and/or operational instructions requested by the processing module or will most likely be needed by the processing module. When the processing module is done with the data and/or operational instructions in main memory, the core control module 40 coordinates sending updated data to the memory 64-66 for storage.

The memory 64-66 includes one or more hard drives, one or more solid state memory chips, and/or one or more other large capacity storage devices that, in comparison to cache memory and main memory devices, is/are relatively inexpensive with respect to cost per amount of data stored. The memory 64-66 is coupled to the core control module 40 via the I/O and/or peripheral control module 52 and via one or more memory interface modules 62. In an embodiment, the I/O and/or peripheral control module 52 includes one or more Peripheral Component Interface (PCI) buses to which peripheral components connect to the core control module 40. A memory interface module 62 includes a software driver and a hardware connector for coupling a memory device to the I/O and/or peripheral control module 52. For example, a memory interface 62 is in accordance with a Serial Advanced Technology Attachment (SATA) port.

The core control module 40 coordinates data communications between the processing module(s) 42 and the network(s) 26 via the I/O and/or peripheral control module 52, the network interface module(s) 60, and a network card 68 or 70. A network card 68 or 70 includes a wireless communication unit or a wired communication unit. A wireless communication unit includes a wireless local area network (WLAN) communication device, a cellular communication device, a Bluetooth device, and/or a ZigBee communication device. A wired communication unit includes a Gigabit LAN connection, a Firewire connection, and/or a proprietary computer wired connection. A network interface module 60 includes a software driver and a hardware connector for coupling the network card to the I/O and/or peripheral control module 52. For example, the network interface module 60 is in accordance with one or more versions of IEEE 802.11, cellular telephone protocols, 10/100/1000 Gigabit LAN protocols, etc.

The core control module 40 coordinates data communications between the processing module(s) 42 and input device(s) 72 via the input interface module(s) 56 and the I/O and/or peripheral control module 52. An input device 72 includes a keypad, a keyboard, control switches, a touchpad, a microphone, a camera, etc. An input interface module 56 includes a software driver and a hardware connector for coupling an input device to the I/O and/or peripheral control module 52. In an embodiment, an input interface module 56 is in accordance with one or more Universal Serial Bus (USB) protocols.

The core control module 40 coordinates data communications between the processing module(s) 42 and output device(s) 74 via the output interface module(s) 58 and the I/O and/or peripheral control module 52. An output device 74 includes a speaker, etc. An output interface module 58 includes a software driver and a hardware connector for coupling an output device to the I/O and/or peripheral control module 52. In an embodiment, an output interface module 56 is in accordance with one or more audio codec protocols.

This disclosure presents novel analog to digital converter (ADC) designs, architectures, circuits, etc. that provide much improved performance in comparison to prior art ADCs. Various aspects, embodiments, and/or examples of the disclosure (and/or their equivalents) that may be used to perform analog to digital conversion of signals provide very high resolution digital format data. Certain examples of such analog-to-digital conversion is performed based on sensing an analog current signal associated with a sensor, a load, etc. or any source of an analog signal. In many examples provided herein, a load 32 is employed as the element having an associated analog signal that is sensed and converted to a digital signal. Generally speaking, such a load 32 may be any of a variety of types of sources, devices, systems, etc. that has an associated analog signal that may be sensed and converted to a digital signal including a sensor, a computing device, a circuit, etc. within any type of application context including industrial, medical, communication system, computing device, etc.

In addition, various aspects, embodiments, and/or examples of the disclosure (and/or their equivalents) that may be used to perform analog to digital conversion of signals may be implemented in accordance with providing both drive and sense capabilities such that a signal is driven from the ADC 28 to the load 32 to facilitate sensing of the analog signal associated with the load 32. In some examples, the signal is driven from the ADC 28 to energize the load 32 and to facilitate its effective operation. Consider an example in which the load 32 is a sensor 30. In such an example, the signal provided from the ADC 28 is operative to provide power to the sensor 30 and also simultaneously to sense the analog signal associated with the sensor 30 simultaneously via a single line. Alternatively, note that certain examples may operate such that the load 32 is provided power or energy from an alternative source. In such instances, the ADC 28 need not specifically be implemented to provide power or energy to the load 32 but merely to sense the analog signal associated with the sensor 30. In some examples, a sensing signal is provided from the ADC 28 to the load 32 such that detection of any change of the sensing signal is used and interpreted to determine one or more characteristics of the analog signal associated with the load 32. In certain examples, the providing of the sensing signal from the ADC 28 to the load 32 and the sensing of the analog signal associated with the load 32 are performed simultaneously via a single line that couples or connects the ADC 28 to the load 32.

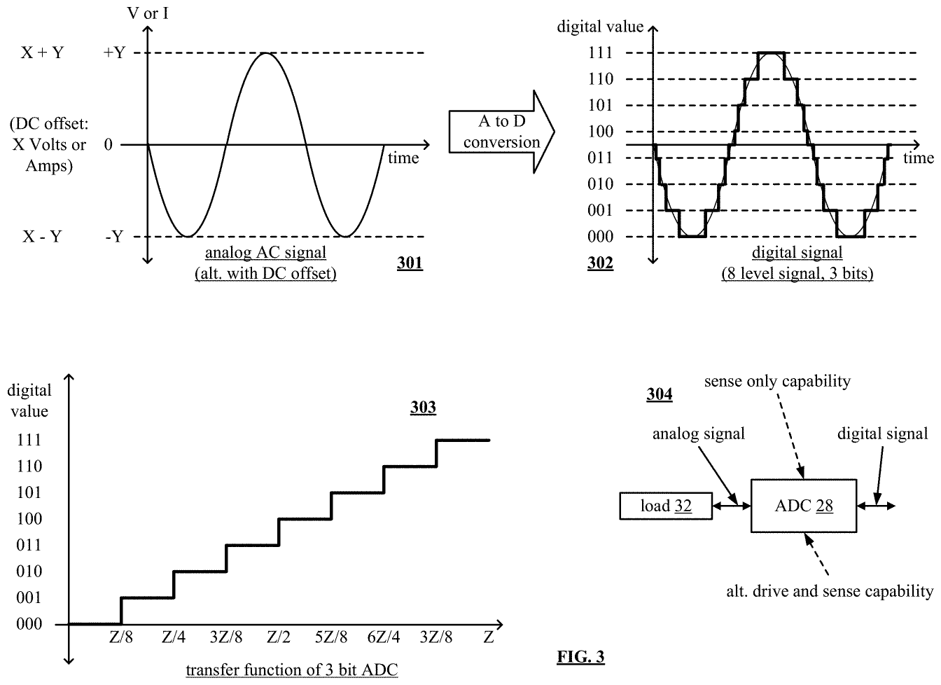

FIG. 3 is a schematic block diagram showing various embodiments 301, 302, 303, and 304 of analog to digital conversion as may be performed in accordance with the present disclosure. In the upper left portion of the diagram, with respect to reference numeral 301, and analog AC signal is shown. Note that the analog AC signal may or may not have a DC offset. Consider an example in which the DC offset is X volts, and consider a sinusoidal analog AC signal oscillates and varies between a maximum of +Y volts to a minimum of −Y volts as a function of time based on a particular frequency of the analog AC signal. Note that this example of an analog AC signal is not exhaustive, and generally speaking, such an analog AC signal may have any variety of shapes, frequencies, characteristics, etc. Examples of such analog signals may include any one or more of a sinusoidal signal, a square wave signal, a triangular wave signal, a multiple level signal (e.g., has varying magnitude over time with respect to the DC component), and/or a polygonal signal (e.g., has a symmetrical or asymmetrical polygonal shape with respect to the DC component).

Note also that such an analog signal may alternatively have only a DC component with no AC component. Note that any of the respective implementations of an ADC has described herein, or their equivalents, is also operative to detect an analog signal having only a DC component. Note that a totally non-varying analog signal having only a DC component, after undergoing analog-to-digital conversion, would produce a digital signal having a constant digital value as a function of time. That is to say, such a discrete-time signal generated based on a DC signal.

In the upper right hand portion of the diagram, with respect reference numeral 302, the analog AC signal shown with respect to reference numeral 301 is shown as undergoing analog-to-digital conversion in accordance with generating a digital signal. Generally speaking, the resolution and granularity of such a digital signal may be of any desired format including performing analog-to-digital conversion based on a range spanning any number of desired levels and generating a digital signal having any number of desired bits, N, where N is a positive integer. This particular example shows generation of additional signal in accordance with a range having 8 levels such that the digital signal includes 3 bits. For example, consider an analog AC signal having no DC offset and varying between a range spanning +Y/−Y volts, then that range is divided into 8 respective sub-range is, and when the value of the analog AC signal crosses from one sub-range into another sub-range as a function of time, then the value of the digital signal correspondingly changes as a function of time. With respect to reference numeral 302, a digital representation of the analog AC signal shown with respect to reference numeral 301 is shown as a function of time.

In the lower left-hand portion of the diagram, with respect to reference numeral 303, a transfer function of a three bit ADC is shown with respect to a Z volt reference. As the magnitude of the analog AC signal varies as a function of time, a corresponding digital value is generated based on where the magnitude of the analog AC signal is within the range from zero to a Z volt reference. Note that this particular example shown with respect to reference numeral 303 is shown as varying between zero and a Z volt reference.

In another example, such a transfer function may be implemented based on using −Y volts as a baseline such that, along the horizontal axis, 0 corresponds to −Y volts, and Z is twice the magnitude of Y (e.g., Z=2×MAG[Y]). For example, consider the analog AC signal shown with respect to reference 301 as being an analog AC signal having no DC offset and varying between a range spanning +Y/−Y volts, then the Z volt reference could correspond to Y (or alternatively some value greater than Y to facilitate detection of the analog AC signal bearing outside of a particular or expected range), then such an 8 level, 3 bit digital signal may be generated such as shown with respect to reference numeral 302.

In the lower right hand portion of the diagram, with respect to reference numeral 304, an ADC 28 is shown as being coupled or connected to a load 32. The ADC 28 is configured to sense an analog signal associated with the load 32 and to generate a digital signal based thereon. Note that the ADC 28 may be implemented to facilitate both drive and sense capabilities such that the ADC 28 is configured to drive an analog current and/or voltage signal to the load 32 while concurrently or simultaneously sensing the analog signal associated with the load 32. In alternative examples, the ADC 28 is also operative to perform simultaneous driving and sensing of the analog signal associated with the load 32 when the load 32 is energized from another source such as from a battery, an external power source, etc.

Note that the ADC 28 includes capability and functionality to perform sensing only or alternatively, to perform both drive and sense. In some examples, the ADC 28 is configured to perform sensing only of an analog signal (e.g., having AC and/or DC components) associated with the load 32. In other example, the ADC 28 is configured to drive an analog current and/or voltage signal to the load 32 while concurrently and/or simultaneously sensing an analog signal (e.g., having AC and/or DC components) associated with the load 32. For example, the ADC 28 is configured to provide power to or energize the load 32 while also concurrently and/or simultaneously sensing an analog signal (e.g., having AC and/or DC components) associated with the load 32. Also, in certain alternative examples, the ADC 28 is also operative to perform simultaneous driving and sensing of the analog signal associated with the load 32 when the load 32 is energized from another source such as from a battery, an external power source, etc.

Various aspects, embodiments, and/or examples of the disclosure (and/or their equivalents) include an ADC that is operative to sense an analog current signal. The ADC is implemented to convert the sensed analog current signal into a very high resolution digital format of a desired resolution (e.g., of a certain sampling rate, resolution, or number of bits, etc.).

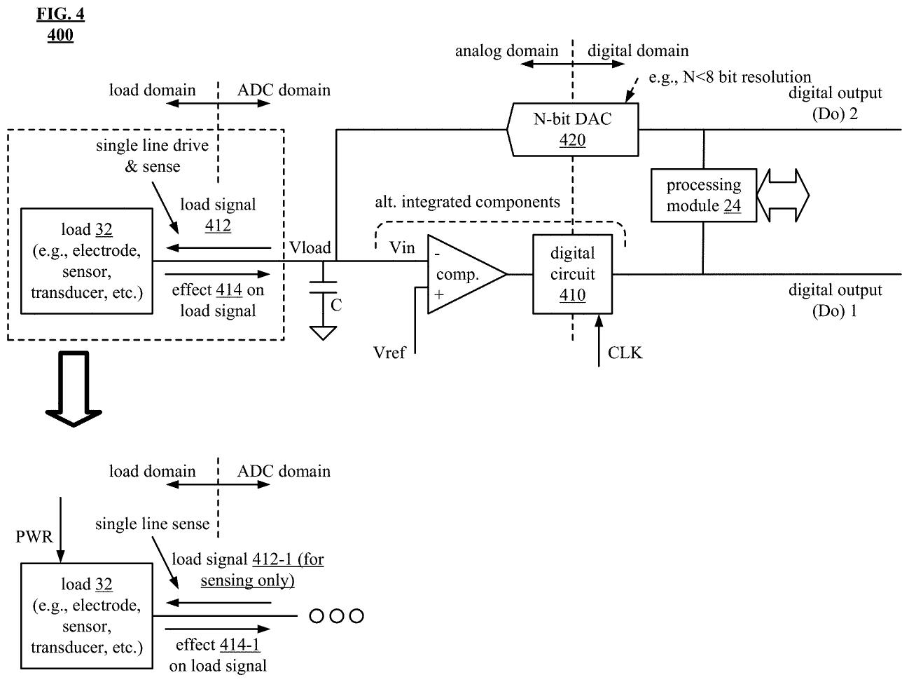

FIG. 4 is a schematic block diagram of an embodiment 400 of an analog to digital converter (ADC) in accordance with the present disclosure. In this diagram, an ADC is connected to or coupled to a load 32 via single line such that the ADC is configured to provide a load signal 412 via that single line and simultaneously to detect any effect 414 on that load signal via a single line. In certain examples, the ADC is configured to perform single line drive and sense of that load signal 412, including any effect 414 thereon via that single line.

Note that certain of the following diagrams show one or more processing modules 24. In certain instances, the one or more processing modules 24 is configured to communicate with and interact with one or more other devices including one or more of ADCs, one or more components implemented within an ADC (e.g., filters of various types including low pass filters, bandpass filters, decimation filters, etc., gain or amplification elements, digital circuits, digital to analog converters (DACs) of varying types include N-bit DACs, analog to digital converters (ADCs) of varying types include M-bit ADCs, etc. Note that any such implementation of one or more processing modules 24 may include integrated memory and/or be coupled to other memory. At least some of the memory stores operational instructions to be executed by the one or more processing modules 24. In addition, note that the one or more processing modules 24 may interface with one or more other devices, components, elements, etc. via one or more communication links, networks, communication pathways, channels, etc. (e.g., such as via one or more communication interfaces of the device, such as may be integrated into the one or more processing modules 24 or be implemented as a separate component, circuitry, etc.).

Also, within certain of the following diagrams, there is a demarcation shown between the analog domain and the digital domain (e.g., showing the portion of the diagram that operates in the analog domain based on continuous-time signaling, and the portion of the diagram that operates in the digital domain that operates in the digital domain based on discrete-time signaling). Moreover, within certain of the following diagrams, there is a demarcation shown between the load domain and the ADC domain (e.g., Showing the connection or coupling between a load and/or an analog signal that is being sensed and the ADC that is sensing the analog signal, which may be associated with the load). In certain examples, an ADC is connected to or coupled to a load via a single line.

Also, such an ADC may be implemented to perform simultaneous driving and sensing of a signal via that single line that connects or couples to the load. For example, such an ADC is operative to drive an analog signal (e.g., current and/or voltage) of the load 32. With respect to implementations that operate in accordance with sensing analog current signals, such an ADC is operative to sense current signals within an extremely broad range including very low currents (e.g., currents below the 1 pico-amp range, within the 10s of pico-amps range, below the 1 nano-amp range, within the 10s of nano-amps range, below the 1 micro-amp range, within the 10s of micro-amps range, etc.) and also up to relatively much larger currents (e.g., currents in the 10s milli-amps range, 100s milli-amps range, or even higher values of amps range, etc.). In some examples, such as with respect to detecting currents that are provided from a photodetection or photodiode component, such an ADC is operative to sense current signals below the 1 pico-amp range, currents within the 100s of micro-amps range, etc.

Also, in some examples, when using appropriately provisioned components (e.g., higher current, higher power, etc.), much higher currents can also be sensed using architectures and topologies in accordance with an ADC as described herein. For example, such an ADC implemented based on architectures and topologies, as described herein, using appropriately provisioned components are operative to sense even higher currents (e.g., is of amps, 10s of amps, or even higher values of amps range, etc.).

In addition, such an ADC may be implemented to provide for extremely low power consumption (e.g., less than 2 μW). Such an ADC may be particularly well-suited for low-power applications such as remote sensors, battery operated applications, etc. The architecture and design of such an ADC requires very few analog components. this provides a number of advantages and improve performance over prior art ADCs including very little continuous static current being consumed. In certain examples, such an ADC is described herein provides for a 10× lower power consumption in comparison to prior art ADC technologies. Such extremely low power consumption implementations may be particularly well-suited for certain applications such as bio-medical applications including sensing of vital signs on the patient, low current sensors, remote sensors, etc.

In addition, note that while such an ADC as described herein provides for significant improvement in a reduction in power consumption in comparison to prior art ADCs (e.g., including prior art ADCs such as successive approximation resolution (SAR) ADCs, D-sigma modulator ADCs, pipe-line ADCs, etc.), such an ADC is described herein may be implemented as a general-purpose ADC in any of a variety of applications. Moreover, the bandwidth of analog signals that may be sensed using such an ADC is described herein is extremely broad, ranging from DC up to and over 10 MHz. In certain particular examples, such an ADC has described herein is implemented for very low frequency measurements, such as from DC up to 1 kHz.

Note also that an ADC as described herein may be designed and tailored particularly for a desired digital signal resolution to be generated based on a particular bandwidth to be sampled. In general, there may be a trade-off between bandwidth and power consumption within a particularly designed ADC. Consider an example in which a very high resolution digital signal is desired for a relatively low sampling bandwidth versus another example in which a relatively low resolution digital signal is desired for a relatively high sampling bandwidth. For example, consider a particularly designed ADC to provide a digital signal having 16-bit resolution for a sampling bandwidth below 100 kHz, then such an ADC may be implemented to consume less than 1 μW of energy.

Such an ADC may be appropriately designed to meet criteria for a particular application. Consider an example in which a 24-bit digital signal is desired for a relatively low sampling bandwidth from DC up to 100 kHz. Consider another example in which a 12 bit digital signal desired for a relatively higher sampling bandwidth from DC up to 1 MHz. In comparing these two examples, as the sampling bandwidth is extended higher and higher, the ADC will consume more current and thereby be more power consumptive. Depending on the particular application at hand, a relatively low sampling bandwidth may be acceptable for the particular application at hand, and very significant power consumption savings may be achieved. Generally speaking, a trade-off in design implementation may be viewed as higher resolution/lower sampling bandwidth/lower power consumption versus higher resolution/higher sampling bandwidth/higher power consumption.

In addition, note that many of the examples of an ADC included herein operate based on sensing a current signal as opposed to a voltage signal. In addition, when the ADC is implemented in an application to sense a voltage signal, an appropriately implemented voltage to current transforming element, such as the trans-impedance amplifier that is operative to transform voltage to current, or vice versa, may be implemented to generate a current signal from a voltage signal in any particular desired application.

In any of the various diagrams, note that such a load 32 may be of any of a variety of types including electrode, a sensor, a transducer, etc. Generally speaking, such a load 32 may be any of a variety of types of components. Examples of such components may include any one or more of sources, devices, systems, etc. that has an associated analog signal that may be sensed and converted to a digital signal including a sensor, a computing device, a circuit, etc. within any type of application context including industrial, medical, communication system, computing device, etc.

Also, note that such a load 32 as depicted within any diagram herein may be energized or powered based on the signal provided from the ADC or alternatively powered by another source such as a battery, external power source, etc. For example, consider the lower left-hand portion of the diagram and need demarcation between the load domain and the ADC domain, such that the load 32 is connected to the ADC via a single line. In certain examples, the ADC is implemented to facilitate single-line sense functionality such that a load signal 412-1 is provided to the load 32 for sensing only, and any effect 414-1 on that load signal is sensed and detected by the ADC. In such an example is this, power is provided to the load 32 from an external source.

Referring again to the top portion of the diagram, the ADC is connected to or coupled to a load 32 via single line such that the ADC is configured to provide a load signal 412 via that single line and simultaneously to detect any effect 414 on that load signal via a single line. For example, the load signal 412 is an analog current signal. An analog capacitor, C, is implemented to be charged in accordance with the load signal 412. Note that such an analog capacitor may alternatively be a load capacitance from the load 32 itself, such that a separate analog capacitor, C, is not needed when the load 32 itself provides a sufficient load capacitance.

In an example of operation and implementation, a load voltage, Vload, is generated based on any effect 414 on that load signal charging the capacitor. This load voltage, Vload, serves as an input voltage, Vin, to one of the inputs of a comparator that also receives a reference signal, Vref (e.g., a voltage reference signal). Note that the reference signal, Vref, may be internally generated, provided from an external source, provided from a processing module 24, etc. The comparator compares the input voltage, Vin, to the reference signal, Vref, and outputs a signal that is based on any difference between the input voltage, Vin, to the reference signal, Vref, that gets processed by a digital circuit 410 to generate a digital output (Do) 1 signal that may be viewed as being a digital stream of 0s and/or is at a clock rate (CLK) at which the digital circuit 410 is clocked.

For example, consider that the input voltage, Vin, is greater than the reference signal, Vref, then the comparator output signal would be positive (e.g., such as a positive rail or power supply voltage of the ADC). Alternatively, consider that the input voltage, Vin, is less than or equal to the reference signal, Vref, then the comparator output signal would be negative (e.g., such as a negative rail or power supply voltage of the ADC).

In another example, consider that the input voltage, Vin, is greater than the reference signal, Vref, then the comparator output signal would be positive or negative (e.g., such as a positive or negative rail or power supply voltage of the ADC). Alternatively, consider that the input voltage, Vin, is less than or equal to the reference signal, Vref, then the comparator output signal would be zero (e.g., such as a ground voltage potential).

Generally speaking, the combined operation of the comparator and the digital circuit 410 may be viewed as performing the analog to digital conversion of a signal that is the difference (e.g., and error voltage, Ve) between the input voltage, Vin, and the reference signal, Vref (e.g., Ve=Vref−Vin) to generate a digital signal of a particularly desired resolution, which may be viewed as M bits, where M is a positive integer greater than or equal to 1.

A processing module 24 is operative to process the Do 1 to generate a digital output (Do) 2. Note that the processing module 24 may be implemented in any of a variety of examples to perform any desired digital signal processing on the Do 1 to generate the Do 2. Examples of such digital signal processing may be increasing the output resolution (e.g., consider Do 1 having a resolution of M bits and Do 2 having a resolution of N bits, where N and M are both positive integers, where M is a positive integer greater than or equal to 1, and N is greater than M), performing filtering on the Do 1 to generate the Do 2 (e.g., such as low pass filtering or bandpass filtering based on certain parameters such as a particular frequency cut off for low pass filtering or a particular frequency range for bandpass filtering).

The processing module 24 provides the Do 2 to an N-bit digital to analog converter (DAC) 420. In some examples, the N-bit DAC 420 has a resolution of N<8 bits. This N-bit DAC 420, based on the Do 2 provided from the processing module 24, forces and output current to the load 32 that follows or tracks the load signal 412 due to the operation of the comparator that compares the input voltage, Vin, to the reference signal, Vref, and, in conjunction with the digital circuit 410, generates Do 1.

From certain perspectives, considering the Do 1 and the Do 2, the Do 1 may be viewed as a digital signal corresponding to the unfiltered load current signal including quantization noise, and the Do 2 may be viewed as another digital signal corresponding to a filtered load current signal.

In this diagram, the positive input of the comparator is driven by the reference signal, Vref. The load voltage, Vload, will follow the reference signal, Vref, based on the comparator output signal that corresponds to the difference or error between the input voltage, Vin, and the reference signal, Vref In many examples, the difference between the input voltage, Vin, and the reference signal, Vref, is very small (e.g., approaching 0, very close to 0, or actually 0) based on the Delta-sigma modulation operation of the comparator and the digital circuit 410. For example, when there is any difference between the input voltage, Vin, and the reference signal, Vref, the ADC adapts/modifies the output current from the N-bit DAC 420 to match the current of the load so that difference or error between the input voltage, Vin, and the reference signal, Vref, will be forced to 0.

Note that the comparator and the digital circuit 410 may be implemented using one or more other components and other examples while still providing the same overall functionality of the ADC. The following diagram shows some alternative possible examples of how the comparator and the digital circuit 410 may be implemented.

Note that this implementation of an ADC includes very few number of analog components. For example, there may be instances in which no capacitors required whatsoever given that the load 32 inherently includes sufficient load capacitance to generate the load voltage, Vload. In certain implementations, the comparator is implemented by a component that performs analog to digital conversion of the load voltage, Vload, directly thereby further reducing the number of analog components within the ADC.

Given the small number of analog components, such an ADC consumes little or no continuous static power thereby facilitating very low power consumption. The only static current being consumed is by the N-bit DAC 420. This N-bit DAC 420 drives and output current that is same as the sensed load current thereby tracking or following the load current. Therefore, within implementations in which the load current is small, so will the corresponding output current from the N-bit DAC 420 be small. The smaller the current provided from the N-bit DAC 420, which is based on the sensed load current, the lower the power consumption of the ADC. Note that there are certainly alternative implementations of an ADC that will consume some static current, such as when an M-bit analog to digital converter (ADC) is used or some other component that is implemented to perform the analog-to-digital conversion of the signal Vin to Do 1.

Also, note that the amount of power consumed by the DAC, particularly the digital power consumed by the DAC, scales with the clock rate, CLK. Note also that applications that are implemented to perform sensing of ADC signal, such as sensing ADC current signal, the clock frequency can be extremely low (e.g., within the range of 1 kHz to 100 kHz) thereby providing for a very small digital power consumption.

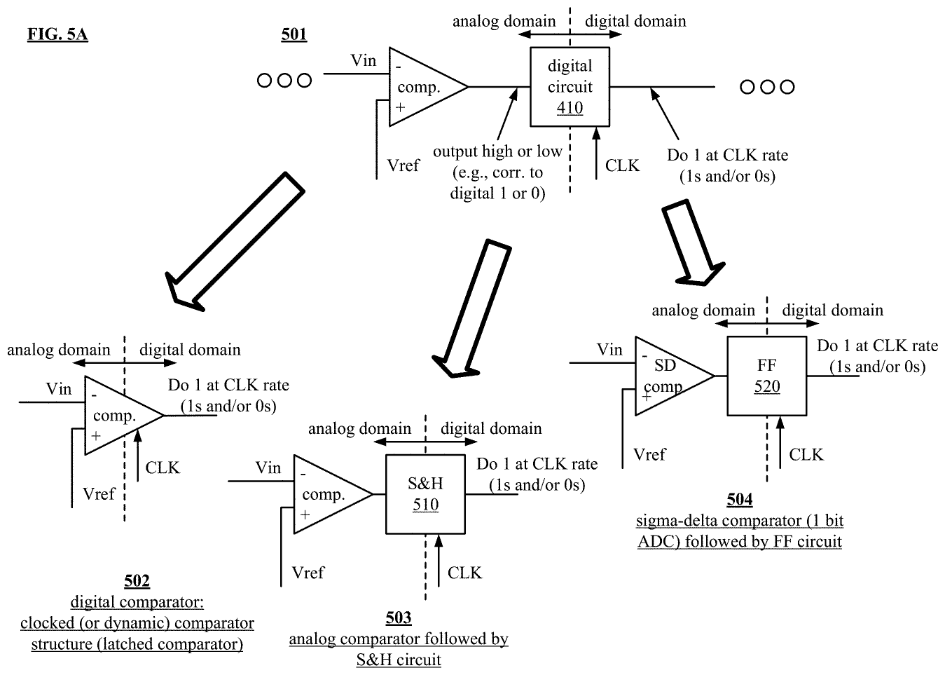

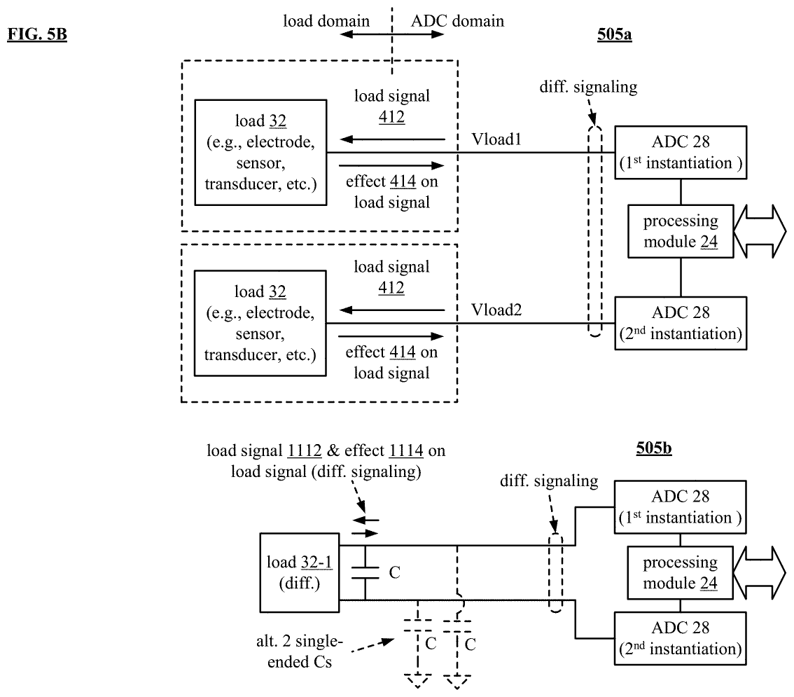

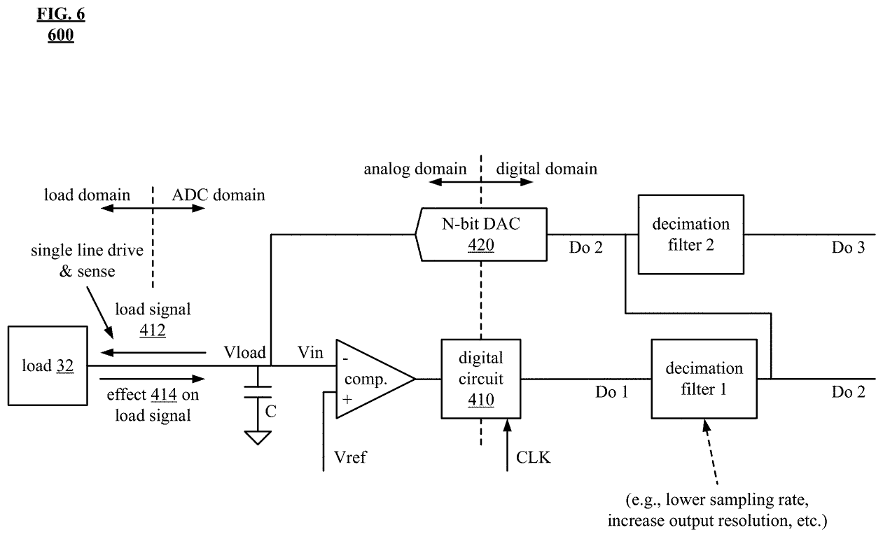

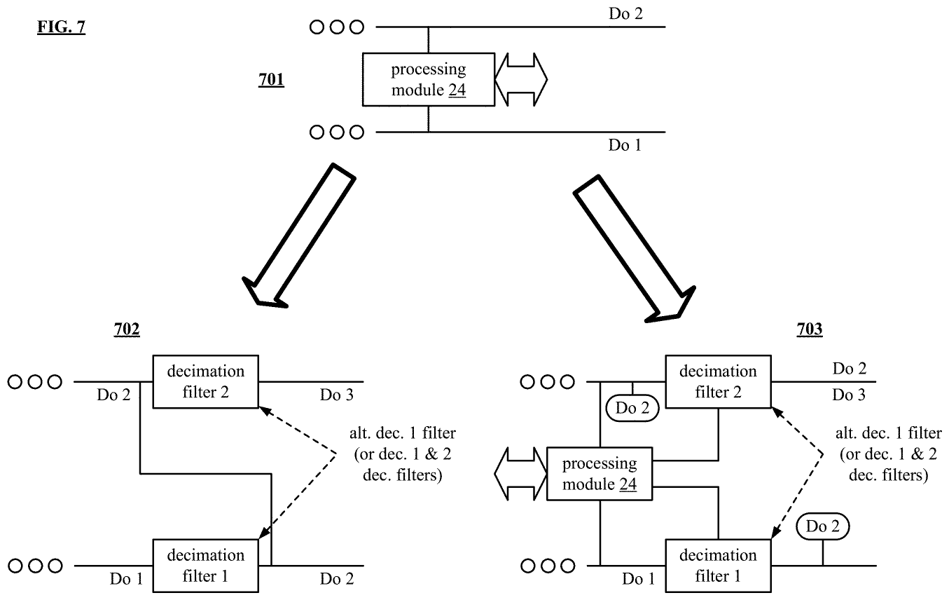

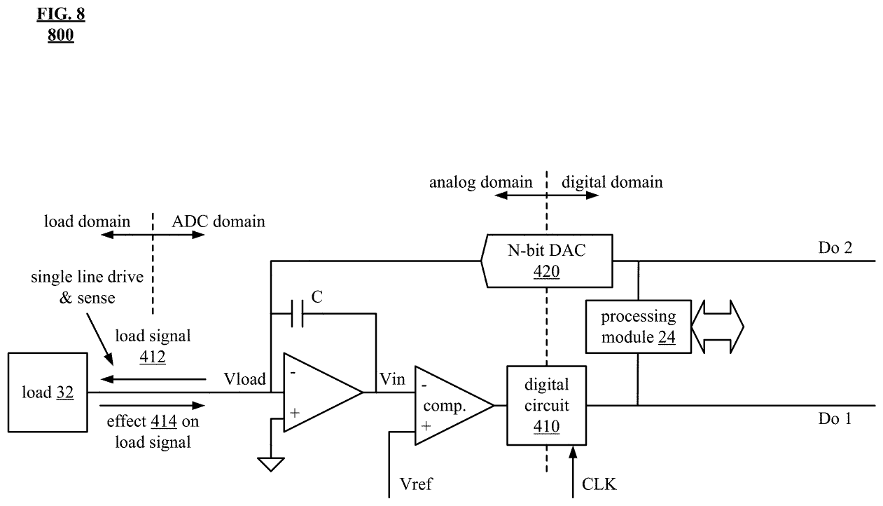

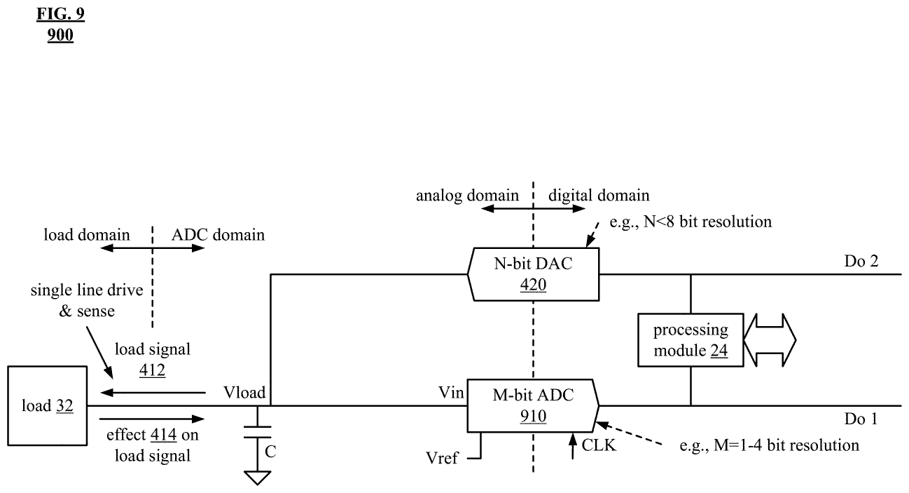

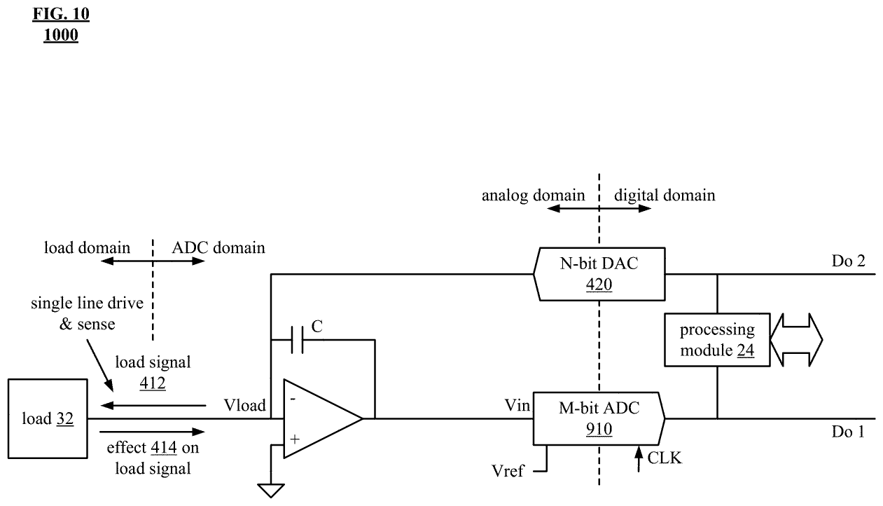

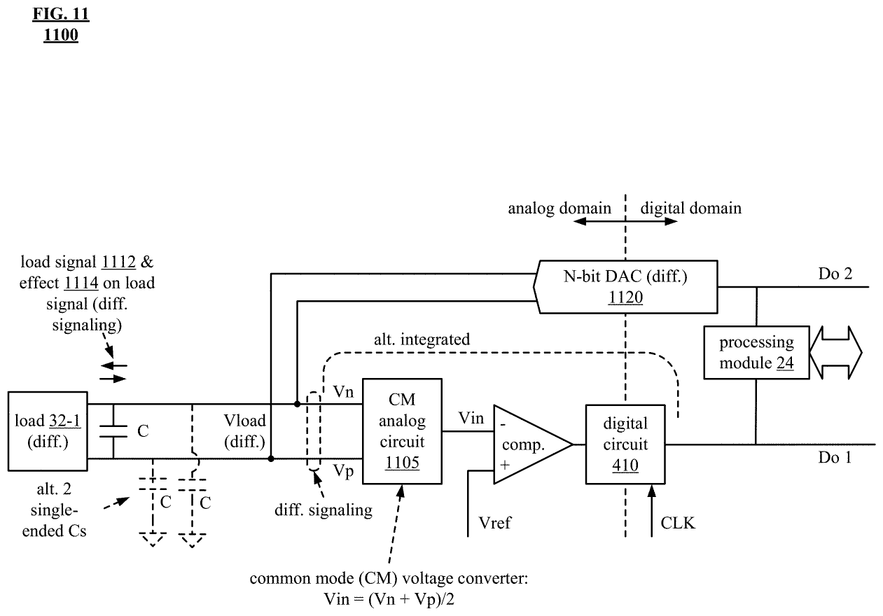

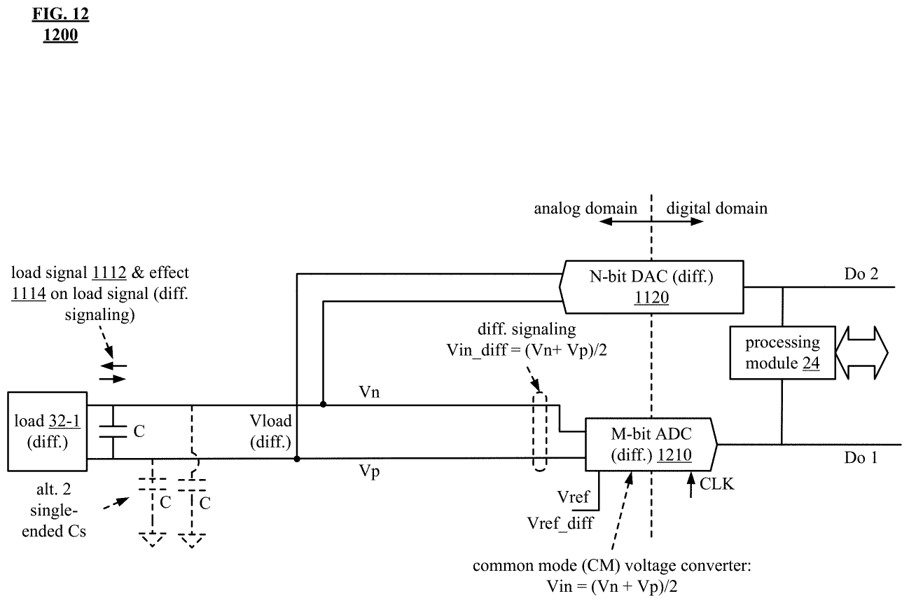

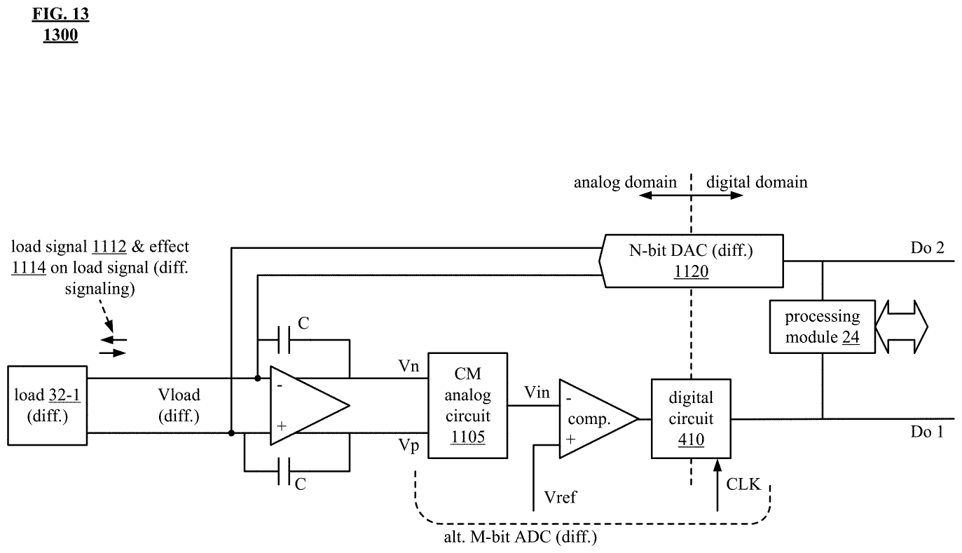

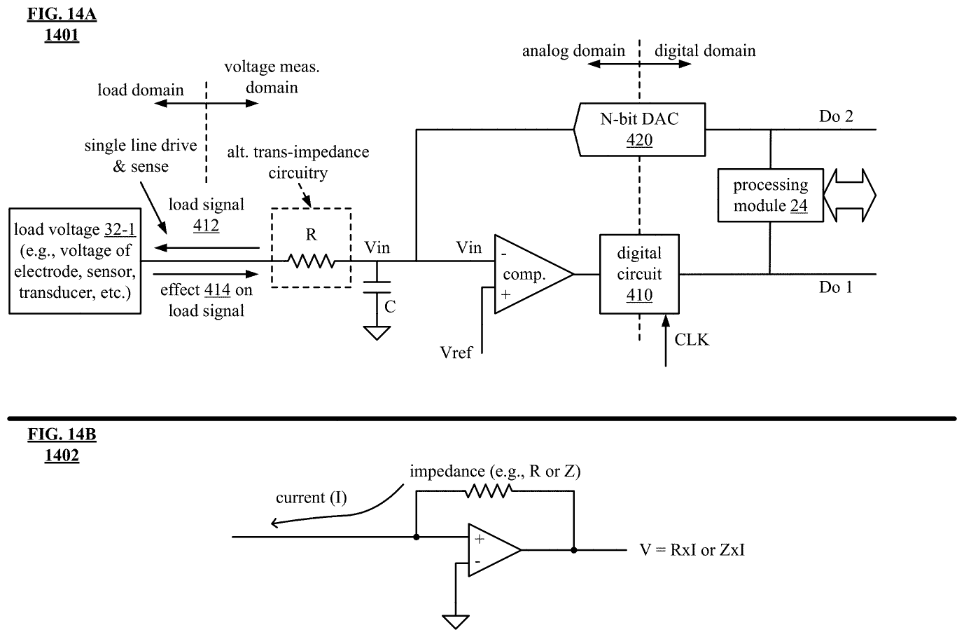

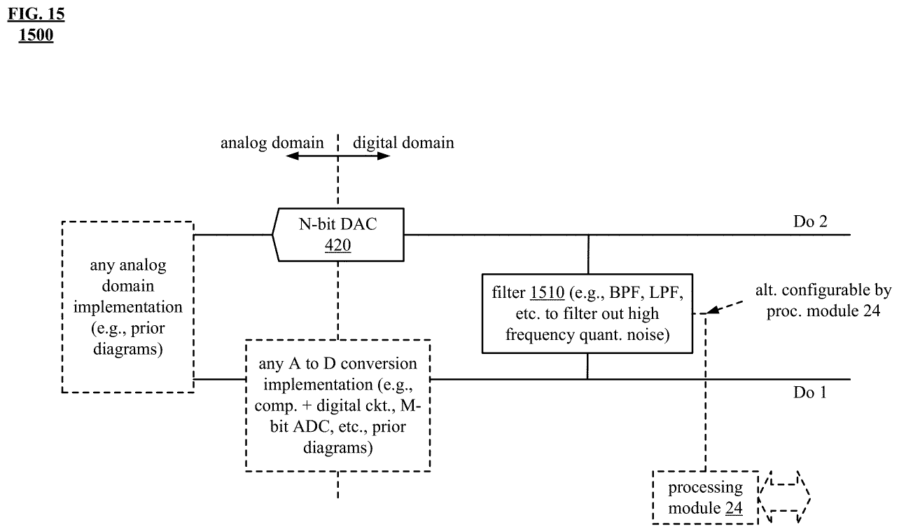

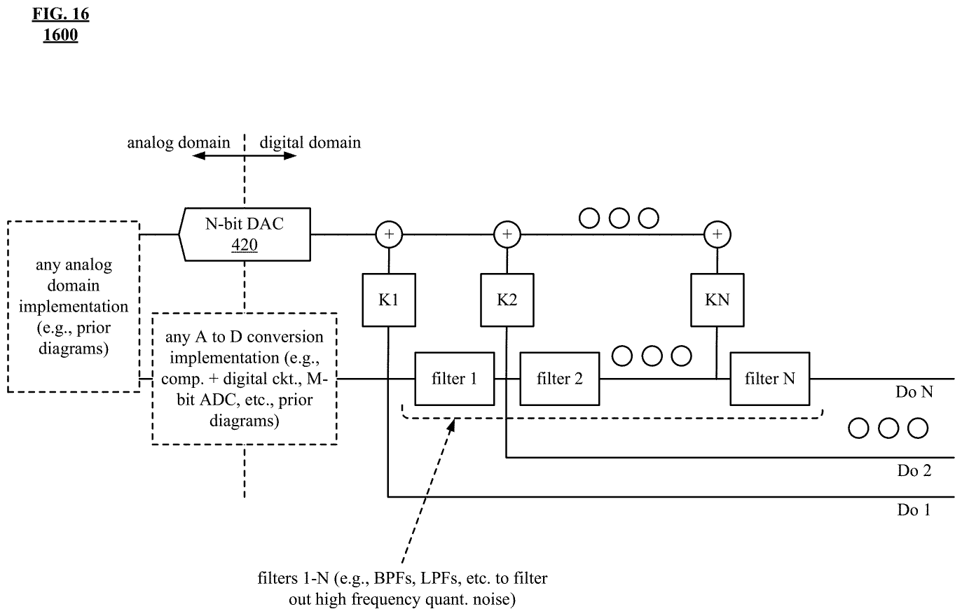

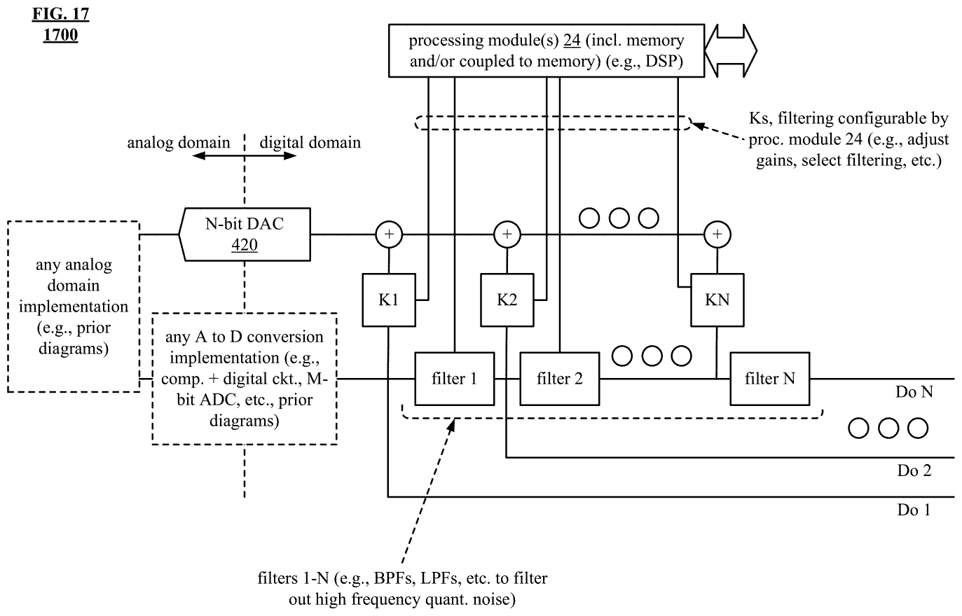

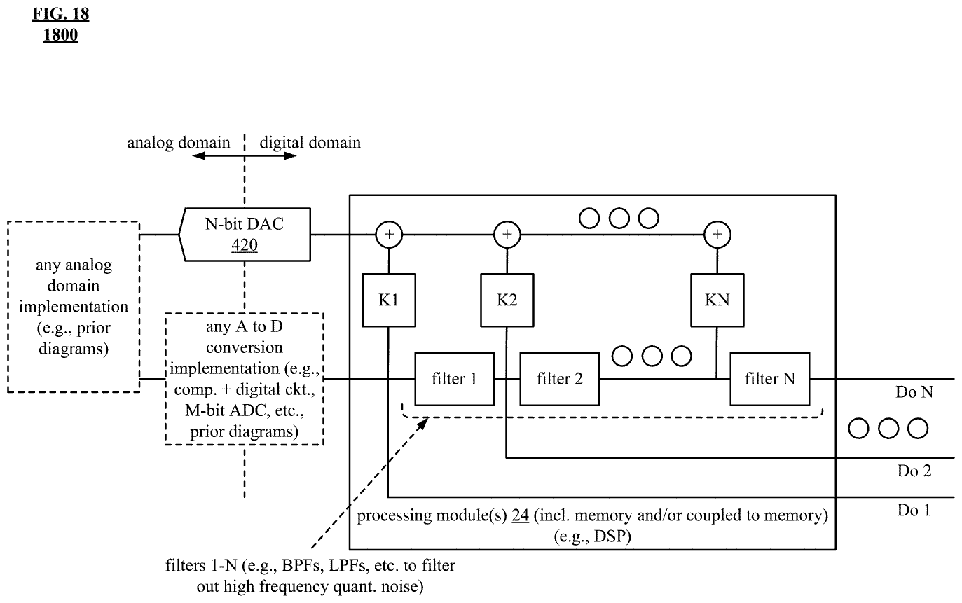

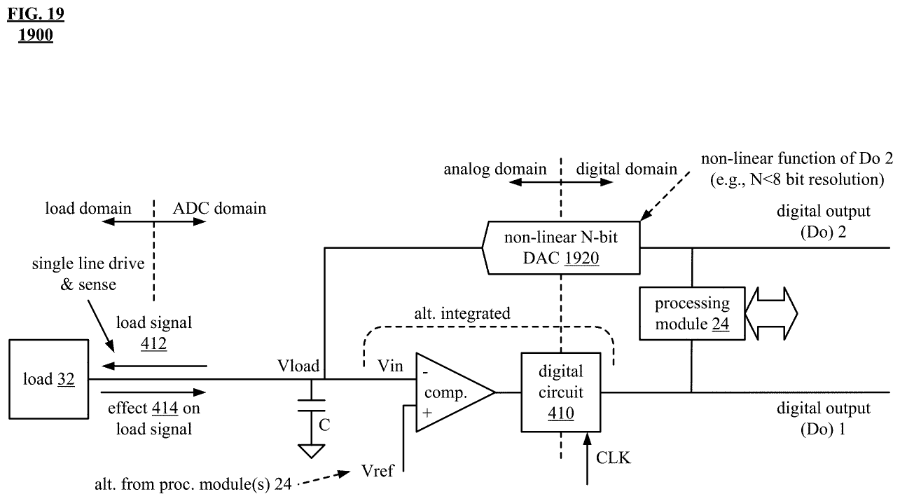

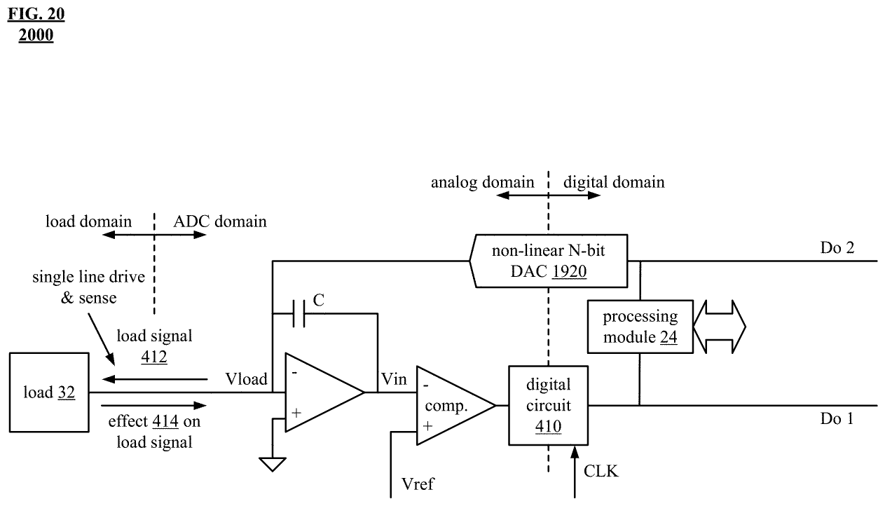

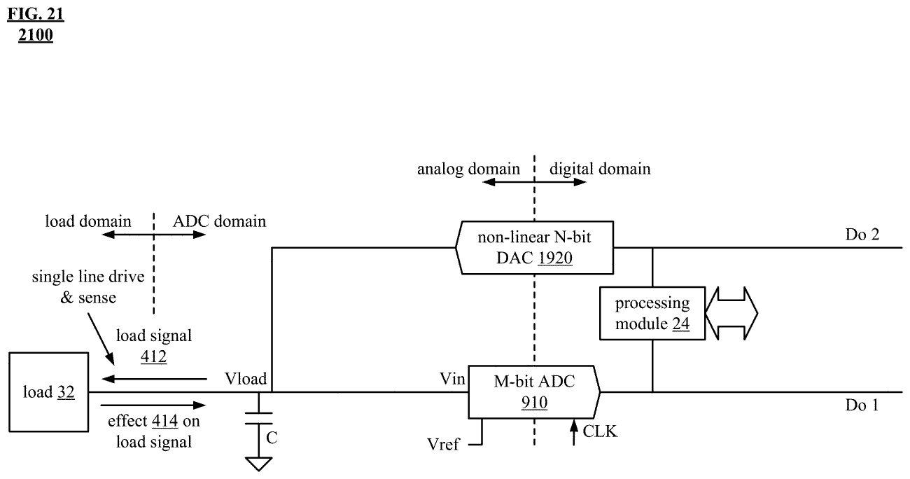

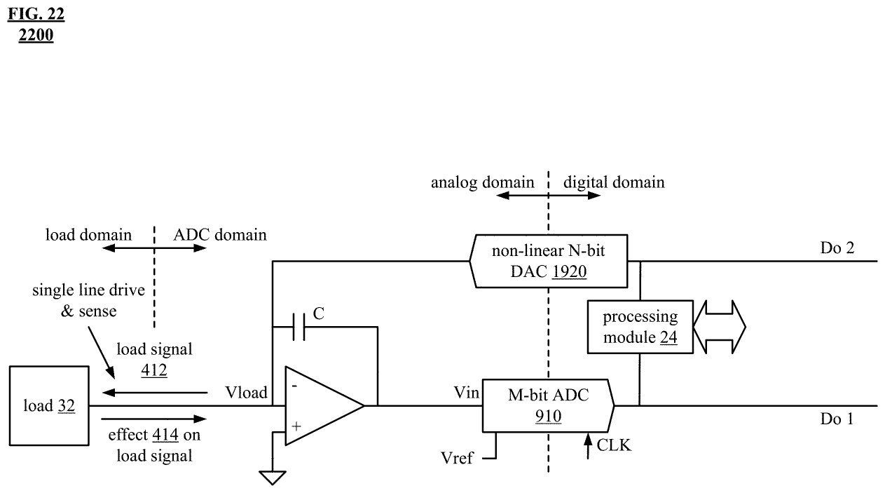

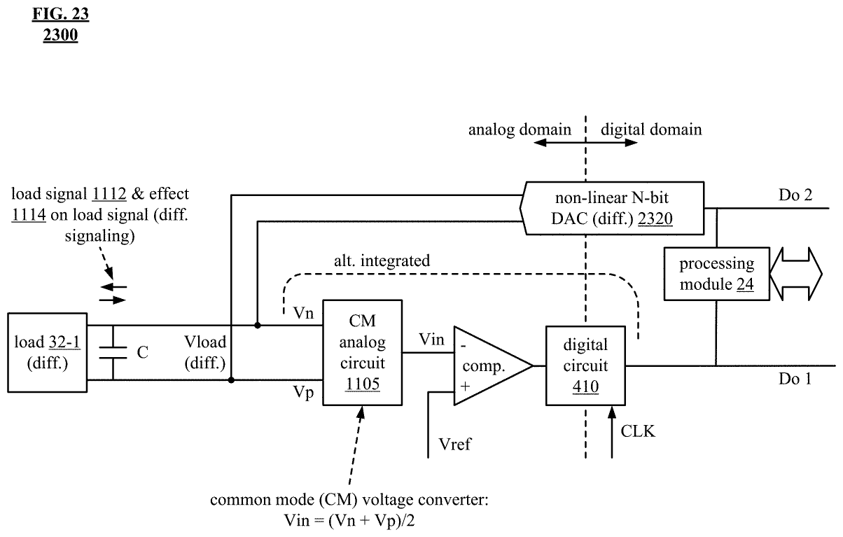

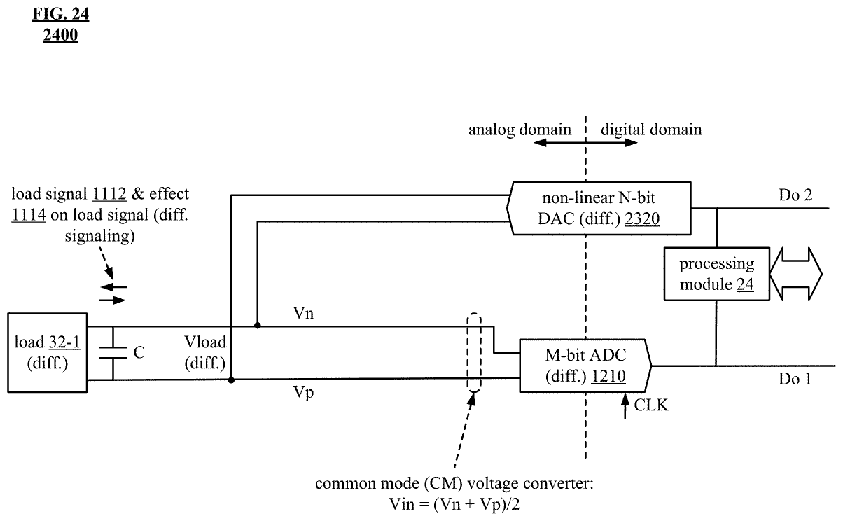

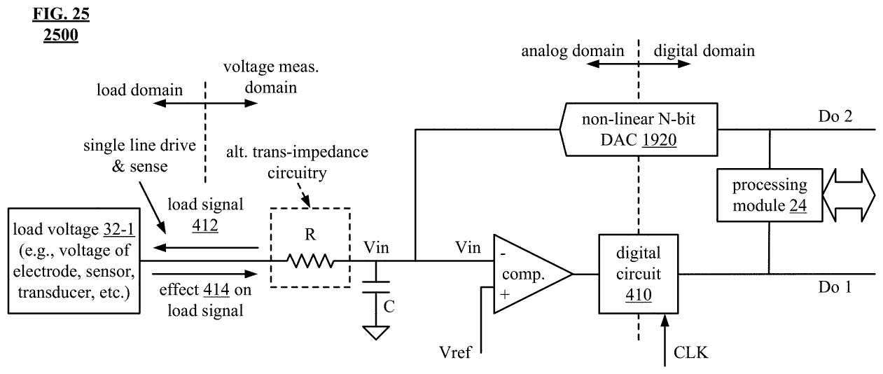

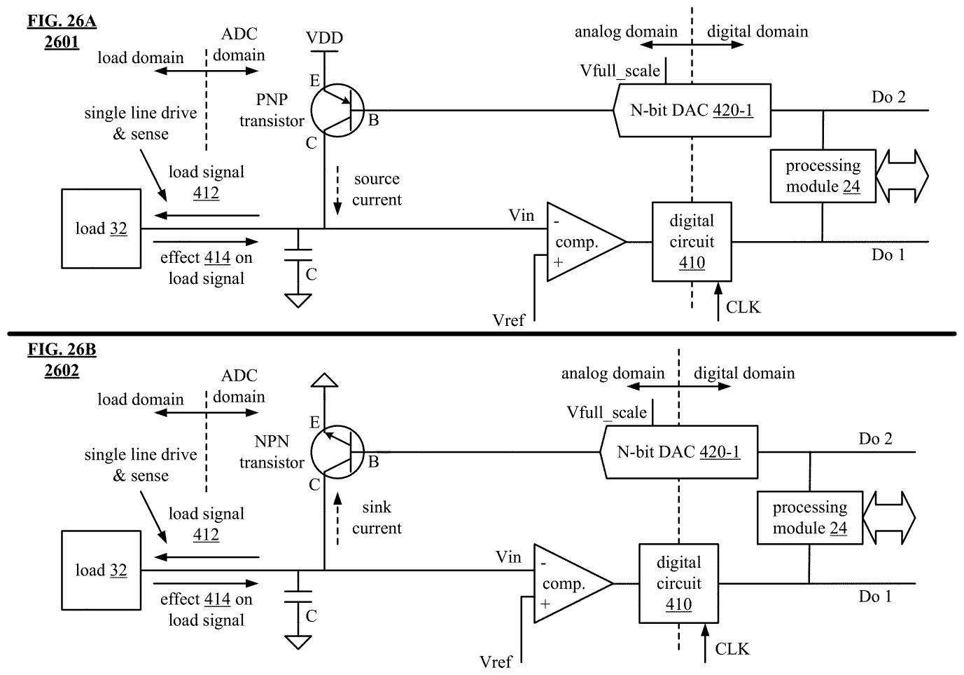

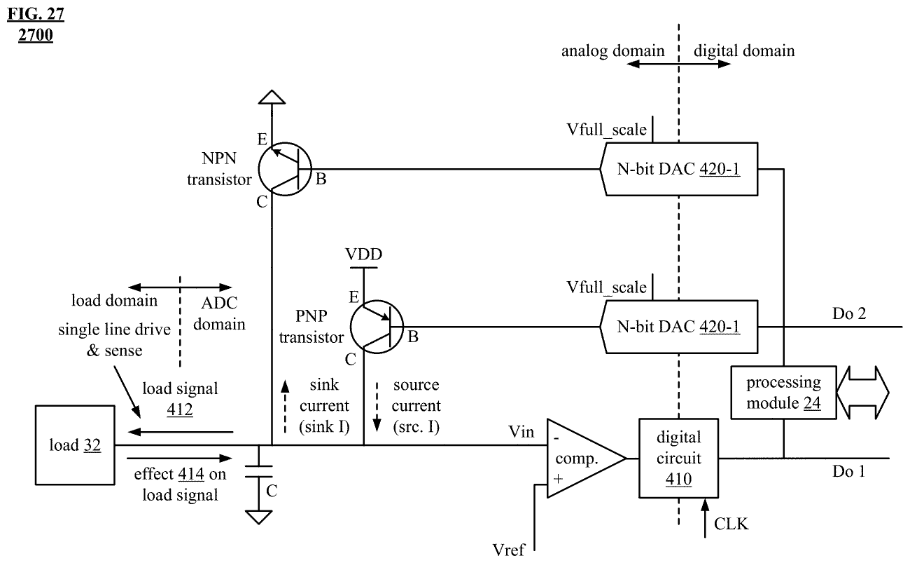

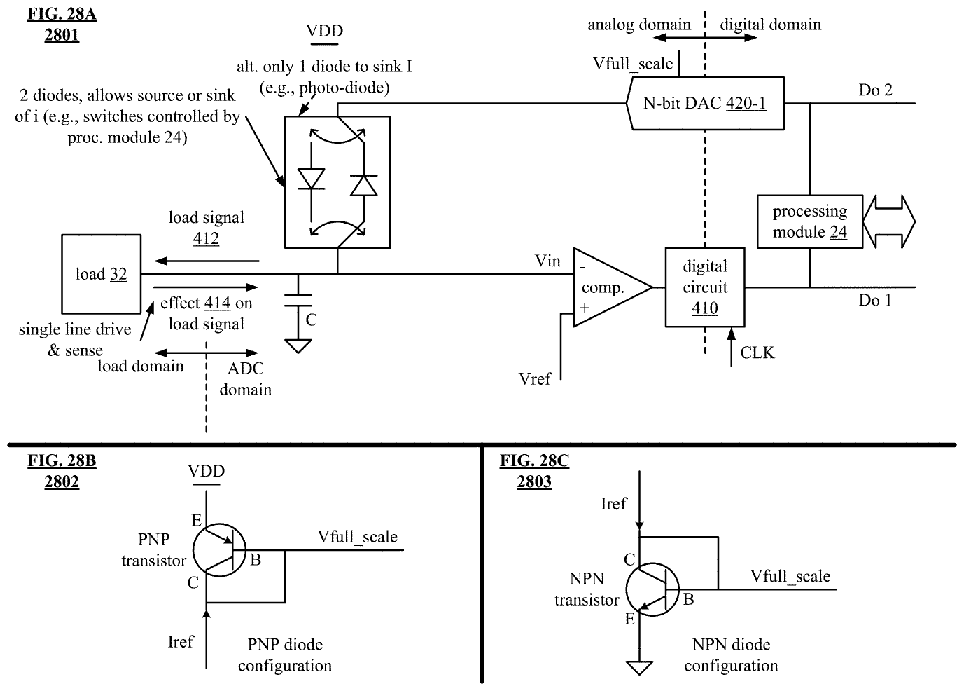

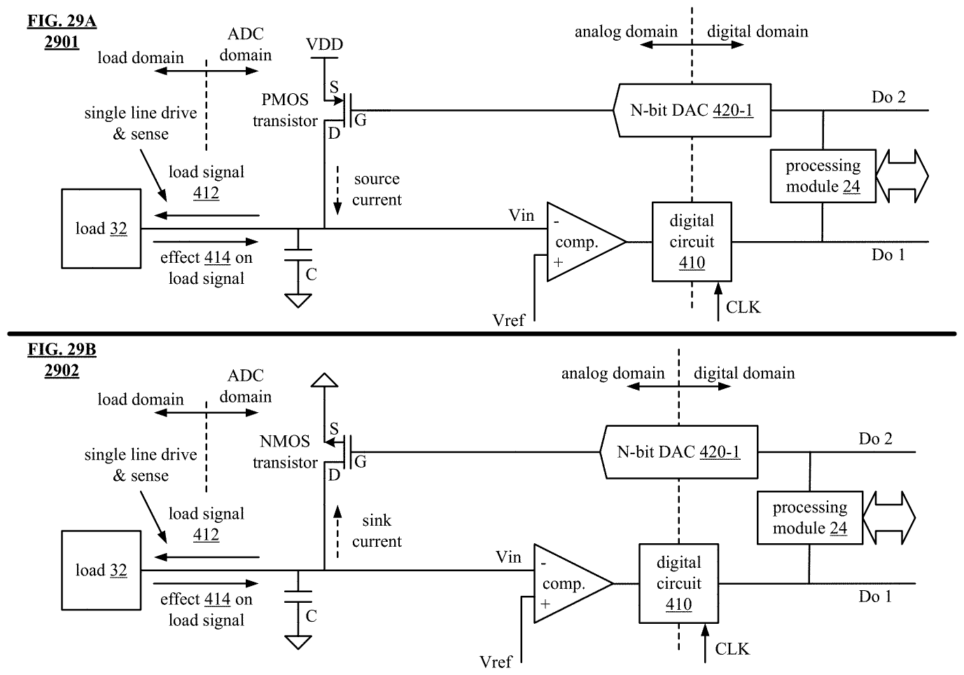

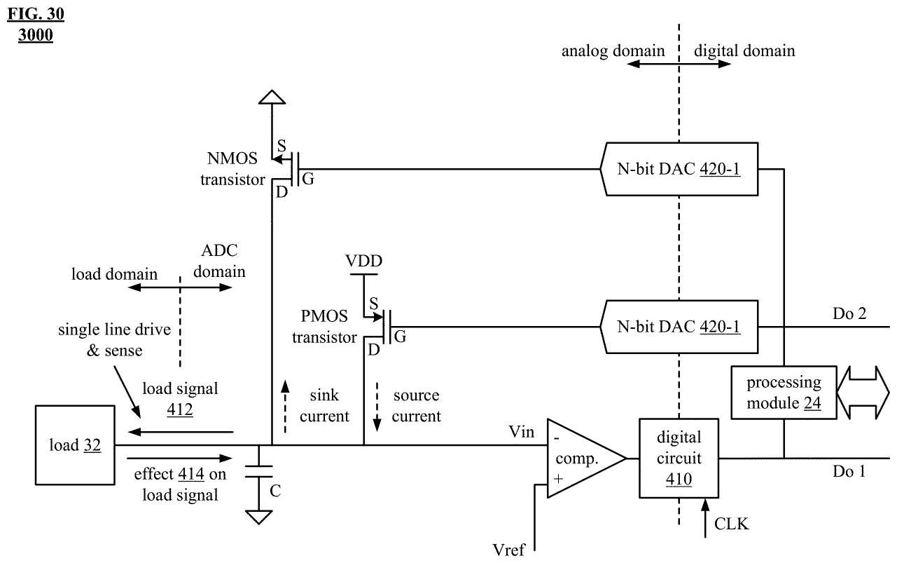

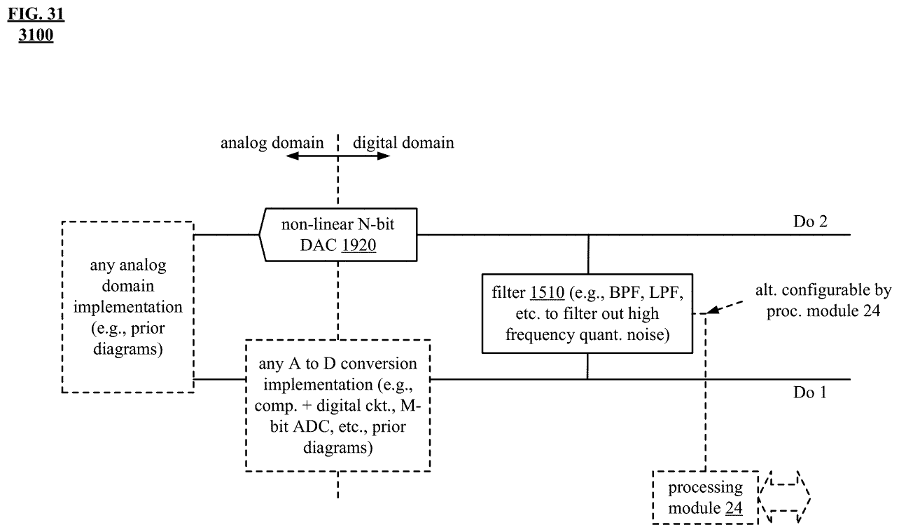

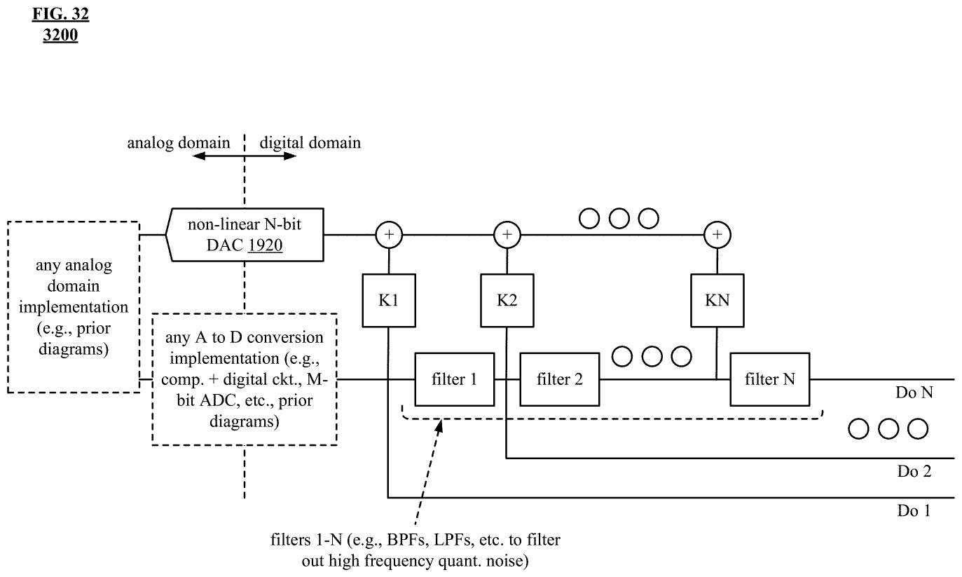

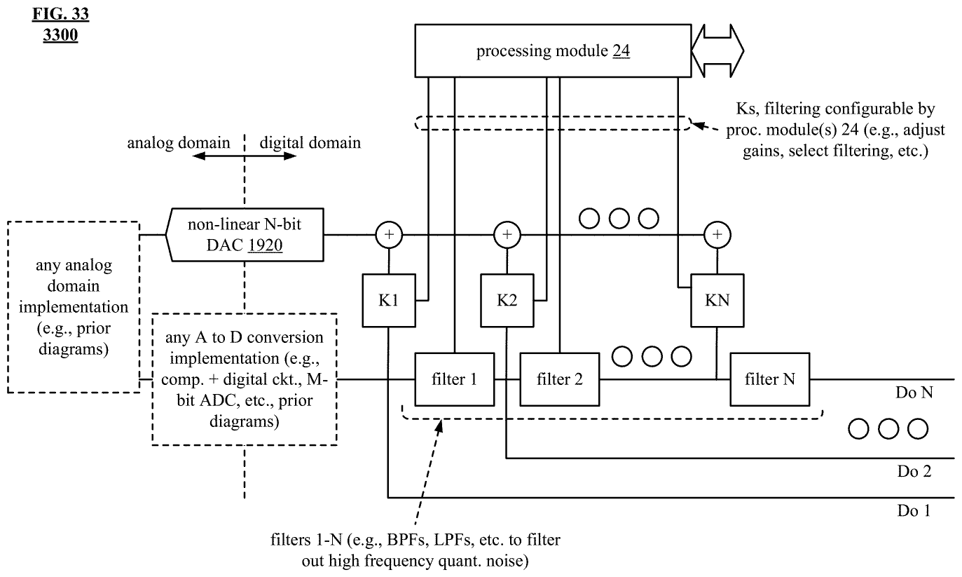

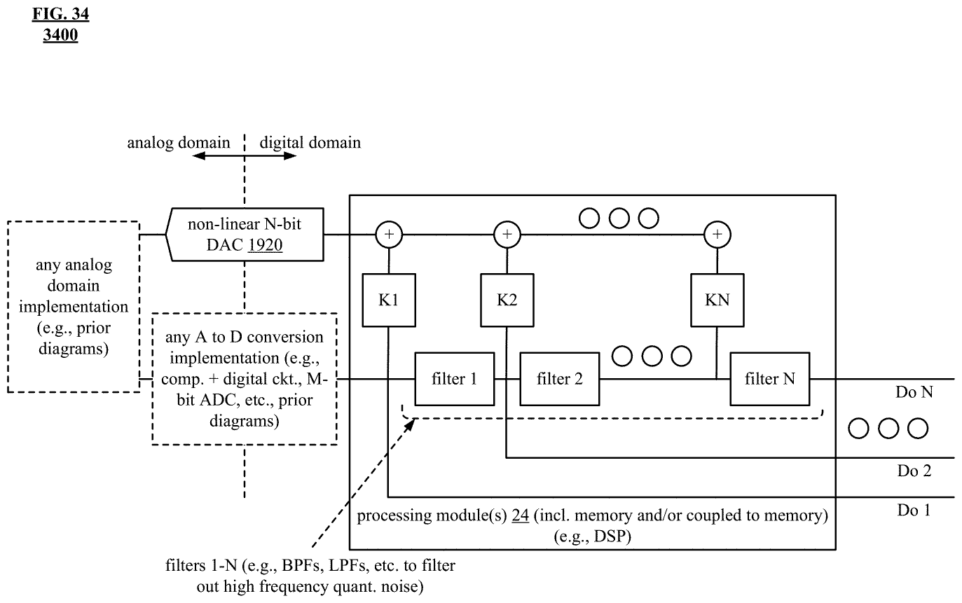

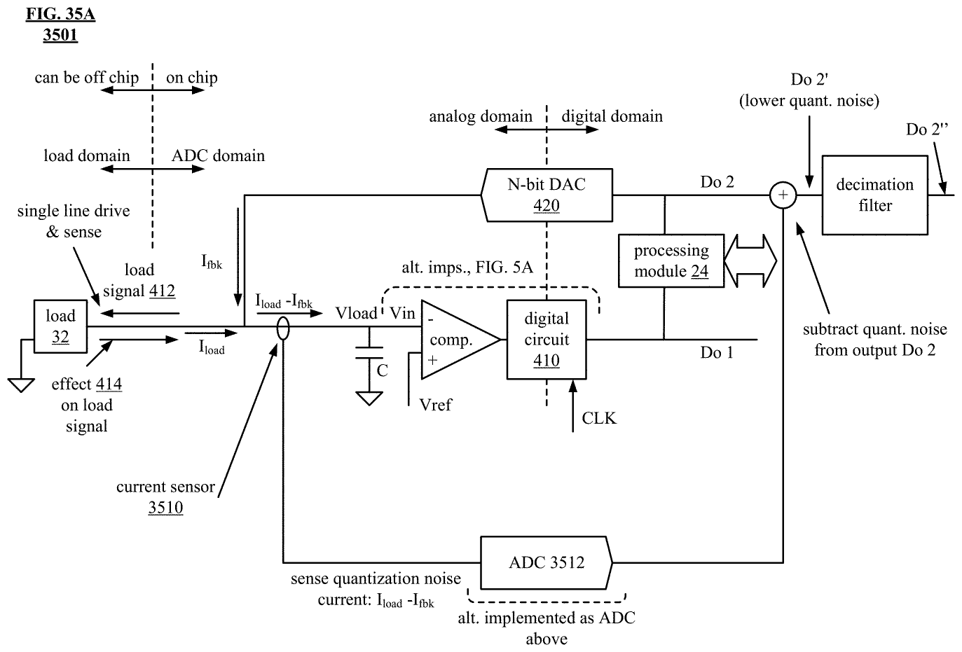

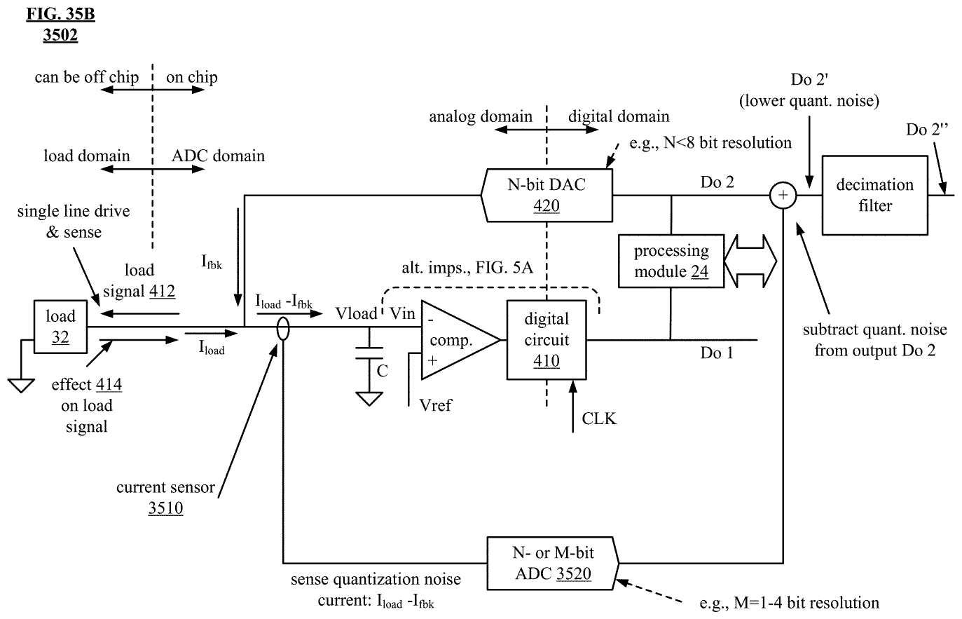

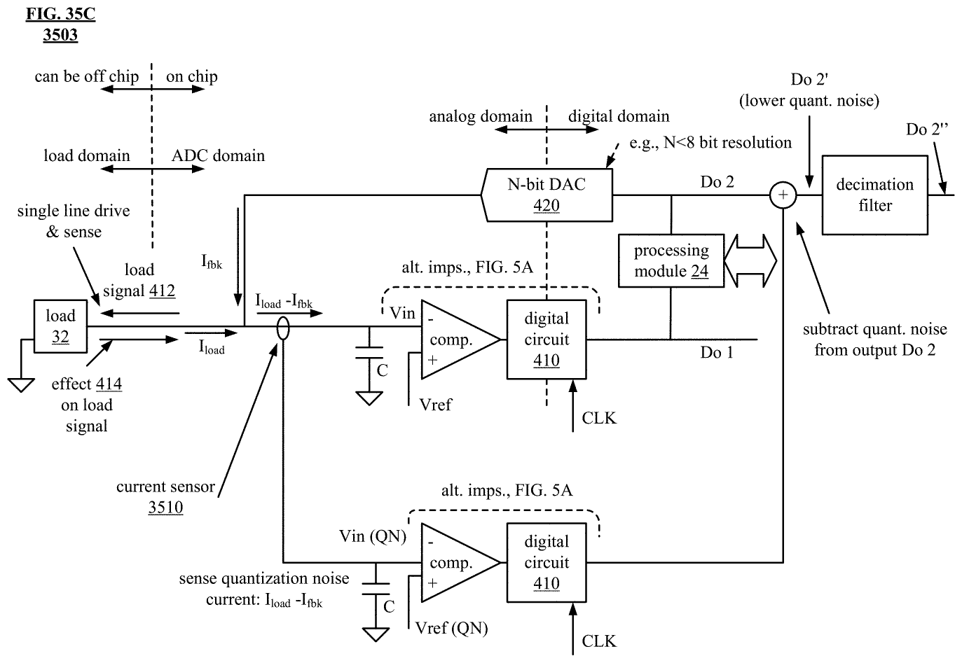

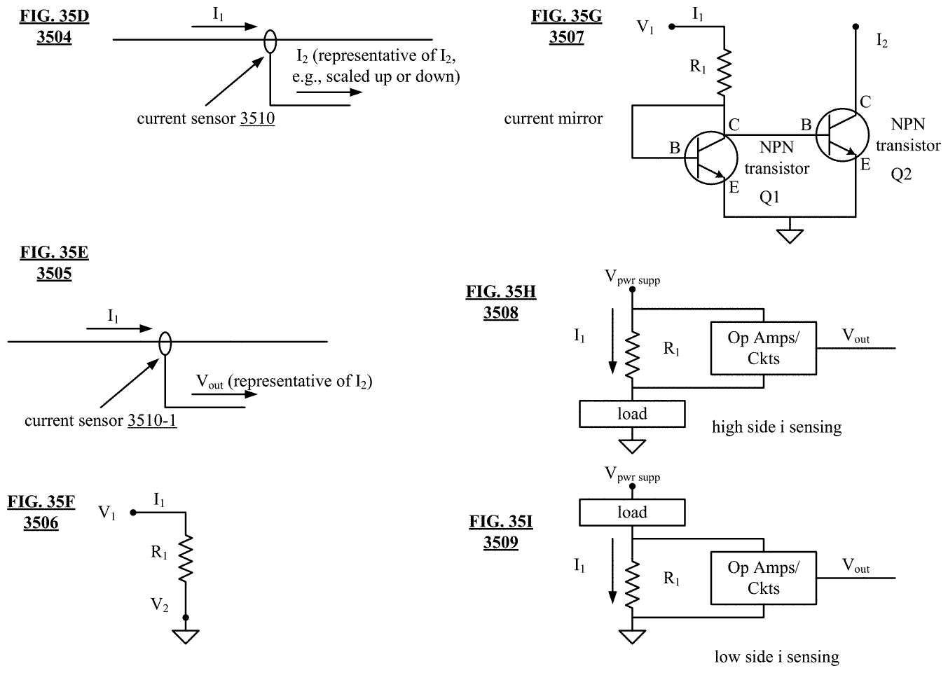

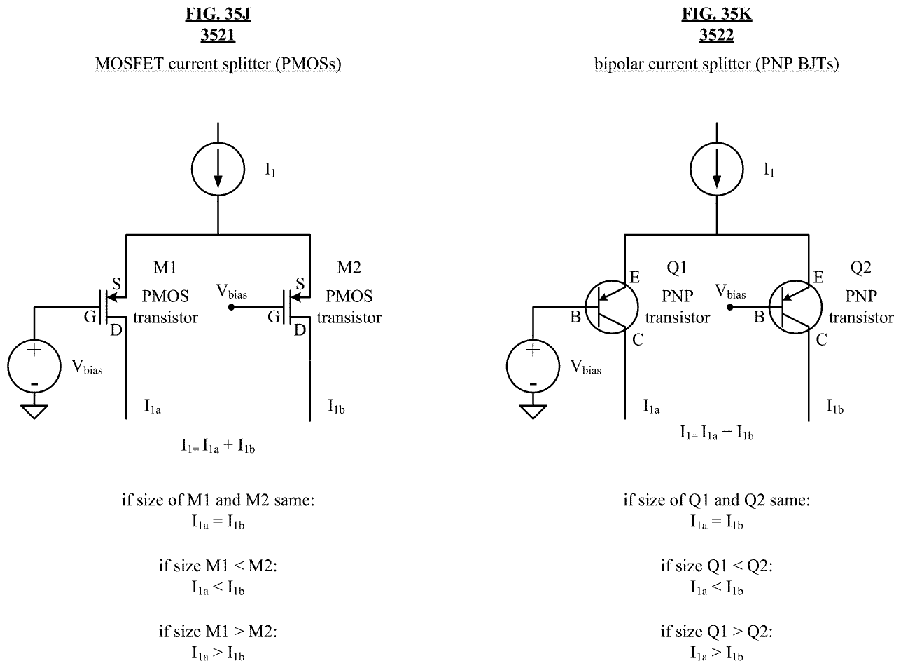

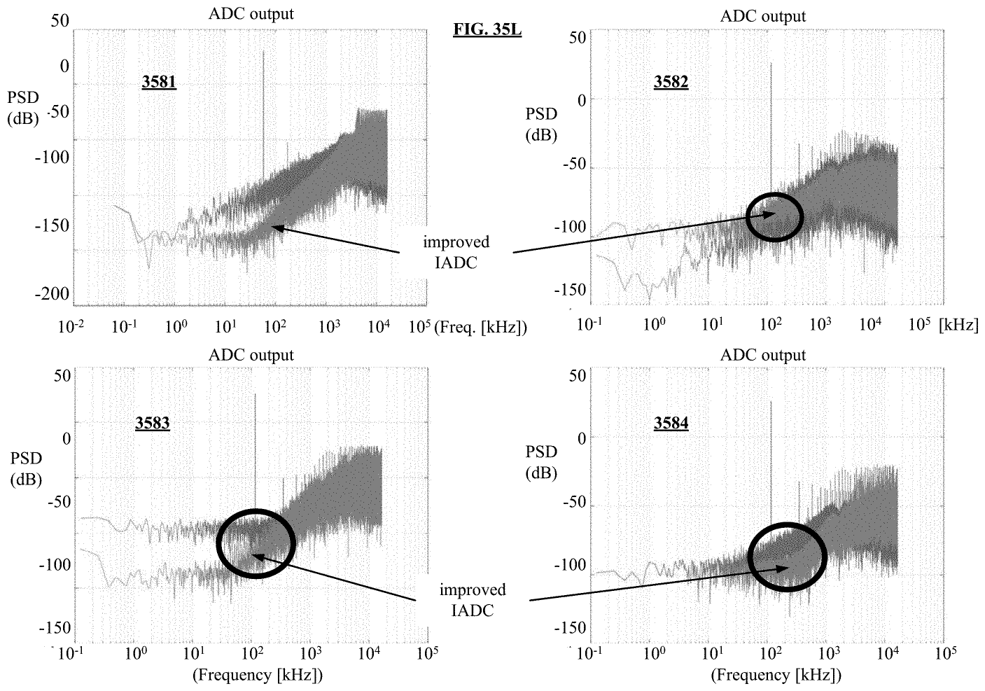

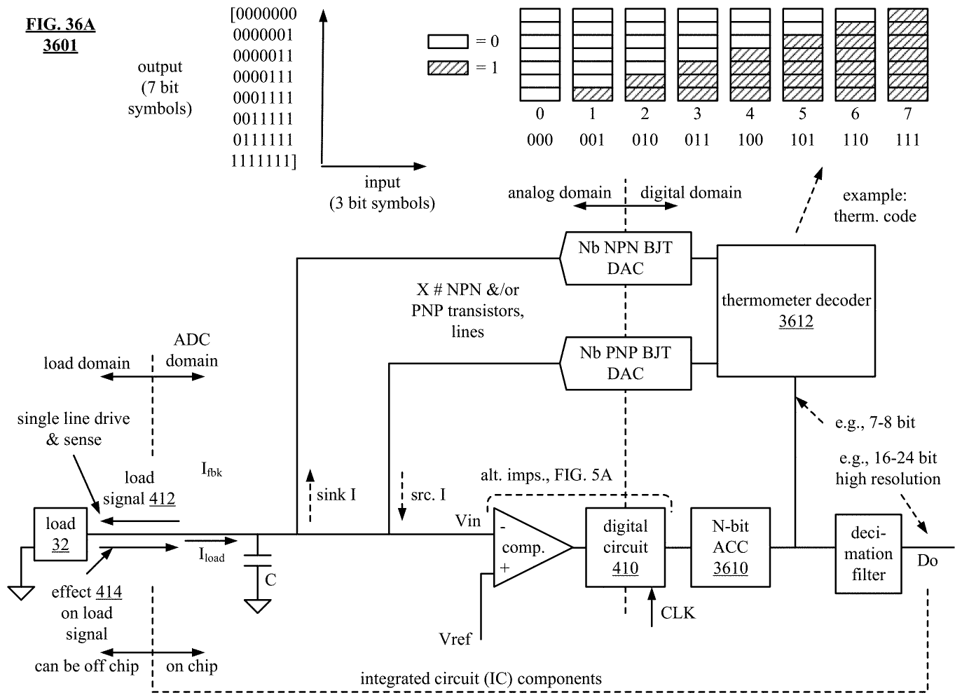

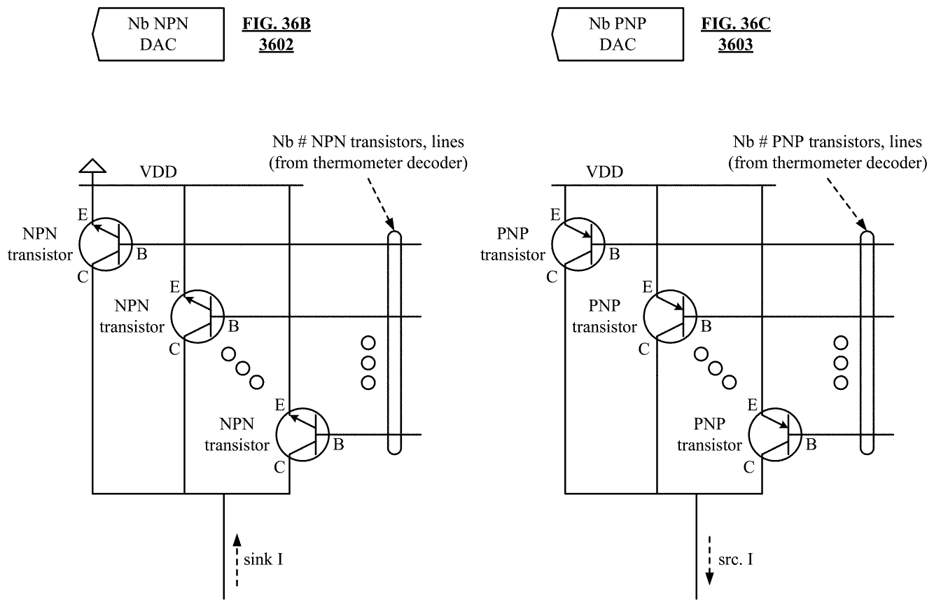

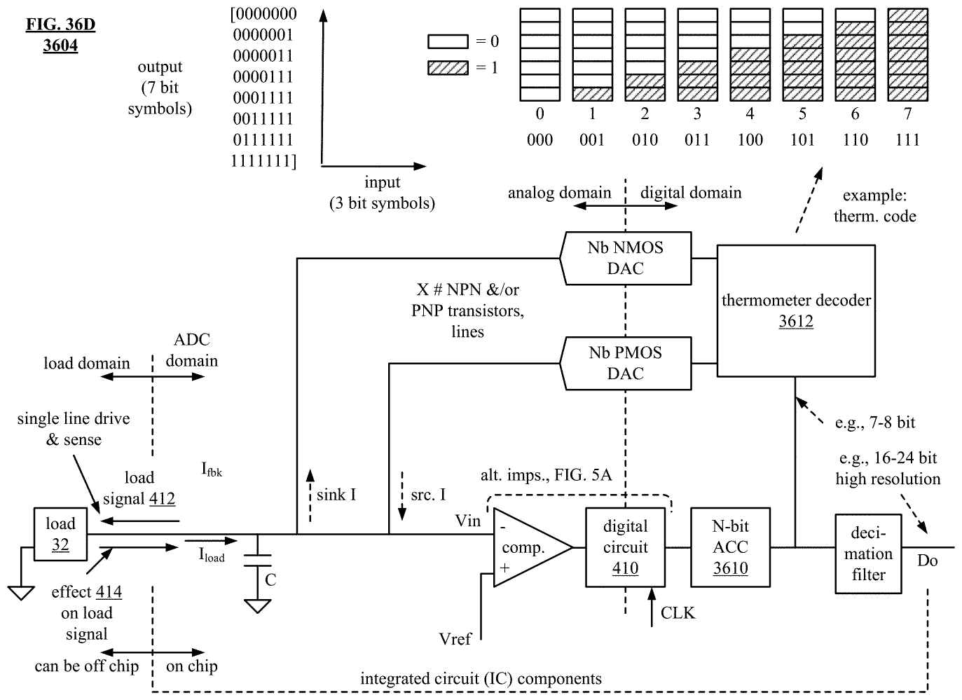

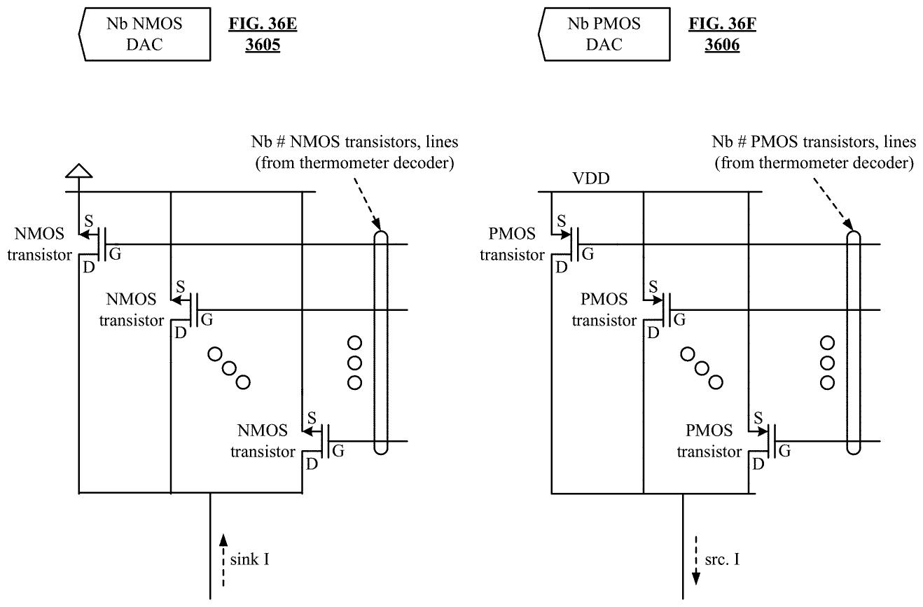

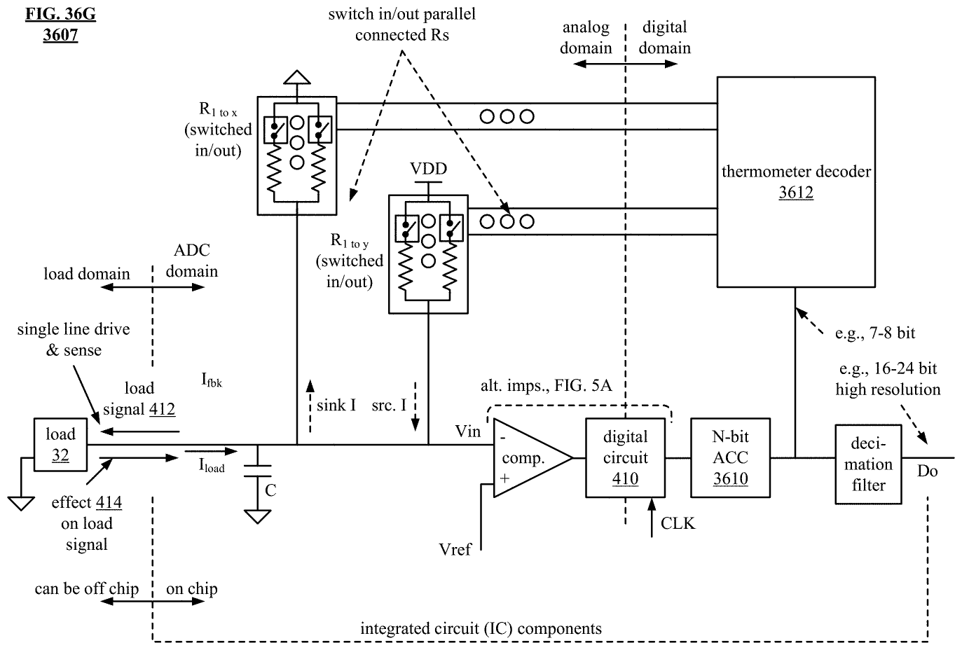

FIG. 5 is a schematic block diagram showing alternative embodiments 501, 502, 503, and 504 of various components may be implemented within an ADC in accordance with the present disclosure. Considering reference numeral 501, a comparator operates in cooperation with the digital circuit 410 as described above such that the combined operation of the comparator and the digital circuit 410 may be viewed as performing the analog to digital conversion of a signal that is the difference (e.g., Ve) between the input voltage, Vin, and the reference signal, Vref (e.g., Ve=Vref−Vin) to generate a digital signal of a particularly desired resolution, which may be viewed as M bits, where M is a positive integer greater than or equal to 1.

However, note that comparator and the digital circuit 410 may be implemented using any of a variety of other means while still facilitating proper operation of an ADC. With respect to reference numeral 502, a digital comparator, which may alternatively be described as a clock (or dynamic) comparator structure (latched comparator) is shown. This singular device performs the operation of both a comparator and the digital circuit 410 within a single device. For example, the digital comparator is clocked at a particular clocking frequency (CLK) and outputs a stream of 1s and/or 0s based on the comparison of Vref and Vin. In comparison to a comparator that operates continuously and that will output one of two values, such as either a high signal or low signal, continually as a function of time, a digital comparator outputs a 1 or 0 at each clock cycle based on the comparison of Vref and Vin in accordance with generating the Do 1 (e.g., 1 when Vref>Vin and 0 when Vref<=Vin, or vice versa). Also note that by only clocking such a digital comparator at certain intervals, a higher accuracy and lower power consumption can be achieved in comparison to a comparator that operates continuously.

With respect to reference numeral 503, the output of the comparator is provided to a sample and hold circuit (S&H) 510. Generally speaking, a S&H 510 holds, locks, or freezes its value at a constant level for a specified minimum period of time. This signal may be viewed as interpreted as a digital stream of 1s and/or 0s at the clocking frequency (CLK) in accordance with generating the Do 1. Note that such a S&H 510 may be implemented in a variety of ways including a circuit that stores electric charge and a capacitor and also employs one or more switching elements such that the circuit stores electric charge is built up over each of certain intervals, and the switching element connects the output of the circuit that stores electric charge to the output at certain in the boroughs such as the clocking frequency (CLK) in accordance with generating the Do 1.

With respect to reference numeral 504, the comparator and the digital circuit for 10 are replaced with a sigma-delta comparator, such as a one bit ADC, followed by a flip-flop circuit (FF) 520. The sigma-delta comparator provides a high or low signal to the FF 520 based on comparison of Vref and Vin, and the FF 520 outputs a 1 or 0 at each clock cycle such as the clocking frequency (CLK) based on the comparison of Vref and Vin in accordance with generating the Do 1.

Generally speaking, note that the implementation of a comparator and the digital circuit 410 as shown within any of the diagrams herein may be alternatively implemented in a variety of different ways including those shown within this diagram and/or their equivalents.

FIG. 5B is a schematic block diagram showing alternative embodiments 505a and 505b of servicing differential signaling using ADCs in accordance with the present disclosure. In addition to servicing and sensing single-ended lines and generating digital signals based thereon using ADCs as described herein, note that servicing and sensing of signals may also be performed. For example, with respect to reference numeral 505a, a first instantiation of an ADC 28 and the second instantiation of an ADC 28 are each respectively coupled via a respective single line to a different perspective load 32. Two respective load voltages, Vload1 and Vload2, are respectively received by the first and second instantiations of an ADC 28. Note that the first and second instantiation of an ADC 28 may be the same or may be different. Each respective instantiation of an ADC 28 in this example is operative to service and sense a respective single-ended line. Together, the first and second instantiations of an ADC 28 are operative to sense a differential signal that is based on the two load voltages, Vload1 and Vload2, and to generate a corresponding digital signal based thereon. In certain examples a processing module 24 is implemented to combine a first digital signal that is based on Vload1 and that is generated by the first instantiation of an ADC 28 and a second digital signal that is based on Vload2 and that is generated by the second instantiation of an ADC 28 to generate a resultant digital signal that corresponds to the differential voltage between the two load voltages, Vload1 and Vload2 (e.g., Vdiff=Vload1−Vload2, or Vdiff=Vload2−Vload1).

As another example, with respect to reference numeral 505b, a differential load 32-1 is serviced such that the two signal lines corresponding to the differential signaling provided by the differential load 32-1 are respectively provided to a first instantiation of an ADC 28 and a second instantiation of an ADC 28. Similarly, a processing module 24 may be implemented to generate a resulting digital signal that corresponds to the differential voltage associated with the differential load 32-1. The first instantiation of an ADC 28 in the second instantiation of an ADC 28 operate cooperatively to provide a load signal 1112 and to detect any effect 1114 on the load signal that is based on the differential load 32-1. A capacitor, C, is also implemented across the differential signal lines of the differential load 32-1. In alternative implementations, two respective single-ended capacitors, C, are respectively connected to the differential signal lines and to ground instead of the capacitor, C, connected to the differential lead lines (e.g., a first single ended capacitor, C, connected to one of the differential signal lines and to ground, and a second single ended capacitor, C, also connected to the other of the differential signal lines and to ground).

Note that any example, embodiment, etc. of any ADC described herein that is operative to sense an analog signal via a single line may be implemented within the first instantiation and the second instantiation of an ADC 28 in either of these examples corresponding to reference numerals 505a and 505b and/or their equivalents.

In an example of operation and implementation, an ADC (e.g., consider the ADC of FIG. 4) includes a capacitor that is operably coupled to a load and configured to produce a load voltage based on charging by a load current and a digital to analog converter (DAC) output current. In some examples, the ADC is coupled to the load via a single line. The ADC also includes a comparator. When enabled, the comparator operably coupled and configured to receive the load voltage via a first input of the comparator, receive a reference voltage via a second input of the comparator, and compare the load voltage to the reference voltage to generate a comparator output signal.

The ADC also includes a digital circuit that is operably coupled to the comparator. When enabled, the digital circuit operably coupled and configured to process the comparator output signal to generate a first digital output signal that is representative of a difference between the load voltage and the reference voltage.

The ADC also includes one or more processing modules operably coupled to the digital circuit and to memory, which may be included within the ADC or external to the ADC. When enabled, the one or more processing modules is configured to execute the operational instructions to process the first digital output signal to generate a second digital output signal that is representative of the difference between the load voltage and the reference voltage, wherein the second digital output signal includes a higher resolution than the first digital output signal.

The ADC also includes an N-bit digital to analog converter (DAC) that is operably coupled to the one or more processing modules. When enabled, the N-bit DAC operably coupled and configured to generate the DAC output current based on the second digital output signal. Note that N is a positive integer. The DAC output current tracks the load current, and the load voltage tracks the reference voltage.

Also, in some examples, the one or more processing modules, when enabled, is further configured to process the first digital output signal in accordance with performing band pass filtering or low pass filtering to generate the second digital output signal that is representative of the difference between the load voltage and the reference voltage.

In alternative examples, the comparator includes a sigma-delta comparator, and the digital circuit includes a clocked flip flop. In even other examples, a digital comparator includes both the comparator and the digital circuit (e.g., the digital comparator is operative to perform the functionality of both the comparator and the digital circuit). When enabled, the digital comparator operably coupled and configured to receive the load voltage via a first input of the comparator, receive a reference voltage via a second input of the comparator, and compare the load voltage to the reference voltage to generate the first digital output signal that is representative of the difference between the load voltage and the reference voltage.

In addition, in certain examples, the ADC includes a decimation filter coupled to the one or more processing modules. When enabled, the decimation filter is operably coupled and configured to process the second digital output signal to generate another digital output signal having a lower sampling rate and a higher resolution than the second digital output signal. Alternative to or in addition to, another decimation filter is coupled to the digital circuit. When enabled, the other decimation filter the operably coupled and configured to process the first digital output signal to generate another digital output signal having a lower sampling rate and a higher resolution than the first digital output signal.

FIG. 6 is a schematic block diagram of another embodiment 600 of an ADC that includes one or more decimation filters in accordance with the present disclosure. This diagram has similarities with respect to FIG. 4 with at least one difference being that a decimation filter 1 and/or a decimation filter 2 are implemented to process the Do 1 and the Do 2. For example, a decimation filter may be implemented to process a digital signal thereby lowering the sample rate thereof and increasing the output resolution. Consider a digital signal having a 12 bit resolution and a 100 kHz sampling rate. In one example, a decimation filter may operate to increase the resolution of that digital signal to be 24-bit resolution with a lower sampling rate of 50 kHz. In another example, decimation filter may operate to increase the resolution of that digital signal to be 18-bit resolution with a lower sampling rate of 75 kHz. generally speaking, any desired transformation of sampling rate and output resolution may be made performed using one or more decimation filters in accordance with any of the various examples of ADCs as described herein. In certain examples, only a decimation filter 1 is included thereby processing the Do 1 to generate the Do 2. In other examples, both a decimation filter 1 is included thereby processing the Do 1 to generate the Do 2 and a decimation filter 2 is included thereby processing the Do 2 to generate a Do 3 (e.g., Do 3 having a lower sampling rate and increased output resolution in comparison to the Do 2).

FIG. 7 is a schematic block diagram showing alternative embodiments 701, 702, and 703 of one or more decimation filters and/or processing modules that may be implemented to perform digital domain processing within an ADC in accordance with the present disclosure. With respect to reference numeral 701, a processing module 24 may be implemented to perform any of a variety of different digital signal processing operations on the Do 1 to generate the Do 2 such as decimation filtering, low pass filtering, bandpass filtering, etc. However, note that such an implementation of the output signals, such as Do 1 and the Do 2 may be implemented in different configurations as desired in particular applications.

For example, with respect to reference numeral 702, a decimation filter 1 and a decimation filter 2 may be implemented. As described above, only a decimation filter 1 may s included thereby processing the Do 1 to generate the Do 2. In other examples, both a decimation filter 1 is included thereby processing the Do 1 to generate the Do 2 and a decimation filter 2 is included thereby processing the Do 2 to generate a Do 3 (e.g., Do 3 having a lower sampling rate and increased output resolution in comparison to the Do 2).

With respect to reference numeral 703, the processing module 24 is configured to control the operation of the decimation filter 1 and decimation filter 2. For example, the processing module 24 is configured to the manner in which decimation filtering may be performed by the decimation filter 1 and/or decimation filter 2 (e.g., including the manner of conversion of digital signal resolution, the modification of sampling rate, etc.).

Note that any of the respective implementations shown within this diagram may be implemented within any other of the appropriate diagrams of an ADC as described herein.

FIG. 8 is a schematic block diagram of another embodiment 800 of an ADC in accordance with the present disclosure. This diagram is similar to that of FIG. 4 with at least one difference being that the capacitor, C, is replaced by an integrator. The integrator is implemented as an operational amplifier with a feedback capacitor, C. The use of the operational amplifier in place of only the capacitor, C, may be used for applications that are tailored to serve greater power than that of FIG. 4. Generally speaking, the feedback capacitor, C, implemented in cooperation with the operational amplifier serves a similar purpose of the capacitor, C, in FIG. 4 of being charged based on the load current and the output current from the N-bit DAC 420 thereby generating the Vin to be provided to the comparator and compared with Vref.

In an example of operation and implementation, an ADC (e.g., consider the ADC of FIG. 800) includes an operational amplifier (op amp) that is operably coupled to a load via a first op amp input. Also, a capacitor is operably coupled to the first op amp input and an op amp output. When enabled, the op amp is operably coupled and configured to generate an output voltage at the op amp output that corresponds to a load voltage that is based on charging of the capacitor by a load current and a digital to analog converter (DAC) output current. In some examples, the ADC is coupled to the load via a single line.

The ADC also includes a comparator that is operably coupled to the op amp. When enabled, the comparator operably coupled and configured to receive the output voltage via a first input of the comparator, receive a reference voltage via a second input of the comparator, and compare the load voltage to the reference voltage to generate a comparator output signal.

The ADC also includes a comparator a digital circuit that is operably coupled to the comparator. When enabled, the digital circuit is operably coupled and configured to process the comparator output signal to generate a first digital output signal that is representative of a difference between the load voltage and the reference voltage.

The ADC also includes a comparator one or more processing modules operably coupled to the digital circuit and to memory, which may be included within the ADC or external to the ADC. When enabled, the one or more processing modules is configured to execute the operational instructions to process the first digital output signal to generate a second digital output signal that is representative of the difference between the load voltage and the reference voltage. Note that the second digital output signal includes a higher resolution than the first digital output signal.

The ADC also includes an N-bit digital to analog converter (DAC) that is operably coupled to the one or more processing modules. When enabled, the N-bit DAC operably coupled and configured to generate the DAC output current based on the second digital output signal. Note that N is a positive integer. Also, the DAC output current tracks the load current, and the load voltage tracks the reference voltage.

In some examples, the one or more processing modules, when enabled, is further configured to process the first digital output signal in accordance with performing band pass filtering or low pass filtering to generate the second digital output signal that is representative of the difference between the load voltage and the reference voltage.

In some examples, the comparator includes a sigma-delta comparator, and the digital circuit includes a clocked flip flop. Also, in some other examples, a digital comparator includes both the comparator and the digital circuit (e.g., the digital comparator is operative to perform the functionality of both the comparator and the digital circuit). When enabled, the digital comparator operably coupled and configured to receive the load voltage via a first input of the comparator, receive a reference voltage via a second input of the comparator, and compare the load voltage to the reference voltage to generate the first digital output signal that is representative of the difference between the load voltage and the reference voltage.

In addition, in certain examples, the ADC includes a decimation filter coupled to the one or more processing modules. When enabled, the decimation filter is operably coupled and configured to process the second digital output signal to generate another digital output signal having a lower sampling rate and a higher resolution than the second digital output signal. Alternative to or in addition to, another decimation filter is coupled to the digital circuit. When enabled, the other decimation filter the operably coupled and configured to process the first digital output signal to generate another digital output signal having a lower sampling rate and a higher resolution than the first digital output signal.

FIG. 9 is a schematic block diagram of another embodiment 900 of an ADC in accordance with the present disclosure. This diagram has certain similarities with one or more of the previous diagrams with at least one difference being that a comparator and the digital circuit 410, or a functionally equivalent component to the comparator and the digital circuit 410, is replaced by a low resolution analog to digital converter (ADC), specifically, an M-bit ADC 910, where M is a positive integer greater than or equal to 1. In certain particular examples, M is a positive integer within the range of 1-4 (e.g., 1, 2, 3, or 4). Also, in certain particular examples, N of the N-bit DAC 420 is less than or equal to M. In certain specific examples, N<8 bit resolution. For example, if N=4, then M=3, 2, or 1. The Do 2 may be viewed as a high-resolution digital signal (N bit resolution) compared to the Do 1 (M bit resolution), such that M<N. In addition, in some examples, the Do 2 is a modified version of the Do 1 after having undergone any desired digital signal processing within the processing module 24.

Note that the M-bit ADC 910 is operative to generate the Do 1 as being an error signal that corresponds to a difference between Vin and Vref and having a resolution of M bits and that is output based on the clocking rate, CLK. For example, the Do 1 is a digital signal that corresponds to corresponds to an error signal, Ve, such that Ve=Vref−Vin or Vin−Vref.

The use of such an M-bit ADC 910 provides many performance improvements for certain applications including a reduction of quantization noise and an increase of the output resolution of the ADC, particularly with respect to the Do 1. For example, instead of Do 1 being a single bit resolution digital signal (e.g., a digital stream of 1s and/or 0s), the Do 1 in this diagram is a digital signal having a higher resolution (e.g., of 2, 3, or 4 bits). In some examples, the Do 1 is then provided to the processing module 24, and the processing module 24 is configured to perform any desired digital signal processing operation on the Do 1 to generate the Do 2 (e.g., increase the output resolution and lower the sampling rate, perform low pass filtering, perform bandpass filtering, etc.).

In this diagram, note that the Do 1 may be passed directly to the N-bit DAC 420 such that the Do 1 is used to drive the N-bit DAC 420. However, in certain examples, the Do 2 is used to drive the N-bit DAC 420 such as when it is a filtered and/or digital signal processed version of the Do 1.

In an example of operation and implementation, an ADC (e.g., the ADC of FIG. 900) includes a capacitor that is operably coupled to a load and configured to produce a load voltage based on charging by a load current and a digital to analog converter (DAC) output current. In some examples, the ADC is coupled to the load via a single line.

The ADC also includes an M-bit analog to digital converter (ADC). When enabled, the M-bit ADC operably coupled and configured to receive the load voltage, receive a reference voltage, and compare the load voltage to the reference voltage and generate a first digital output signal that is representative of a difference between the load voltage and the reference voltage.

The ADC also includes a processing module operably coupled to the digital circuit and to memory, which may be included within the ADC or external to the ADC. When enabled, the processing module is configured to execute the operational instructions to process the first digital output signal to generate a second digital output signal that is representative of the difference between the load voltage and the reference voltage. Note that the second digital output signal includes a higher resolution than the first digital output signal.

The ADC also includes an N-bit digital to analog converter (DAC) that is operably coupled to the processing module. When enabled, the N-bit DAC is operably coupled and configured to generate the DAC output current based on the second digital output signal. Note that the DAC output current tracks the load current, and the load voltage tracks the reference voltage. N is a first positive integer, and M is a second positive integer greater than or equal to 1. In some examples, N is greater than M. In other examples, N is the first positive integer that is less than or equal to 8, and M is the second positive integer that is greater than or equal to 1 and less than or equal to 4.

In even other examples, the one or more processing modules, when enabled, is further configured to process the first digital output signal in accordance with performing band pass filtering or low pass filtering to generate the second digital output signal that is representative of the load voltage.

In addition, in certain examples, the ADC includes a decimation filter coupled to the one or more processing modules. When enabled, the decimation filter is operably coupled and configured to process the second digital output signal to generate another digital output signal having a lower sampling rate and a higher resolution than the second digital output signal. Alternative to or in addition to, another decimation filter is coupled to the digital circuit. When enabled, the other decimation filter the operably coupled and configured to process the first digital output signal to generate another digital output signal having a lower sampling rate and a higher resolution than the first digital output signal.

FIG. 10 is a schematic block diagram of another embodiment 1000 of an ADC in accordance with the present disclosure. This diagram is similar to the previous diagram with at least one difference being that the capacitor, C, is replaced by an integrator. The integrator is implemented as an operational amplifier with a feedback capacitor, C. The use of the operational amplifier in place of only the capacitor, C, may be used for applications that are tailored to serve greater power than that of the previous diagram. Generally speaking, the feedback capacitor, C, implemented in cooperation with the operational amplifier serves a similar purpose of the capacitor, C, in the previous diagram of being charged based on the load current and the output current from the N-bit DAC 420 thereby generating the Vin to be provided to the comparator and compared with Vref.

In addition, with respect to all of these examples of an ADC, the ADC operates by providing an output current to the load 32 to cancel out the load current. This may be viewed as providing an output current that is equal to and opposite polarity to the load current. Again, note that such an ADC may be implemented not only to sense an analog signal associated with the load 32 but also to provide power and/or energy to the load 32 within implementations where the load 32 is not energized via another source. In some examples, this providing of power and/or energy from the ADC to the load 32 is performed simultaneously via a single line via which the ADC senses and analog signal associated with the load 32. Also, such an ADC may be implemented to perform sensing only of an analog signal associated with the load 32 without providing power and/or energy to the load 32.

FIG. 11 is a schematic block diagram of an embodiment 1100 of an ADC that is operative to process an analog differential signal in accordance with the present disclosure. This diagram shows an implementation of an ADC operating on a differential load 32-1 such that the ADC provides a load signal 1112 to the differential load 32-1 and also detects any effect 1114 on that load signal. In this diagram, a capacitor, C, is connected to the differential lead lines of the differential load 32-1. In alternative implementations, two respective single-ended capacitors, C, are respectively connected to the differential signal lines and to ground instead of the capacitor, C, connected to the differential lead lines (e.g., a first single ended capacitor, C, connected to one of the differential signal lines and to ground, and a second single ended capacitor, C, also connected to the other of the differential signal lines and to ground).

Also, the N-bit DAC 420 is replaced with a differential N-bit DAC 1120, wherein N is a positive integer. The N-bit DAC 420 is operative to generate a differential output current signal that is provided to the differential load 32-1 based on the Do 2.

A differential signal may be viewed as being composed of two respective voltages corresponding to the two differential signal lines, Vp and Vn (e.g., sometimes referred to as a positive voltage, Vp, is a negative voltage, Vn). In this diagram, a common mode (CM) analog circuit 1105 is implemented to convert the differential signal to a single-ended signal. For example, the CM analog circuit 1105 is operative to generate an input voltage, Vin, such that Vin=(Vn+Vp)/2. In some examples, note that the CM analog circuit 1105, the comparator, and the digital circuit 410 are all be implemented within a singular component or device that is operative to process a differential signal and to generate the Do 1 based thereon.

FIG. 12 is a schematic block diagram of another embodiment 1200 of an ADC that is operative to process an analog differential signal in accordance with the present disclosure. This diagram has certain similarities with the previous diagram with at least one difference being that the CM analog circuit 1105, the comparator, and the digital circuit 410, or a functionally equivalent component to CM analog circuit 1105, the comparator, and the digital circuit 410, is replaced by a low resolution analog to digital converter (ADC), specifically, a differential M-bit ADC 1210, where M is a positive integer greater than or equal to 1. In certain particular examples, M is a positive integer within the range of 1-4 (e.g., 1, 2, 3, or 4).

Also, in certain particular examples, N of the differential N-bit DAC 1120 is less than or equal to M. In certain specific examples, N<8 bit resolution. For example, if N=4, then M=3, 2, or 1. The Do 2 may be viewed as a high-resolution digital signal (N bit resolution) compared to the Do 1 (M bit resolution), such that M<N. In addition, in some examples, the Do 2 is a modified version of the Do 1 after having undergone any desired digital signal processing within the processing module 24.

In certain examples, note that the differential M-bit ADC 1210 is operative to generate the Do 1 as being an error signal that corresponds to a difference between Vin (such that Vin=(Nv+Vp)/2) and Vref and having a resolution of M bits and that is output based on the clocking rate, CLK. For example, the Do 1 is a digital signal that corresponds to corresponds to an error signal, Ve, such that Ve=Vref−Vin or Vin−Vref.

In other examples, note that the differential M-bit ADC 1210 is operative to generate the Do 1 as being an error signal that corresponds to a difference between the differential input voltage signal, Vin_diff, that is composed of Vn and Vp and a differential reference signal, Vref_diff (e.g., Vref_diff being a differential signal that is composed two different reference voltages, such as Vref1 and Vref2, and having a resolution of M bits and that is output based on the clocking rate, CLK. For example, the Do 1 is a digital signal that corresponds to corresponds to an error signal, Ve_diff, that corresponds to the difference between the two differential signals, Ve_diff=Vref_diff−Vin_diff or Vin_diff−Vref_diff.

The use of such a differential M-bit ADC 1210 provides many performance improvements for certain applications including a reduction of quantization noise and an increase of the output resolution of the ADC, particularly with respect to the Do 1. For example, instead of Do 1 being a single bit resolution digital signal (e.g., a digital stream of 1s and/or 0s), the Do 1 in this diagram is a digital signal having a higher resolution (e.g., of 2, 3, or 4 bits). In some examples, the Do 1 is then provided to the processing module 24, and the processing module 24 is configured to perform any desired digital signal processing operation on the Do 1 to generate the Do 2 (e.g., increase the output resolution and lower the sampling rate, perform low pass filtering, perform bandpass filtering, etc.).

In this diagram, note that the Do 1 may be passed directly to the differential N-bit DAC 1120 such that the Do 1 is used to drive the differential N-bit DAC 1120. However, in certain examples, the Do 2 is used to drive the differential N-bit DAC 1120 such as when it is a filtered and/or digital signal processed version of the Do 1.

FIG. 13 is a schematic block diagram of another embodiment 1300 of an ADC that is operative to process an analog differential signal in accordance with the present disclosure. This diagram has certain similarities to certain of the previous diagrams that operate based on differential signaling with at least one difference being that the capacitor, C, that was connected between the differential signal lines of the load 32-1 is replaced by a differential integrator with two respective feedback capacitors, C. The differential integrator is implemented as an operational amplifier with two respective feedback capacitors, C, and is operative to generate a differential input signal is based on Vn and Vp. The use of the operational amplifier in place of only the capacitor, C, two respective feedback capacitors, C may be used for applications that are tailored to serve greater power than that of the previous diagram. Generally speaking, the two respective feedback capacitors, C, implemented in cooperation with the differential operational amplifier serve a similar purpose of the capacitor, C, that was connected between the differential signal lines of the load 32-1 in the previous diagram of being charged based on the differential load current and the differential output current from the differential N-bit DAC 1120 thereby generating the Vin to be provided to the comparator and compared with Vref.

Note that the CM analog circuit 1105, the comparator, and the digital circuit 410 may alternatively be replaced with a differential M-bit ADC 1210 such as in accordance with the previous diagram.

FIG. 14A is a schematic block diagram of an embodiment 1401 an ADC that is operative to perform voltage measurement in accordance with the present disclosure. This diagram has some similarities with the previous diagrams with at least one difference being that the load 32 is replaced by the load voltage 32-1, which may be a voltage of any of a number of devices including the load 32. Examples of such a load voltage 32-1 include any of the voltage of an electrode, sensor, transducer, etc. Another difference within this diagram is that a resistor, R, is placed in line with the single line that connects her couples the ADC that is operative to perform voltage measurement and the load voltage 32-1. For example, the load voltage 32-1, when dropping across the resistor, R, to generate the input voltage, Vin, will provide a current signal that will charge the capacitor, C, that is provided to one of the inputs of the comparator. Generally speaking, a load voltage 32-1 can be measured by inserting a resistor, R, between the load voltage 32-1 and the ADC so as to facilitate conversion of the load voltage 32-1 to a current, Iin, that is equal to the difference between the load voltage 32-1, Vload, and Vin, such that Iin=(Vload−Vin)/R. note also that a prince impedance circuitry may alternatively be implemented that is operative to convert a voltage to a current signal such that the current signal may be sensed by an ADC as described herein.

FIG. 14B is a schematic block diagram of an embodiment 1402 an transimpedance amplifier that may be implemented within an ADC that is operative to perform voltage measurement in accordance with the present disclosure. The trans-impedance circuitry includes a buffer, operational amplifier, etc. having a first input coupled to the ground potential, and a second input coupled to a node that is sourcing or sinking current, such as the node connected to the N-bit DAC 420. An impedance (shown as an R or generically a Z, which may have inductive and/or capacitive reactants components) is also coupled from the second input to the output of the buffer, operational amplifier, etc. A current, I, that flows through the impedance generates an output voltage, V, that is based on the impedance times the current, I (e.g., V=R×I or Z×I). Such a trend impedance amplifier, or any appropriate circuit or component that is operative to perform voltage to current signal conversion, or vice versa, may be used in place of the resistor shown within the previous diagram.

FIG. 15 is a schematic block diagram showing an embodiment 1500 of digital domain filtering within an ADC in accordance with the present disclosure. This diagram shows an alternative implementation to having a processing module 24 implemented to receive him perform any desired digital signal processing on the Do 1 and to generate the Do 2. Specifically, a filter 1510 is implemented to process the Do 1 to generate the Do 2. Note that the filter 1510 may be of any desired type of digital filter. In certain examples, bandpass filtering or low pass filtering is performed by the filter 1510 to filter out high-frequency quantization noise within the Do 1 in accordance with generating the Do 2. Possible examples of a low pass filter or low pass filter operation may be implemented based on an accumulator or in integrator. For example, consider an application tailored for detecting a DC analog signal, or for detecting an analog signal having a frequency within the voice frequency bands such as 20 kHz to 100 kHz, then appropriate low pass filtering or bandpass filtering is performed by the filter 1510 to filter out high-frequency quantization noise within the Do 1 in accordance with generating the Do 2.

In certain examples, note that a processing module 24 may be in communication with the filter 1510 such that the particular filtering to be performed by the filter 1510 is configurable based on control signaling from the processing module 24. For example, consider the filter 1510 to be a configurable or selectable filter that includes one or more options of bandpass filtering or low pass filtering. The processing module 24 is configured to select a first type of filtering to be performed at or during a first time and a second type of filtering to be performed at or during a second time, and so on.

FIG. 16 is a schematic block diagram showing an embodiment 1600 of digital domain filtering using cascaded filters within an ADC in accordance with the present disclosure. This diagram shows digital signal processing based on a cascade of N and pass filters or N low pass filters. In a particular example, N=10. The gain elements, K1 through KN, are amplification constants that are used to stabilize the feedback loop from any digital output signal that is generated by the respective cascade of N filter (e.g., filter 1 through filter N) that provide the digital input control signal to the N-bit DAC 420. The different respective game factors operate to stabilize the feedback that is provided to the N-bit DAC 420. Note that this implementation is operative to provide a number of different respective digital output signals, shown as Do 1, Do 2 through Do N as corresponding to the respective outputs from the respective cascade of N filter (e.g., filter 1 through filter N). Note that any one or more decimation filters may also be implemented to perform decimation filtering of the digital output signals, shown as Do 1, Do 2 through Do N as corresponding to the respective outputs from the respective cascade of N filter (e.g., filter 1 through filter N).

FIG. 17 is a schematic block diagram showing another embodiment 1700 of digital domain filtering using configurable/adjustable cascaded filters within an ADC in accordance with the present disclosure. This diagram is similar to the previous diagram with at least one difference being that one or more processing modules 24 is coupled or connected to each of the respective gain elements (K1 through KN) and the respective cascade of N filter (e.g., filter 1 through filter N). The one or more processing modules 24 is configured to adjust a gains of the respective gain elements (K1 through KN) and mean particular characteristics by which filtering is performed by the respective cascade of N filter (e.g., filter 1 through filter N).

For example, the one or more processing modules 24 is configured to select a first set of gains for the respective gain elements (K1 through KN) and a first type of filtering to be performed by the respective cascade of N filter (e.g., filter 1 through filter N) at or during a first time and a second set of gains for the respective gain elements (K1 through KN) and a second type of filtering to be performed by the respective cascade of N filter (e.g., filter 1 through filter N) at or during a second time.

FIG. 18 is a schematic block diagram showing an embodiment 1800 of one or more processing modules implemented to perform digital domain filtering within an ADC in accordance with the present disclosure. This diagram includes one or more processing modules 24 that is operative to perform the filtering pictorially illustrated within the previous diagram. For example, one or more processing modules 24 may be implemented perform any desired digital signal processing of any of the respective digital output signals, shown as Do 1, Do 2 through Do N including the digital signal processing pictorially described with respect to the previous diagram. In this diagram, the one or more processing modules 24 itself for themselves performs the digital signal processing. In the previous diagram, separate and distinct digital signal processing components are implemented, ending one or more processing modules 24 of that diagram are operative to control and configure the manner in which those digital signal processing components operate.

In addition, alternative examples of an ADC may be implemented using anon-linear N-bit DAC that operates based on a non-linear function. For example, a non-linear N-bit DAC is operative to provide an output current based on the non-linear function of the digital input signal provided to it. Such a non-linear function may be described also as a non-linear companding function such that companding corresponds to a non-linear response of the ADC based on the signal it receives and/or senses. In such a non-linear N-bit DAC, the output current is a non-linear function of the input.

Considering one possible example of an ADC that includes a non-linear N-bit DAC, the digital output signal (e.g., the Do 1 and/or the Do 2 signal) that is generated by such an ADC is a non-linear function of the analog signal that it is sensing. Consider an ADC that includes a non-linear N-bit DAC and operates based on a logarithmic function when sensing a current signal, then the digital output signal (e.g., the Do 1 and/or the Do 2 signal) is a logarithmic function of the input current. Such an ADC that includes a non-linear N-bit DAC may be referred to as a companding ADC. Generally speaking, such an ADC that provides for a non-linear response when generating a digital output signal based on the analog signal that it is sensing may be referred to as a companding ADC.

Note that such a companding ADC may also be implemented to perform simultaneous driving and sensing of a signal via that single line that connects or couples to the load. For example, such an ADC is operative to drive an analog signal (e.g., current and/or voltage) of a load 32. With respect to implementations that operate in accordance with sensing analog current signals, such a companding ADC is also operative to sense current signals within an extremely broad range including very low currents (e.g., currents below the 1 pico-amp range, within the 10s of pico-amps range, below the 1 nano-amp range, within the 10s of nano-amps range, below the 1 micro-amp range, within the 10s of micro-amps range, etc.) and also up to relatively much larger currents (e.g., currents in the 10s milli-amps range, 100s milli-amps range, or even higher values of amps range, etc.). In some examples, such as with respect to detecting currents that are provided from a photodetection or photodiode component, such a companding ADC is also operative to sense current signals below the 1 pico-amp range, currents within the 100s of micro-amps range, etc.

Also, in some examples, when using appropriately provisioned components (e.g., higher current, higher power, etc.), much higher currents can also be sensed using architectures and topologies in accordance with a companding ADC as described herein. For example, such a companding ADC implemented based on architectures and topologies, as described herein, using appropriately provisioned components that are operative to sense even higher currents (e.g., is of amps, 10s of amps, or even higher values of amps range, etc.).

In addition, note that various implementations of such a companding ADC may be implemented to cover a number of decades orders of magnitude. For example, consider a companding ADC that is implemented to detect current signals radiating from the 10s of pico-amps to ones of milli-amps. Such a companding ADC would cover a dynamic range of 7-8 decades or 7-8 orders of magnitude. Within such an example, such a very broad dynamic range may be divided using a log scale into the 7-8 decades, such that there are a few data points within each particular decade. Note also that there is a trade-off regarding the resolution of the digital output signal (e.g., the Do 1 and/or the Do 2 signal) that is generated by such a companding ADC and range of current signals that may be sensed. For example, when the dynamic range of signals to be sensed by such a companding ADC is relatively large, then there can be limitations on sensing very low currents with a high degree of accuracy.

Generally speaking, the broader the dynamic range of signals to be sensed, then a higher resolution of the digital output signal (e.g., the Do 1 and/or the Do 2 signal) provides for a higher degree of accuracy, particularly when sensing very low currents. Consider an example in which currents within a dynamic range of 10s of pico-amps to 100s of micro-amps is to be sensed (e.g., within a photodetection or photodiode component), then generating a digital output signal using a certain number of bits (e.g., a resolution of 12 bits) may be insufficient to cover the entire range. Within such a particular example, increasingly resolution of the digital output signal (e.g., to a resolution of 16 bits) can help facilitate sensing of signals with higher resolution and also assist sensing very low currents with a high degree of accuracy.

Several the following diagrams have similarities to the prior diagrams with at least one difference being that a non-linear N-bit DAC 1920 is implemented to generate the current that is output to a load that matches or tracks the current of the load. Similarly, as described with respect to other examples of an ADC, the companding ADCs of these subsequent diagrams also operate by providing an output current to the load 32 to cancel out the load current. This may be viewed as providing an output current that is equal to and opposite polarity to the load current. Note also that such a companding ADC may be implemented not only to sense an analog signal associated with the load 32 but also to provide power and/or energy to the load 32 within implementations where the load 32 is not energized via another source. In some examples, this providing of power and/or energy from the companding ADC to the load 32 is performed simultaneously via a single line via which the companding ADC senses and analog signal associated with the load 32. Also, such a companding ADC may be implemented to perform sensing only of an analog signal associated with the load 32 without providing power and/or energy to the load 32.

Generally speaking, with respect to such non-linear N-bit DACs, such as the non-linear N-bit DAC 1920, the output current provided there from is a non-linear function of the Do 2. Therefore, the Do 2 itself is also an inverse function of the load current, given that the output current from the non-linear N-bit DAC 1920 is operative to match or track the current of the load (e.g., being equal and opposite of the current of the load thereby minimizing the error signal that is based on the difference between Vref and Vin).

FIG. 19 is a schematic block diagram of an embodiment 1900 of an ADC that includes a non-linear N-bit digital to analog converter (DAC) in accordance with the present disclosure. This diagram is similar to certain of the previous diagrams (e.g., FIG. 4) that include a comparator and a digital circuit 410 that generates the Do 1 that is provided to the processing module 24. The processing module 24 processes the Do 1 to generate the Do 2. Also, an analog capacitor, C, is connected to a node that couples the load 32 to the companding ADC (e.g., an ADC that includes a non-linear N-bit digital to DAC, an ADC that provides for a non-linear response when generating a digital output signal based on the analog signal that it is sensing).

However, in this diagram, a non-linear N-bit DAC 1920 is implemented to generate the current signal that is provided to the node that connects or couples the companding ADC to the load 32 to match and track the current signal of the load.

Many of the subsequent diagrams include similar components and operate similarly with at least one difference being that they operate as companding ADCs such that they provide for a non-linear response when generating a digital output signal based on the analog signal that it is sensing. Many of the diagrams include a non-linear N-bit DAC 1920 is implemented in place of the N-bit DAC 420.

FIG. 20 is a schematic block diagram of another embodiment 2000 of an ADC that includes a non-linear N-bit DAC in accordance with the present disclosure. This diagram is similar to FIG. 8 with a difference being that a non-linear N-bit DAC 1920 is implemented in place of the N-bit DAC 420.

FIG. 21 is a schematic block diagram of another embodiment 2100 of an ADC that includes a non-linear N-bit DAC in accordance with the present disclosure. This diagram is similar to FIG. 9 with a difference being that a non-linear N-bit DAC 1920 is implemented in place of the N-bit DAC 420.

FIG. 22 is a schematic block diagram of another embodiment 2200 of an ADC that includes a non-linear N-bit DAC in accordance with the present disclosure. This diagram is similar to FIG. 10 with a difference being that a non-linear N-bit DAC 1920 is implemented in place of the N-bit DAC 420.

FIG. 23 is a schematic block diagram of an embodiment 2300 of an ADC that includes a non-linear N-bit DAC that is operative to process an analog differential signal in accordance with the present disclosure. This diagram is similar to FIG. 11 with a difference being that a differential non-linear N-bit DAC 2320 is implemented in place of the differential N-bit DAC 1120.

FIG. 24 is a schematic block diagram of another embodiment 2400 of an ADC that includes a non-linear N-bit DAC that is operative to process an analog differential signal in accordance with the present disclosure. This diagram is similar to FIG. 12 with a difference being that a differential non-linear N-bit DAC 2320 is implemented in place of the differential N-bit DAC 1120.

FIG. 25 is a schematic block diagram of an embodiment 2500 an ADC that includes a non-linear N-bit DAC and that is operative to perform voltage measurement in accordance with the present disclosure. This diagram is similar to FIG. 14A with a difference being that a non-linear N-bit DAC 1920 is implemented in place of the N-bit DAC 420. For example, implementing an appropriate element in-line between the companding ADC and a load voltage 32-1 (e.g., a resistor, R, a trans-impedance circuitry, and/or any appropriate complement to convert voltage to current, etc.) facilitates the conversion of the load voltage 32-1 to a load current that may be detected using such a companding ADC. In such an example, the non-linear N-bit DAC 1920 within the companding ADC operates based on a function of Do 2. In an example that includes a resistor, R, implemented non-linear N-bit DAC 1920, the Do 2 itself is an inverse function of the load voltage 32-1 divided by R (e.g., function of Vload/R).

Certain of the following diagrams show the use of one or both of a PNP transistor (alternatively, Positive-Negative-Positive Bipolar Junction Transistor (BJT)) or an NPN transistor (alternatively, Negative-Positive-Positive BJT) to implement the non-linear conversion function. For example, the use of one or both of a PNP transistor or NPN transistor may be used to implement a logarithmic conversion function.

In addition, certain of the following diagrams operate using a N-bit DAC 420-1 that provides an output voltage signal to be received by the base of an NPN transistor or a PNP transistor. In such examples, one or more of an NPN transistor or a PNP transistor is implemented to provide the current that matches or tracks the load current. Certain examples operate by sourcing current, and others operate by sinking current. Even other examples operate by providing both functionality of sourcing current and sinking current as may be required to match or track the load current.

FIG. 26A is a schematic block diagram of an embodiment 2601 an ADC that includes a PNP transistor (alternatively, Positive-Negative-Positive Bipolar Junction Transistor (BJT)) implemented to source current in accordance with the present disclosure.

Generally speaking, a BJT is a type of transistor including three terminals, a base (B), a collector (C), and an emitter (E). Such a BJT includes two semiconductor junctions that share a thin doped region in between them. Considering an NPN transistor, a thin p-doped region is implemented in between two n-type semiconductor regions thereby forming the two semiconductor junctions. Considering an PNP transistor, a thin n-doped region is implemented in between two p-type semiconductor regions thereby forming the two semiconductor junctions.

With respect to such a transistor, the collector current, I_{c}, as a function of the voltage between the base (B) and emitter (E) is as follows:

$${I}_{C} = {I}_{Z} ( {e}^{\frac{{g}^{V} BE}{kT}} - 1 ) ,$$

where, based on the Shockley diode equation or the diode law,

Iₛ the reverse bias saturation current (alternatively referred to as scale current);

V_{BE} is the voltage across the semiconductor junction;

V_{T} is the thermal voltage, kT/q, which is the Boltzmann constant, k, times temperature, T, divided by electron charge, q.

As such, the value of V_{BE} is the output voltage of the N-bit DAC 420-1, which operates based on a full-scale voltage shown as Vfull_scale, such that the N-bit DAC 420-1 is operative to provide an output voltage up to and including the full-scale voltage shown as Vfull_scale.

Given that V_{BE} is the output voltage of the N-bit DAC 420-1, then it is also the conversion of the Do 2 to an analog signal.

Therefore, the Do 2 is a an inverse function of the above equation showing the collector current, as follows:

$$D o 2 = {V}_{B E} \approx \frac{k T}{q} ln ( \frac{{I}_{C}}{{I}_{S}} )$$

The full-scale voltage shown as Vfull_scale is a reference voltage for the N-bit DAC 420-1, which also operates to control the full-scale output current. FIG. 28B and FIG. 28C show examples by which a temperature independent full-scale reference circuit may be implemented.

Referring again to FIG. 26A, this diagram shows a PNP transistor implemented to source current to a node that connects to the load 32 to match and track the load current.

FIG. 26B is a schematic block diagram of an embodiment 2602 an ADC that includes an NPN transistor (alternatively, Negative-Positive-Positive BJT) implemented to sink current in accordance with the present disclosure. This diagram shows an NPN transistor implemented to sink current from a node that connects to the load 32 to match and track the load current.

FIG. 27 is a schematic block diagram of an embodiment 2700 an ADC that includes both a PNP transistor implemented to source current and an NPN transistor implemented to sink current in accordance with the present disclosure. This diagram shows both a PNP transistor implemented to source current to a node that connects to the load 32 to match and track the load current and also an NPN transistor implemented to sink current from a node that connects to the load 32 to match and track the load current. In cooperation with one another, both the PNP transistor and the NPN transistor can operate either to sink or source current as may be needed to match and track the load current.

FIG. 28A is a schematic block diagram of an embodiment 2801 an ADC that includes diodes implemented to source and/or sink current in accordance with the present disclosure. This diagram shows the two diodes implemented and controlled using switches, such as being controlled by the processing module 24, to provide for sinking or sourcing current to or from the node that connects to the load 32 to match and track the load current.

FIG. 28B is a schematic block diagram of an embodiment 2802 a PNP transistor diode configuration operative to generate a full scale voltage signal in accordance with the present disclosure. In addition, note that one way to have a temperature independent full-scale reference current is to use a PNP or NPN diode configuration to generate the full-scale voltage (Vfull_scale) based on an applied reference current Iref. This is to form a current mirror. The output bipolar transistor current to the load is a mirror copy of the reference current, Iref, which is scaled by the voltage value provided by the N-bit DAC 420-1. The reference current is applied to the collector of the PNP (or NPN) and the base is connected to the collector to form a diode configuration. The base voltage of the PNP is the full-scale voltage (Vfull_scale) that is applied to the N-bit DAC. Such a configuration for a PNP transistor is shown with respect to FIG. 28B. Such a configuration for an NPN transistor is shown with respect to FIG. 28B.

FIG. 28C is a schematic block diagram of an embodiment 2803 an NPN transistor diode configuration operative to generate a full scale voltage signal in accordance with the present disclosure.

Such implementations of a companding ADC using one or more NPN transistors, PNP transistors, and/or diodes provide a number of advantages over prior art ADCs. For example, they may be operated using extremely low power. Also, they operate to provide direct conversion of a digital output (e.g., Do 2) that is logarithmically proportional to the input current. Moreover, using an appropriate implementation, such as that described to provide a temperature independent full-scale reference current, such a companding ADC is temperature independent as opposed to the prior art ADCs, which are temperature dependent. Also, the accuracy and operation of such a companding ADC is independent of the Iₛ current of the bipolar transistor [reverse bias saturation current (alternatively referred to as scale current)], which can have very wide tolerance across components.

Certain of the following diagrams show the use of one or both of a P-channel or P-type metal-oxide-semiconductor field-effect transistor (MOSFET) (alternatively, PMOS transistor) or an N-channel or N-type metal-oxide-semiconductor field-effect transistor (MOSFET) (alternatively, NMOS transistor) to implement the non-linear conversion function. For example, the use of one or both of a PMOS transistor or an NMOS transistor may be used to implement a logarithmic conversion function.

In addition, certain of the following diagrams operate using a N-bit DAC 420-1 that provides an output voltage signal to be received by the gate of an NMOS transistor or a PMOS transistor. In such examples, one or more of an NMOS transistor or a PMOS transistor is implemented to provide the current that matches or tracks the load current. Certain examples operate by sourcing current, and others operate by sinking current. Even other examples operate by providing both functionality of sourcing current and sinking current as may be required to match or track the load current.

FIG. 29A is a schematic block diagram of an embodiment 2901 an ADC that includes a P-channel or P-type metal-oxide-semiconductor field-effect transistor (MOSFET) (alternatively, PMOS transistor) implemented to source current in accordance with the present disclosure.

For example, the use of one or both of an NMOS transistor or a PMOS transistor operates as a square root conversion function. For example, the drain current, ID, of a MOSFET is as follows:

$${I}_{D} = \frac{μ {C}_{OX}}{2} \frac{W}{L} {( {V}_{G S} - {V}_{T} )}^{2} ,$$

where

V_{GS} is the voltage across the gate (G) to source (S) junction of the MOSFET;

V_{T} is the thermal voltage, kT/q, which is the Boltzmann constant, k, times temperature, T, divided by electron charge, q;

W is gate width;

L is gate length;

μCₒₓ is a process transconductance parameter; and

μCₒₓ (W/L) is a MOSFET transconductance parameter.

As such, the voltage across the gate (G) to source (S) junction of the MOSFET, V_{GS}, is the output voltage of the N-bit DAC 420-1. As such, the value of V_{GS} is the output voltage of the N-bit DAC 420-1.

Given that V_{GS} is the output voltage of the N-bit DAC 420-1, then it is also the conversion of the Do 2 to an analog signal.

Therefore, the Do 2 (shown as Do in the equation below) is a an inverse function of the above equation showing the drain current, ID, as follows:

$$Do = {V}_{G S} = \sqrt{\frac{2 L}{μ {C}_{OX} W} {I}_{D}} - {V}_{T}$$

As can be seen, this shows the Do 2 (shown as Do in the equation above) as being a square root function of the input current, which is the drain current, ID.

Also, note that parallel measurement similar to the log ratio-metric measurement may be used to remove the dependence on V_{T}, which is the thermal voltage, kT/q, and which varies as a function of temperature. For example, a similar diode configuration and Iref current mirror as in the bipolar transistor variant can be applied here with respect to MOSFET devices.

For example, consider generating a first digital output signal, shown as Do 1 below, and also a first digital output signal, shown as Do2 below:

$${Do}_{1} = {V}_{G S} = \sqrt{\frac{2 L}{μ {C}_{OX} W} {I}_{D 1}} - {V}_{T} , and$$

$${Do}_{2} = {V}_{G S} = \sqrt{\frac{2 L}{μ {C}_{OX} W} {I}_{D 2}} - {V}_{T} ,$$

then the difference between them is as follows:

$${Do}_{1} - {Do}_{2} = \sqrt{\frac{2 L}{μ {C}_{OX} W} {I}_{D 1}} - \sqrt{\frac{2 L}{μ {C}_{OX} W} {I}_{D 2}} ,$$

which is temperature independent and has no dependence on V_{T}, which is the thermal voltage, kT/q.

Referring again to FIG. 29A, this diagram shows a PMOS transistor implemented to source current to a node that connects to the load 32 to match and track the load current.

FIG. 29B is a schematic block diagram of an embodiment 2902 an ADC that includes an N-channel or N-type metal-oxide-semiconductor field-effect transistor (MOSFET) (alternatively, NMOS transistor) implemented to sink current in accordance with the present disclosure. This diagram shows an NMOS transistor implemented to sink current from a node that connects to the load 32 to match and track the load current.

FIG. 30 is a schematic block diagram of an embodiment 3000 an ADC that includes both a PMOS transistor implemented to source current and an NMOS transistor implemented to sink current in accordance with the present disclosure. This diagram shows both a PMOS transistor implemented to source current to a node that connects to the load 32 to match and track the load current and also an NMOS transistor implemented to sink current from a node that connects to the load 32 to match and track the load current. In cooperation with one another, both the PMOS transistor and the NMOS transistor can operate either to sink or source current as may be needed to match and track the load current.

FIG. 31 is a schematic block diagram showing an embodiment 3100 of digital domain filtering within an ADC that includes a non-linear N-bit DAC in accordance with the present disclosure. This diagram is similar to FIG. 15 with a difference being that a non-linear N-bit DAC 1920 is implemented in place of the N-bit DAC 420.

FIG. 32 is a schematic block diagram showing an embodiment 3200 of digital domain filtering using cascaded filters within an ADC that includes a non-linear N-bit DAC in accordance with the present disclosure. This diagram is similar to FIG. 16 with a difference being that a non-linear N-bit DAC 1920 is implemented in place of the N-bit DAC 420.

FIG. 33 is a schematic block diagram showing another embodiment 3300 of digital domain filtering using configurable/adjustable cascaded filters within an ADC that includes a non-linear N-bit DAC in accordance with the present disclosure. This diagram is similar to FIG. 17 with a difference being that a non-linear N-bit DAC 1920 is implemented in place of the N-bit DAC 420.

FIG. 34 is a schematic block diagram showing an embodiment 3400 of one or more processing modules implemented to perform digital domain filtering within an ADC that includes a non-linear N-bit DAC in accordance with the present disclosure. This diagram is similar to FIG. 18 with a difference being that a non-linear N-bit DAC 1920 is implemented in place of the N-bit DAC 420.

FIGS. 35A, 35B, and 35C are schematic block diagrams showing various embodiments 3501, 3502, and 3503, respectively, of analog to digital converters (ADCs) with improved bandwidth in accordance with the present disclosure.

Referring to embodiment 3501, this diagram has certain similarities with other diagrams. For example, FIG. 4. An ADC is connected to or coupled to a load 32 via single line such that the ADC is configured to provide a load signal 412 via that single line and simultaneously to detect any effect 414 on that load signal via a single line (including any change thereof). In certain examples, the ADC is configured to perform single line drive and sense of that load signal 412, including any effect 414 thereon via that single line. This embodiment similarly includes a charging capacitor, C, that is coupled to one or the inputs of a comparator as voltage signal, Vᵢₙ. The other input of the comparator receives a reference voltage signal, V_{ref}. The output of the comparator is provided to a digital circuit 410 (e.g., which is clocked by a clock signal CLK and is configured to generate a digital output signal Do 1 at the particular clock rate of the clock signal CLK). Note that while a comparator coupled to a digital circuit 410 is shown in this diagram note that such a combination of elements may be alternatively implemented using any of the variations found in certain other diagrams herein, such as with respect to FIG. 5A. Note that any of the various implementations 501, 502, 503, 504, may alternatively be implemented in place of the combination of a comparator and a digital circuit 410 within this diagram and any other diagram herein. The output of the digital circuit 410 provides a digital output signal Do 1. As may be desired, the digital output signal Do 1 is provided to one or more processing modules 24 that is configured to communicate and interact with one or more other devices as described herein.

In some examples, the one or more processing modules 24 is configured to process the digital output signal Do 1 to generate another digital output signal Do 2 that is fed back to the N-bit DAC 420 that is configured to generate a feedback current signal I_{fbk}. That interacts with the load current Load to generate a quantization noise current, I_{load}−I_{fbk}, that charges the capacitor C thereby generating the voltage is provided to the input of the comparator that is coupled to that capacitor C.

In this diagram, a current sensor 3510 is implemented and configured to measure the quantization noise current, I_{load}−I_{fbk}, that charges the capacitor C and thereby generates a signal that is representative of the quantization noise current, I_{load}−I_{fbk}. Note that the signal that is representative of the quantization noise current, I_{load}−I_{fbk}, maybe a scaled version of the quantization noise current, I_{load}−I_{fbk} (e.g., scaled by some scaling factor k<1). Note that any of a variety of types of current sensors may be implemented to effectuate the operation of the current sensor 3510. Note that any such scheming information as may be performed by the current sensor 3510 when generating the signal that is representative of the quantization noise current, I_{load}−I_{fbk}, that it gets provided to the ADC 3512 will be compensated for as the ADC 3512 generates the output digital signal from the ADC 3512 that undergoes combination with the digital output signal Do 2. For example, any appropriate information regarding scaling of the signal generated by the current sensor 3510 will be included within the digital signal that is generated by the ADC 3512 (e.g., if the signal generated by the current sensor 3510 corresponds to a scaled representation of the quantization noise current, I_{load}−I_{fbk}, by a factor of ½ then the ADC 3512 will scale up the digital output signal by a factor of 2; if the signal generated by the current sensor 3510 corresponds to a scaled representation of the quantization noise current, I_{load}− I_{fbk}, by a factor of ¼ then the ADC 3512 will scale up the digital output signal by a factor of 4; and so on). Some various options (non-exhaustive) by which current sensing and current sensing circuits may be implemented are shown with respect to FIGS. 35D through 35K.

The current measurement signal that is provided from the current sensor 3510 is a signal that is representative of the sensed quantization noise current, I_{load}−I_{fbk}, that charges the capacitor C and thereby generates the voltage signal, Vᵢₙ, that is provided to one of the inputs of the comparator. Note that this current measurement signal may be viewed as a signal that is representative of the quantization noise current, i_{load}−I_{fbk}. This current measurement signal is provided to an ADC 3512 that is configured to generate additional signal that is provided to a combiner (e.g., a subtract or a summer such that one of the inputs is inverted before combination) to be combined with the other digital output signal Do 2 to subtract the quantization noise from that other digital output signal Do 2. The output of the combiner, after combination of the other digital output signal Do 2 and the digital signal that is generated by the ADC 3512 that corresponds to the quantization noise current (e.g., representative of the quantization noise current, I_{load}−I_{fbk}), is yet another/third digital output signal Do 2′ that has significantly lower quantization noise than the other digital output signal Do 2. Note that the ADC 3512 may be implemented similar to an ADC as shown in the top portion of the diagram, such as similar to that of FIG. 4 and/or other implementations of an ADC as described herein.

An ADC implemented based on this embodiment 3501 and others presented herein provide much improved bandwidth compared to other ADCs. For example, by sensing and subtracting the quantization noise current, or effectively within the digital domain by subtracting the quantization noise from the other digital output signal Do 2, a signal having a much higher bandwidth may be achieved with relatively little complexity, if any. For example, an ADC as implemented based on this embodiment 3501 and others presented herein provide the benefits of a third or fourth quarter modulator, such as a sigma delta modulator, without any extra added complexity. By subtracting out the quantization noise from the digital output signal Do 2, the other digital output signal Do 2′ is generated that has a significantly extended operational bandwidth in comparison to the digital output signal Do 2. In addition, such an ADC as implemented based on this embodiment 3501 and others presented herein may be implemented much more economically than prior art ADCs. Not only can such an ADC as implemented based on this embodiment 3501 and others presented herein be implemented to provide much improved performance including in terms of improved bandwidth, but it may also be implemented without any extra added complexity, and may be implemented more economically than prior art ADCs.

As may be desired in certain implementations, the decimation filter may be implemented to process the other/third digital output signal Do 2′ to generate yet another/fourth digital output signal Do 2″ having a lower sampling rate and a higher resolution than the other/third digital output signal Do 2′.

In certain examples, note that the other/fourth digital output signal Do 2″ is provided to one or more other devices such as one or more processing modules that is configured to process the other/fourth digital output signal Do 2″ to interpret information contained therein. Also, many other embodiments, diagrams, etc. show one or more digital output signals being generated by the various components therein. Similarly, in certain examples, note that any such one or more digital output signals is provided to one or more other devices such as one or more processing modules that is configured to process the one or more digital output signals to interpret information contained therein.

Within this diagram as well as any other diagram herein that includes a decimation filter, note that information included within the digital signal being provided to the decimation filter and the digital signal being output from the decimation filter both include comparable information. The decimation filter is operative to modify the sampling rate and resolution between digital signal being provided to the decimation filter and the digital signal being output from the decimation filter.

The quantization noise current, I_{load}−I_{fbk}, that is provided to one of the inputs of the comparator that operates in cooperation with the digital circuit 410 is configured to generate a digital signal that is oversampled with a high-frequency clock in the digital circuit 410. Again, the comparator and the digital circuit 410 may be implemented in an alternative implementation, yet the clock signal is such that it generates an oversampled digital output signal Do 1. The N-bit DAC 420 is configured to generate the feedback current signal, I_{fbk}, that undergoes combination with the load current signal to generate the quantization noise current, I_{load}−I_{fbk}. In an ideal implementation, N of the N-bit DAC 420 is infinite such that the N-bit DAC four and 20 generates a feedback current signal having zero quantization noise. However, in a real application implementation, N of the N-bit DAC 420 is finite such that the feedback current signal, I_{fbk}, does include some effect that is caused by the quantization noise.

Such an implementation of an ADC as shown in this diagram significantly expands the bandwidth of operation having a very high signal to noise ratio (SNR). For example, the operational frequency range extends significantly, in some instances up to 200-300 kHz (e.g., with a 20 MHz sampling rate), by sensing and removing the effects of the quantization noise current via the sensing of the quantization noise current, I_{load}−I_{fbk}, and combination with the digital output signal Do 2 thereby generating a digital output signal Do 2′ having much lower quantization noise. The sensing of and subtracting of the quantization noise from the digital output Do 2 significantly improves the overall functionality of the ADC by extending the bandwidth having a very high SNR.

Also, note that such an ADC is configured to consume a very low-power in operation. For example, in once this example, the entire power consumption of the ADC is approximately 6 milli-Watts (mW) (e.g., consuming less than 6 mW during operation). Note that the implementation of such an ADC includes a mixture of approximately 90% digital circuitry and 10% analog circuitry. One of the larger components in the overall ADC is the and-bit DAC 420. Given the significant amount of digital circuitry within such an implementation, the power consumption of the ADC is very low. In addition, given the significantly small number of analog components within the ADC, thermal noise is significantly reduced. Generally speaking, reducing the number of analog components will facilitate reduction in thermal noise of the overall circuit. In some implementations, the digital output signal Do 2′ (after subtraction of the quantization noise from the digital output signal Do 2) or the other digital output signal Do 2″ (output from the decimation filter) is implemented to have 14-16 bits of resolution. In some specific implementations when the bandwidth is extended even more significantly, and the resolution of these digital output signals Do2′ or Do 2″ may be even greater, such as more than 20 bits of resolution (e.g., 21 bits of resolution in one specific example).

With such an extension of bandwidth to an upper range of approximately 200-300 kHz (e.g., with a 20 MHz sampling rate), such an ADC that is operative to consume very little power and provide very high accuracy while also providing such a broad operational bandwidth, such an ADC may be implemented in a broad range of applications. For example, by providing an operational bandwidth up to approximately 100 kHz, such an ADC may be implemented within audio applications while providing high accuracy and while consuming very low-power. For example, considering audio applications, such as processing of human speech, such an ADC is configured to detect with very high accuracy even very small variations within a person's voice.

Also, with respect to the ADC 3512 implemented near the bottom of the diagram, note that the ADC 3512 may be as simple as that 1-bit ADC. Such an ADC may be approximately ¼ of the size of the N-bit DAC 420 located towards the top of the diagram. In other implementations, the ADC 3512 is replaced with a single comparator.

In addition, note that the one or more processing modules 24 may be viewed as operating as an integrator in certain examples. For example, consider a 6-bit digital output signal Do 2 coming out of the one or more processing modules 24 as being representative of the signal plus noise (e.g., as including quantization noise).

In an example of operation and implementation, the analog to digital converter (ADC) includes a capacitor that is operably coupled to a load and configured to produce a load voltage based on charging by a load current and a digital to analog converter (DAC) output current. Note that the ADC is coupled to the load via a single line. The ADC also includes a current sensor that is operably coupled and configured to sense a quantization noise current that is based on the load current and the DAC output current and to generate a signal that is representative of the quantization noise current. The ADC also includes a comparator operably coupled and configured to receive the load voltage via a first input of the comparator, receive a reference voltage via a second input of the comparator, and compare the load voltage to the reference voltage to generate a comparator output signal. The ADC also includes a digital circuit that is operably coupled to the comparator and configured to process the comparator output signal to generate a first digital output signal that is representative of a difference between the load voltage and the reference voltage.

The ADC also includes one or more processing modules that is operably coupled to the digital circuit and the memory and configured to execute operational instructions (e.g., such as operational instructions stored in memory) to process the first digital output signal to generate a second digital output signal that is representative of the difference between the load voltage and the reference voltage. In certain examples, the second digital output signal includes a higher resolution than the first digital output signal.

The ADC also includes an N-bit digital to analog converter (DAC) that is operably coupled to the one or more processing modules and configured to generate the DAC output current based on the second digital output signal. Note that N is a positive integer. Also, the DAC output current tracks the load current, and the load voltage tracks the reference voltage.

The ADC also includes another ADC that is operably coupled to the current sensor and configured to generate a digital signal that is representative of the quantization noise current based on the signal that is representative of the quantization noise current.

The ADC also includes a combining circuit that is operably coupled to the another ADC and the one or more processing modules and configured to subtract the digital signal that is representative of the quantization noise current from the second digital output signal to generate a third digital output signal.

In certain examples, the one or more processing modules is further configured to process the first digital output signal in accordance with performing band pass filtering or low pass filtering to generate the second digital output signal that is representative of the difference between the load voltage and the reference voltage.

In certain other examples, the comparator includes a sigma-delta comparator, and the digital circuit includes a clocked flip flop. In even other examples, a digital comparator includes both the comparator and the digital circuit. The digital comparator operably coupled and configured to receive the load voltage via a first input of the comparator, receive a reference voltage via a second input of the comparator, and compare the load voltage to the reference voltage to generate the first digital output signal that is representative of the difference between the load voltage and the reference voltage.

In certain alternative examples, the ADC also includes a decimation filter coupled to the combining circuit. When enabled, the decimation filter operably coupled and configured to process the third digital output signal to generate a fourth digital output signal having a lower sampling rate and a higher resolution than the third digital output signal.

Note that the load may be of any of a variety of types including an electrode, a sensor, or a transducer. In certain examples, the ADC includes an operational bandwidth having an upper range of 200 kHz or 300 kHz. Also, in certain specific implementations, the ADC is configured to consume less than 6 mW during operation.

Referring to embodiment 3502, this diagram is similar to the previous diagram with the least one difference being that the ADC 3512 shown at the bottom of the previous diagram is replaced with an N- or M-bit ADC 3520. For example, this ADC at the bottom of the diagram may be implemented as an N-bit ADC 3520 similar to the N-bit DAC 420 at the top of the diagram (e.g., N corresponds to a positive integer less than or equal to 8 bit resolution, N<8). In one particular implementation, N corresponds to a positive integer less than or equal to 8 bit resolution (N<8), and M corresponds to a positive integer between 1 and 4 bit resolution (M=1 to 4), inclusive. In certain implementations as described above, the N- or M-bit ADC 3520 may be implemented using an M-bit ADC 3520, such that M<N, given that the signal that is representative of the quantization noise current, I_{load}−I_{fbk}, that is generated by the current sensor 3510 will generally be a much smaller signal (e.g., a much smaller current signal in terms of magnitude) than the quantization noise current, I_{load}−I_{fbk}, itself.

In this diagram, the N- or M-bit ADC 3520 is implemented instead of the ADC 3512 of the previous diagram. For example, the N- or M-bit ADC 3520 is operably coupled to the current sensor and configured to generate a digital signal that is representative of the quantization noise current based on the signal that is representative of the quantization noise current. Note that M is a positive integer that is less than or equal to N.

Referring to embodiment 3503, this diagram has certain similarities with the previous two diagrams with at least one difference being that the ADC at the bottom of the prior two diagrams is replaced with a comparator operating in conjunction with a digital circuit 410 that is clocked by a clock signal CLK. In this diagram, a charging capacitor C is connected to one of the inputs of the comparator to generate a voltage signal at that input of the comparator. In addition, a reference voltage Vref (QN) is provided to the other input of the comparator to facilitate detection of a voltage signal corresponding to the quantization noise current, I_{load}− I_{fbk}. Also note that the combination of the comparator and the digital circuit 410 may alternatively be implemented using any of a number of variations including those described with respect to FIG. 5A. In this diagram, a first and second charging capacitor C, a first and second comparator, and a first and second digital circuit 410 are implemented. The second charging capacitor C, the second comparator, and the second digital circuit 410 are implemented instead of the ADC 3512 or the N- or M-bit ADC 3520 of the previous diagrams.

FIGS. 35D, 35E, 35F, 35G, 35H, 35I, 35J, and 35K are schematic block diagrams showing various embodiments 3504, 3505, 3506, 3507, 3508, 3509, 3521, and 3522, respectively, of current sensor circuitry that may be implemented in accordance with the present disclosure. These diagrams show some samples of various means by which current may be sensed. Note that these examples are non-not exhaustive and any other equivalent type current sensing capable device may alternatively be used.

Referring to embodiment 3504, a current sensor 3510 generates a current signal I₂ that is representative of the current flowing through the line from left to right I₁. For example, the current signal I₂ may be a scaled up or scale down versions of the current signal I₁. Such a current sensor 3510 may be implemented in a variety latest including a ferromagnetic current sensor that encompasses the wire or line that includes the current signal I₁ being sensed. Based on the coupling of magnetic field is generated by the current signal I₁ within the ferromagnetic current sensor, the current signal I₂ is induced within the magnetic core of the ferromagnetic current sensor.

Referring to embodiment 3505, a current sensor 3510-1 generates a voltage signal Vout that is representative of the current flowing through the line from left to right I₁. For example, the voltage signal Vₒᵤₜ may is a signal that is representative of the current signal There may be some instances in which a voltage signal Vout that is representative of the current signal I₁ is more desirable than a current signal I₂ that is representative of the current signal I₁.

Referring to embodiment 3506, in this diagram, the current signal I₁ is provided to a resistor R₁. The difference in voltage between the two ends of the resistor R₁ (V1 and V2) along with the value of the resistor R₁ are used to determine the current signal I₁ based on Ohm's Law (Delta V=ΔV=V1−V2=I₁×R₁, and I₁=(V1−V2)/R₁). Note that the symbol Δ is sometimes used in place of the word Delta herein, and vice versa; they both mean the same thing being the difference of, change of, difference between two values, etc. as is understood in the art.

Referring to embodiment 3507, this diagram shows a current mirror circuit. This included two transistor implementation of the current mirror that is based on the relationship that two equal sized transistors at the same temperature with the same characteristics, such as the V_{BE} (voltage drop between the base and emitter of an NPN transistor in this implementation of two NPN BJTs (alternatively, Negative-Positive-Negative Bipolar Junction Transistors)) have the same collector current Ic. The current mirror is a circuit that functions to produce a copy of the current flowing into or out of an input terminal, such as the current signal I₁ that is flowing through the resistor R₁ and into the collector of the transistor Q1 on the left-hand side of the diagram. The collector and the base of the transistor Q1 are connected together. Also, the collector of the transistor Q1 is connected to the base of the transistor Q2. The voltage at the collector note of the transistor Q1 corresponds to the V_{BE} of that same transistor Q1. This same voltage potential is provided to the base of the transistor Q2. As such, of the current signal I₂ that will be induced to flow at the collector note of the transistor Q2 will be the same as the current signal I₁.

Referring to embodiment 3508 and 3509, these diagrams correspond to high side current sensing and low side current sensing, respectively based on a load being implemented above or below a resistor R₁. A power supply voltage, V_{pwr supp}, provides a voltage potential that is higher than ground and thereby facilitates the flow of current signal I₁ via the load and the resistor R₁. One or more operational amplifiers/circuits is implemented to generate an output voltage signal Vₒᵤₜ that is representative of the current signal I₁ that is flowing via the load and the resistor R₁.

Referring to embodiment 3508, this diagram depicts high side current sensing such that the current sensing connects to the resistor between the power supply of the load. The sensed voltage signal may be scaled, such as amplified, by one or more operational amplifiers/circuits to generate the output voltage signal Vₒᵤₜ that is representative of the current signal I₁ that is flowing via the load and the resistor R₁. Some advantages of performing include eliminating ground disturbance, detecting the high load current caused by accidental electrical shorts, having the load connecting to the system ground directly, etc.

Referring to embodiment 3509, this diagram depicts low side current sensing such that the current sensing connects to the resistor between the load and ground. The sensed voltage signal may be scaled, such as amplified, by one or more operational amplifiers/circuits to generate the output voltage signal Vₒᵤₜ that is representative of the current signal I₁ that is flowing via the load and the resistor R₁. Some advantages of performing low side current sensing include providing a low input common mode voltage, a ground referenced input and output, and a relatively simple and low-cost implementations, etc.

Referring to embodiment 3521, this diagram shows a metal-oxide-semiconductor field-effect transistor (MOSFET) current splitter implemented using PMOS transistors. For example, consider a current signal I₁ entering the node connected to the sources of the PMOS transistors of the MOSFET current splitter. Also, a voltage bias, Vbias is provided to the gates of the PMOS transistors of the MOSFET current splitter. Considering a MOSFET current splitter that includes two PMOS transistors M1 and M2 of the same size, then the current signal will be evenly split between the two PMOS transistors M1 and M2 as follows: I₁=I₁ₐ+I_{1b}, and I₁ₐ=I_{1b}. Alternatively, considering a MOSFET current splitter that includes two PMOS transistors M1 and M2 of not of the same size, and PMOS transistor M1 is less in size than the PMOS transistor M2, then the current signal I₁ will be split between the two PMOS transistors M1 and M2 as follows: I₁=I₁ₐ+I_{1b}, and I₁ₐ<I_{1b}. In an alternative implementation, considering a MOSFET current splitter that includes two PMOS transistors M1 and M2 of not of the same size, and PMOS transistor M1 is greater in size than the PMOS transistor M2, then the current signal I₁ will be split between the two PMOS transistors M1 and M2 as follows: I₁=I₁ₐ+I_{1b}, and I₁ₐ>I_{1b}.

Referring to embodiment 3522, this diagram shows a bipolar current splitter implemented using PNP transistors (alternatively, Positive-Negative-Positive Bipolar Junction Transistors (BJT)). For example, consider a current signal I₁ entering the node connected to the emitters of the PNP BJT transistors of the bipolar current splitter. Also, a voltage bias, Vbias is provided to the bases of the PNP BJT transistors of the bipolar current splitter. Considering a bipolar current splitter that includes two PNP BJT transistors Q1 and Q2 of the same size, then the current signal I₁ will be evenly split between the two PNP BJT transistors Q1 and Q2 as follows: I₁=I₁ₐ+I_{1b}, and I₁ₐ=I_{1b}. Alternatively, considering a bipolar current splitter that includes two PNP BJT transistors Q1 and Q2 of not of the same size, and PNP BJT transistor Q1 is less in size than the PNP BJT transistors Q2, then the current signal I₁ will be split between the two PNP BJT transistors Q1 and Q2 as follows: I₁=I₁ₐ+I_{1b}, and I₁ₐ<I_{1b}. In an alternative implementation, considering a bipolar current splitter that includes two PNP BJT transistors Q1 and Q2 of not of the same size, and PNP BJT transistor Q1 is greater in size than the PNP BJT transistors Q2, then the current signal I₁ will be split between the two PNP BJT transistors Q1 and Q2 as follows: I₁=I₁ₐ+I_{1b}, and I₁ₐ>I_{1b}.

Note that any one of these examples of different ways in which to perform current sensing may be limited within an ADC as described herein. Generally speaking, any desired current sensor implementations may be used in various embodiments of the disclosure.

FIG. 35F shows multiple performance diagrams of ADC output 3581, 3582, 3583, and 3584, respectively, expressed as power spectral density (PSD [dB]) as a function of frequency (kilo-Hertz [kHz]) in accordance with the present disclosure.

Referring to diagram 3581, this diagram shows the ADC output with no thermal noise in the clock jitter effect. The ADC providing improved bandwidth as described herein by subtracting out the quantization noise from the digital output Do 2 (e.g., shown as improved IADC in the diagram). As can be seen, the operational bandwidth of the ADC is significantly extended in the upper frequency ranges (e.g., into the 100s of kHz and even the low/10s of MHz upper limits).

Referring to diagram 3582, this diagram shows the ADC output with thermal noise and also with clock jitter effect. The thermal noise raises the overall noise floor within the ADC providing improved bandwidth, but the ADC providing improved bandwidth still provides improved bandwidth as described herein by subtracting out the quantization noise from the digital output Do 2 (e.g., shown as improved IADC in the diagram). Note that the thermal noise dominates at lower frequencies in the quantization noise dominates at higher frequencies. By subtracting out quantization noise from the digital output Do 2, the operational bandwidth of the ADC is it significantly extended (e.g., into the 100s of kHz and even the low/10s of MHz upper limits).

Referring to diagram 3583, this diagram shows the ADC output with thermal noise and also shows that quantization noise is largely negligible at lower frequencies. Although quantization noise can become exacerbated at higher frequencies, the ADC providing improved bandwidth does provide an operational bandwidth extending into the higher frequencies (e.g., into the 100s of kHz and even the low/10s of MHz upper limits). As can be seen in this diagram, such an ADC providing improved bandwidth as described herein helps lower the quantization noise at higher frequencies. As can also be seen in this diagram, the ADC providing improved bandwidth provides improved bandwidth as described herein by subtracting out the quantization noise from the digital output Do 2 (e.g., shown as improved IADC in the diagram).

Referring to diagram 3584, this diagram also shows the ADC output with thermal noise and also with clock jitter effect. As can also be seen in this diagram, the ADC providing improved bandwidth provides improved bandwidth as described herein by subtracting out the quantization noise from the digital output Do 2 (e.g., shown as improved IADC in the diagram).

FIG. 36A is a schematic block diagram showing an embodiment 3601 of an ADC implemented with a thermometer decoder in accordance with the present disclosure. Referring to embodiment 3601, this diagram has certain similarities to others herein including a single line that is coupled from the ADC to a load 32, thereby facilitating single line drive and sense by providing a load signal 412 and detecting an effect 414 on that load signal, a charging capacitor C, a comparator implemented with a digital circuit 410 (which may alternatively be implemented using any of the variations including those in FIG. 5A), etc.

However, this diagram has certain differences from other diagrams herein as well. For example, a N-bit accumulator 3610 (shown as N-bit ACC 3610 and the diagram) is implemented to process the digital output signal from the digital circuit 410 (or alternative one or more components that generates the digital output signal generated by those one or more components). For example, the N-bit accumulator 3610 is configured to convert the digital output signal to a digital signal having a certain number of bits. In some examples, this operation involves converting a digital output signal that includes one bit every clock signal of the clocking signal that is provided to the digital circuit 410 to an N-bit signal that includes N-bits every clock signal. In one specific example, this operation involves conversion of a one-bit digital signal to a 7-bit signal or an 8-bit signal. Generally speaking, the N-bit accumulator 3610 may be configured in various alternative implementations to generate an N-bit signal having any desired number of bits, such that N is a positive integer greater than or equal to 2.

Note also that the decimation filter may be implemented to process the output digital signal from the N-bit accumulator 3610 as well. For example, the decimation filter is configured to process the digital output signal provided from the N-bit accumulator 3610 to generate another digital output signal having a lower sample rate and a higher resolution.

In addition, the digital signal that is generated by the N-bit accumulator 3610 is provided to a thermometer decoder 3612. The thermometer decoder 3612 is configured to generate an output symbol that includes a sequence of 0s followed by a sequence of 1s in most instances, or alternatively all 0s or all 1 s. For example, with respect to a thermometer code, there cannot be any 0s in between two 1s. Generally speaking, with respect to a thermometer code, an input value representing a particular number (e.g., 3=011 binary) generates an output value such that the lowermost bits are all of value 1, and the other uppermost bits or all of value 0. Generally speaking, for an n-bit binary code, the corresponding thermometer code will have 2ⁿ−1 symbols. As such, as many bits are needed to represent the thermometer code.

The top portion of the diagram pictorially illustrates an example of a thermometer code with 8 symbols each having 7 bits. Consider 8 binary input symbols composed of 3 bits each: 0=000, 1=001, 2=010, 3=011, 4=100, 5=101, 6=110, and 7=111.

Based on the input value, the thermometer code will generate the following output symbols.

Input 0=000, then output=0000000

Input 1=001, then output=0000001

Input 2=010, then output=0000011

Input 3=011, then output=0000111

Input 4=100, then output=0001111

Input 5=101, then output=0011111

Input 6=110, then output=0111111

Input 7=111, then output=1111111

Note that while this example corresponds to a thermometer code operating on input symbols composed of three bits each and generating output symbols composed of seven bits each, different sized thermometer codes may alternatively be implemented using the thermometer decoder 3612. For example, consider input symbols composed of 7 or 8 bits each, then corresponding output symbols in accordance with the thermometer code may be generated based on these principles.

In an example of operation and implementation, the thermometer decoder 3612 outputs thermometer code symbols based on the inputs provided from the N-bit accumulator 3610. A number of PNP BJTs (alternatively, Positive-Negative-Positive Bipolar Junction Transistors) and NPN BJTs (alternatively, Negative-Positive-Positive BJTs) are implemented to perform digital to analog conversion of the output symbols provided from the thermometer decoder 3612. Generally speaking, any desired total number X of PNP BJTs and NPN BJTs are implemented (e.g., consider Nb PNP BJTs and also Nb NPN BJTs, such that Nb is a positive integer greater than or equal to 2). By using a thermometer decoder 3612 to provide the inputs to and facilitate the operation of the Nb PNP BJTs and also Nb NPN BJTs that are implemented to perform digital to analog conversion thereby generating a source current and/or a sink current, as few as only one current source for current sink is switched on or off at a time during any transition between two successive respective values output by the thermometer decoder 3612. For example, consider the input to the thermometer decoder 3612 transitioning from 2=010 to 3=011, then the output from the thermometer decoder 3612 would transition from 0000011 to 0000111. Note that only one bit of the output from the thermometer decoder 3612 changes during such a transition. By using a thermometer decoder 3612 to facilitate operation of the Nb PNP BJTs and also Nb NPN BJTs that are implemented to perform digital to analog conversion, a significant reduction in noise may be facilitated with respect to the adaptation of a source current and/or a sink current that is set back within the ADC to regulate the input voltage (Vᵢₙ) to the comparator to the input reference voltage (V_{ref}) to the comparator. This implementation provides a significant improvement over alternative implementations that would switch on or off a large number of current sources and/or current sinks. The thermometer decoder 3612 facilitates adaptation of the feedback source current and/or a sink current in a manner that is very low noise, high precision, etc.

In certain examples, note that the sampling rate within such an ADC implemented with a thermometer decoder is programmable. For example, the sampling rate may be anywhere within the range of 400 kHz to 40 MHz in certain implementations. In addition, the reference currents that may be used within such an ADC implemented with a thermometer decoder may be of extremely low value, such as varying between 1 μA to 100 μA in certain implementations. Also, in certain examples, note that the input reference voltage signal Vref is provided as a programmable sinusoidal signal. Note that such an ADC implemented with a thermometer decoder is operative to operate using very low power, and can sink and or source current to the load 32.

FIGS. 36B and 36C are schematic block diagrams showing embodiments 3602 and 3603, respectively, of one or more PNP BJTs (alternatively, Positive-Negative-Positive Bipolar Junction Transistors) and NPN BJTs (alternatively, Negative-Positive-Positive BJTs) implemented to sink and source current within embodiments of ADCs implemented with a thermometer decoder in accordance with the present disclosure.

Referring to embodiment 3602, this diagram shows the number of NPN BJTs (e.g., Nb NPN BJTs) that are implemented such that an output symbol from a thermometer decoder is provided to the respective base terminals of the NPN BJTs. For example, each of the respective bits of the output symbol from the thermometer decoder is provided via a respective line to a respective one of the base terminals of the NPN BJTs. Considering an example of an output symbol from the thermometer decoder being 0000011, then the respective bits that are provided via the respective lines to the base terminals of the NPN BJTs are as follows: 0 is provided to 5 of the NPN BJTs, and 1 is provided to 2 of the NPN BJTs (e.g., 0 to NPN BJT 1, 0 to NPN BJT 2, 0 to NPN BJT 3, 0 to NPN BJT 4, 0 to NPN BJT 5, 1 to NPN BJT 6, and 1 to NPN BJT 7). As mentioned above, when the output from the thermometer decoder changes up or down by a particular value, only one of the bits of the output symbol of the thermometer decoder changes, and as such, only one of the respective NPN BJTs is switched on or off. Such an implementation of a number of NPN BJTs is configured to sink current based on the number of NPN BJTs that are switched on in response to the output symbol from the thermometer decoder.

Referring to embodiment 3603, this diagram shows the number of PNP BJTs (e.g., Nb PNP BJTs) that are implemented such that an output symbol from a thermometer decoder is provided to the respective base terminals of the PNP BJTs. This operates similarly to the implementation of the previous diagram with a difference being that the number of PNP BJTs is configured to source current based on the number of PNP BJTs that are switched on in response to the output symbol from the thermometer decoder. As such, the desired sink current and/or source current is provided to the single line that is connected to and/or coupled to the load 32.

Implementing both the embodiments 3602 and 3603, as such, the desired sink current and/or source current is provided to the single line that is connected to and/or coupled to the load 32.

Note that various implementations may include the structure of one or both of the embodiments 3602 and/or 3603 as may be desired in various implementations that may operate by sinking and/or sourcing current.

FIG. 36D is a schematic block diagram showing an alternative embodiment 3604 of an ADC implemented with a thermometer decoder in accordance with the present disclosure. This diagram is similar to the embodiment 3601 of FIG. 36A with at least one difference being that the PNP BJTs (alternatively, Positive-Negative-Positive Bipolar Junction Transistors) and NPN BJTs (alternatively, Negative-Positive-Positive BJTs) are replaced respectively with PMOS and NMOS metal-oxide-semiconductor field-effect transistors (MOSFETs) (PMOS and NMOS transistors). The PMOS and NMOS transistors operate similarly to source and/or sink current based on the to the single line that is connected to and/or coupled to the load 32. In certain examples, it is preferable to implement PMOS and NMOS transistors instead of PNP and NPN BJTs to source and/or sink current.

FIGS. 36E and 36F are schematic block diagrams showing embodiments of one or more metal-oxide-semiconductor field-effect transistors (MOSFETs) including one or more PMOS transistors and NMOS transistors implemented to sink and source current within embodiments of ADCs implemented with a thermometer decoder in accordance with the present disclosure.

Referring to embodiments 3605 and 3606, these diagrams are similar to the embodiments 3602 and 3603 of FIG. 36B and FIG. 36C, respectively, with at least one difference being that the PNP BJTs (alternatively, Positive-Negative-Positive Bipolar Junction Transistors) and NPN BJTs (alternatively, Negative-Positive-Positive BJTs) are replaced respectively with PMOS and NMOS metal-oxide-semiconductor field-effect transistors (MOSFETs) (PMOS and NMOS transistors).

Referring to embodiment 3605, this diagram shows the number of NMOS transistors that are implemented such that an output symbol from a thermometer decoder is provided to the respective gate terminals of the NMOS transistors. For example, each of the respective bits of the output symbol from the thermometer decoder is provided via a respective line to a respective one of the gate terminals of the NMOS transistors. Such an implementation of a number of NMOS transistors is configured to sink current based on the number of NMOS transistors that are switched on in response to the output symbol from the thermometer decoder. As such, the desired sink current is provided to the single line that is connected to and/or coupled to the load 32.

Referring to embodiment 3606, this diagram shows the number of PMOS transistors that are implemented such that an output symbol from a thermometer decoder is provided to the respective gate terminals of the PMOS transistors. This operates similarly to the implementation of the previous diagram with a difference being that the number of PMOS transistors is configured to source current based on the number of PMOS transistors that are switched on in response to the output symbol from the thermometer decoder. As such, the desired source current is provided to the single line that is connected to and/or coupled to the load 32.

Implementing both the embodiments 3605 and 3606, as such, the desired sink current and/or source current is provided to the single line that is connected to and/or coupled to the load 32.

Note that various implementations may include the structure of one or both of the embodiments 3605 and/or 3606 as may be desired in various implementations that may operate by sinking and/or sourcing current.

FIG. 36G is a schematic block diagram showing an alternative embodiment 3607 of an ADC implemented with a thermometer decoder in accordance with the present disclosure. Referring to embodiment 3607, this diagram has similarity to the embodiment 3601 and embodiment 3604 with at least one difference being that the Nb PNP BJTs and also Nb NPN BJTs or replaced by resistor banks that operate to sink and/or source current. For example, consider a number of resistors (e.g., R₁ to Rₓ connected to ground to sink current and/or R₁ to Rₓ connected to ground to a power supply such as VDD to source current) that are implemented within respective resistor banks such that any desired number of those resistors in each of the respective banks may be connected or disconnected as desired to facilitate a particular current sink and/or current source to be fed back to the single line that is connected to and/or coupled to the load 32.

In an example of operation and implementation, a smaller sink current and/or smaller source current is provided from the respective resistor banks based on all of the resistors therein being switched in. For example, number of resistors implemented in parallel provides a lower resistance than any one of the respective resistor is singularly switched in while the others are not connected. Based on the value of the output symbol from the thermometer decoder 3612, the appropriate number of resistors are switched in within the one or more resistor banks thereby facilitating the desired current sink and/or current source to be fed back to the single line that is connected to and/or coupled to the load 32.

Note that alternative implementations, circuits, etc., may be implemented to provide the desired current sink and/or current source to be fed back to the single line that is connected to and/or coupled to the load 32 based on the value of the output symbol from the thermometer decoder 3612. For example, a number of independent and/or dependent current sources may alternatively be implemented and controlled based on the output symbol from the thermometer decoder 3612, a number of current buffers may alternatively be implemented and controlled based on the output symbol from the thermometer decoder 3612, etc.

Note that various aspects, embodiments, and/or examples of the disclosure (and/or their equivalents) include analog to digital converters (ADCs) including current mode ADCs (IADCs). Note that any embodiment, implementation, and/or example of an ADC as described herein (and/or their equivalents) may be implemented within various devices and/or systems as described herein. In addition, other alternative implementations of ADCs are described in U.S. Utility patent application Ser. No. 17/132,241, “Single-ended direct interface dual DAC feedback photo-diode sensor,” filed Dec. 23, 2020, pending. Any instantiation of an ADC as described herein may alternatively be implemented using any of the various implementations of various ADCs described in U.S. Utility patent application Ser. No. 17/132,241 including the additional U.S. Utility Patent Applications that are claimed priority to therein and/or incorporated by reference.

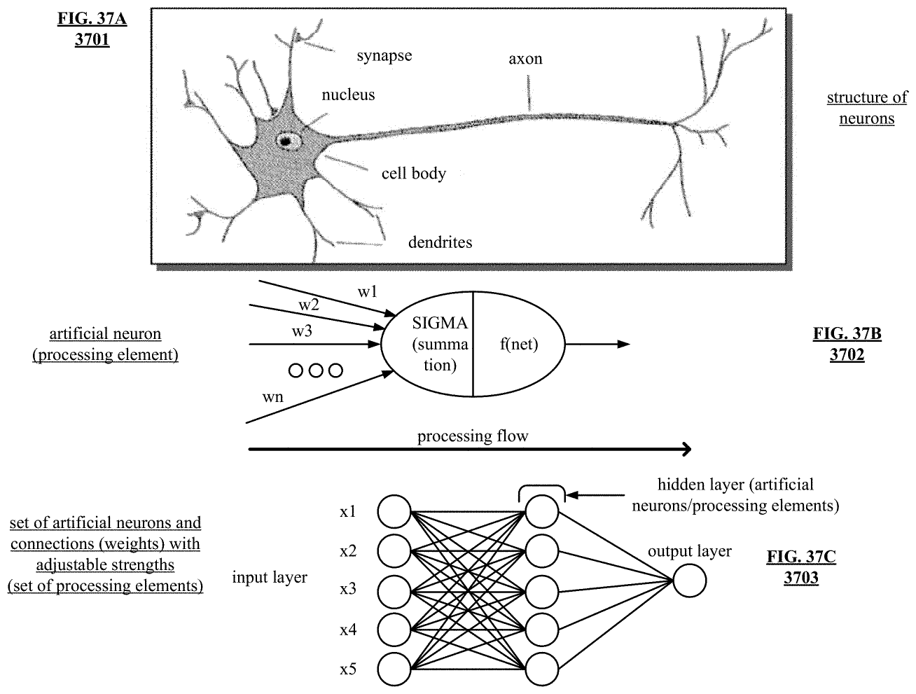

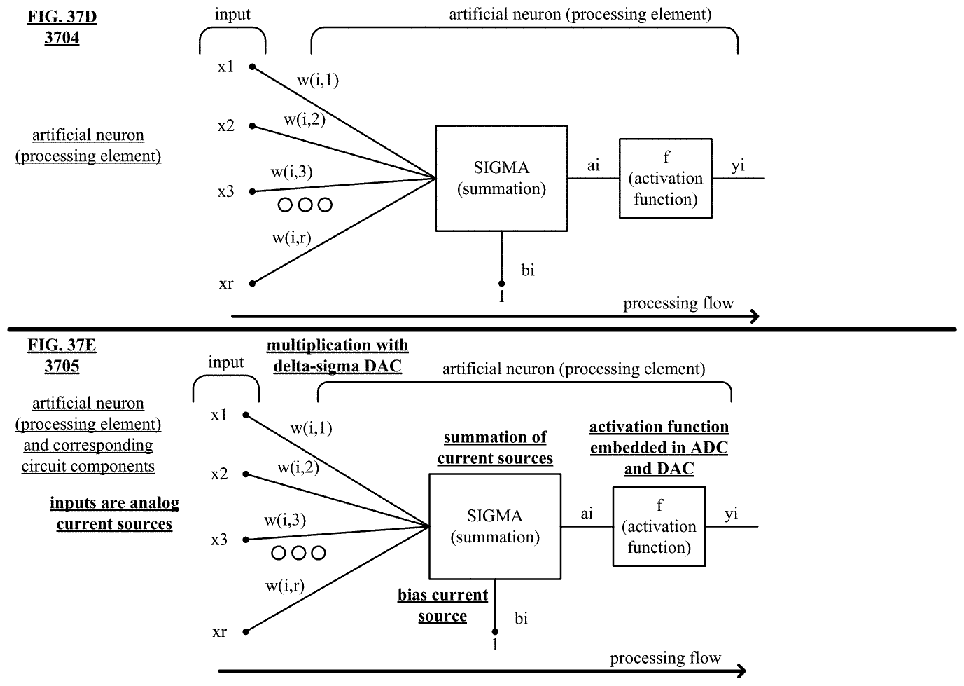

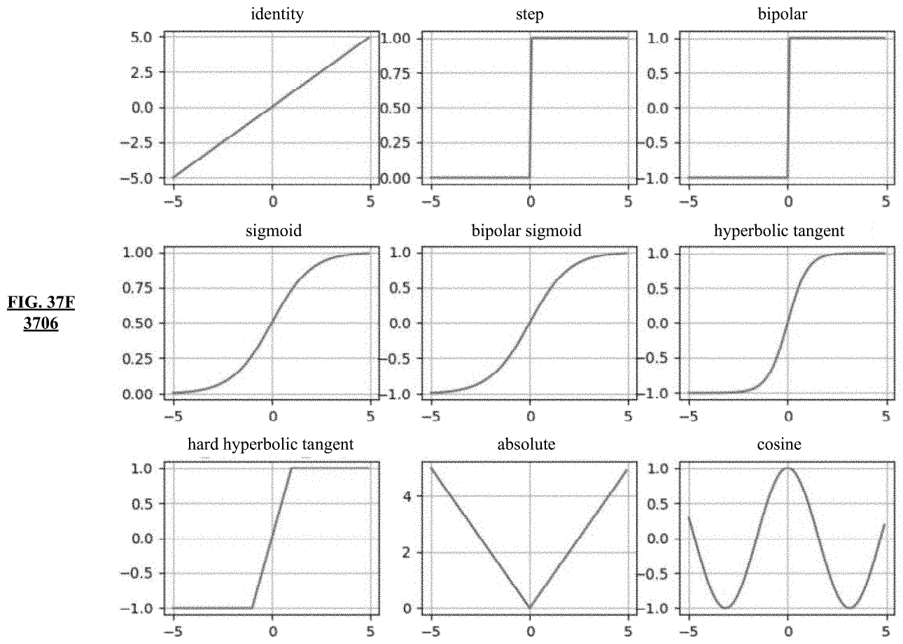

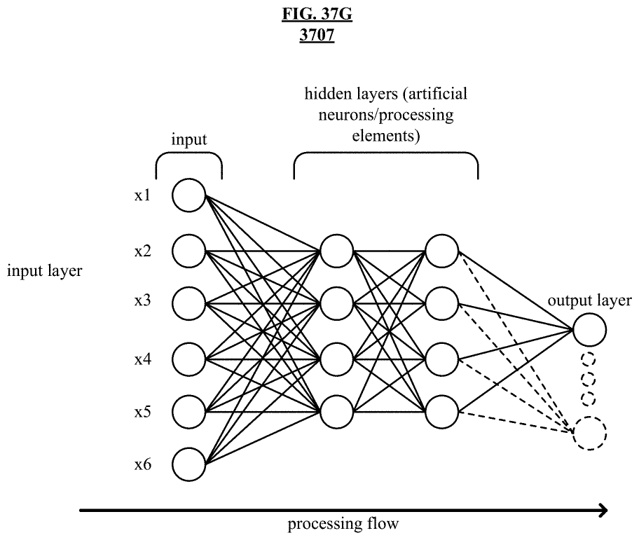

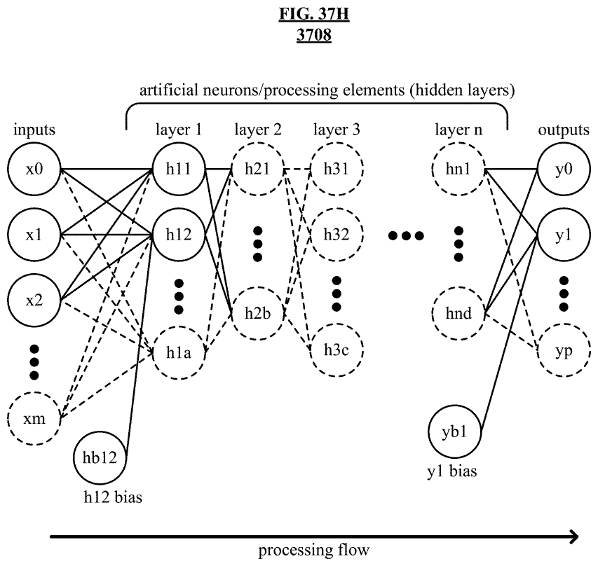

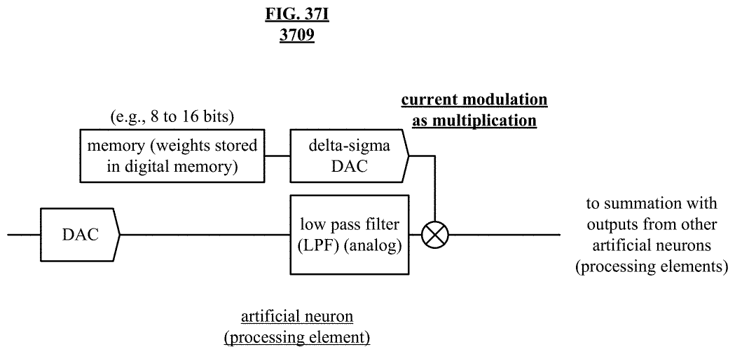

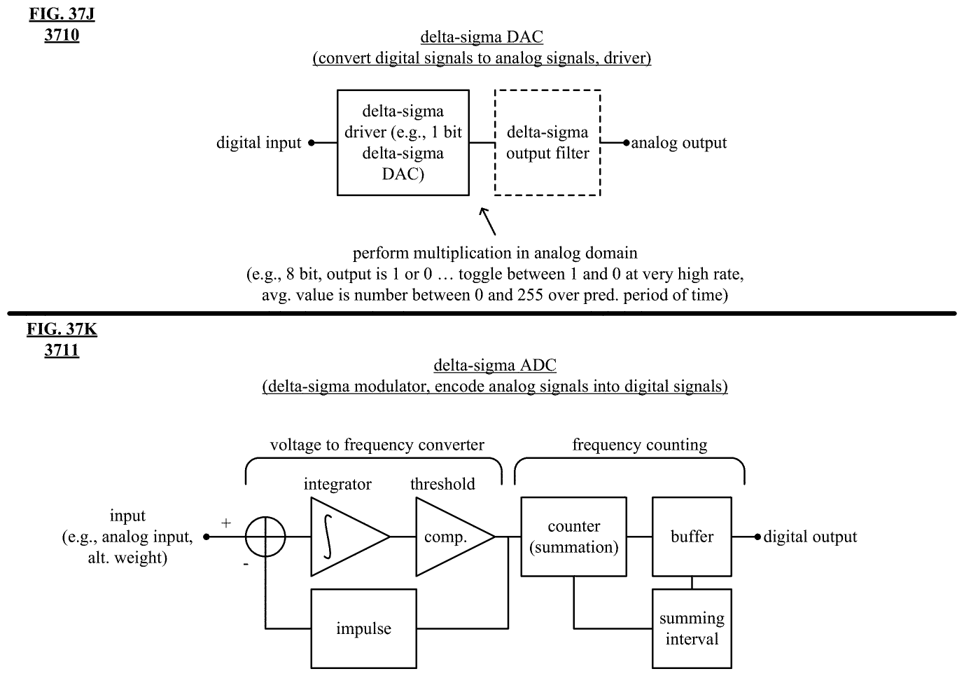

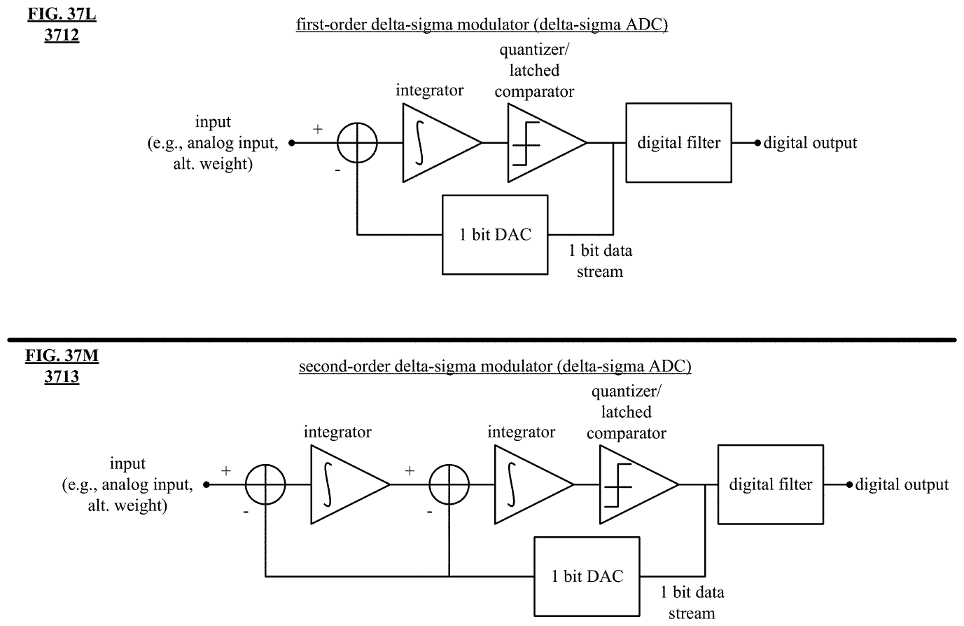

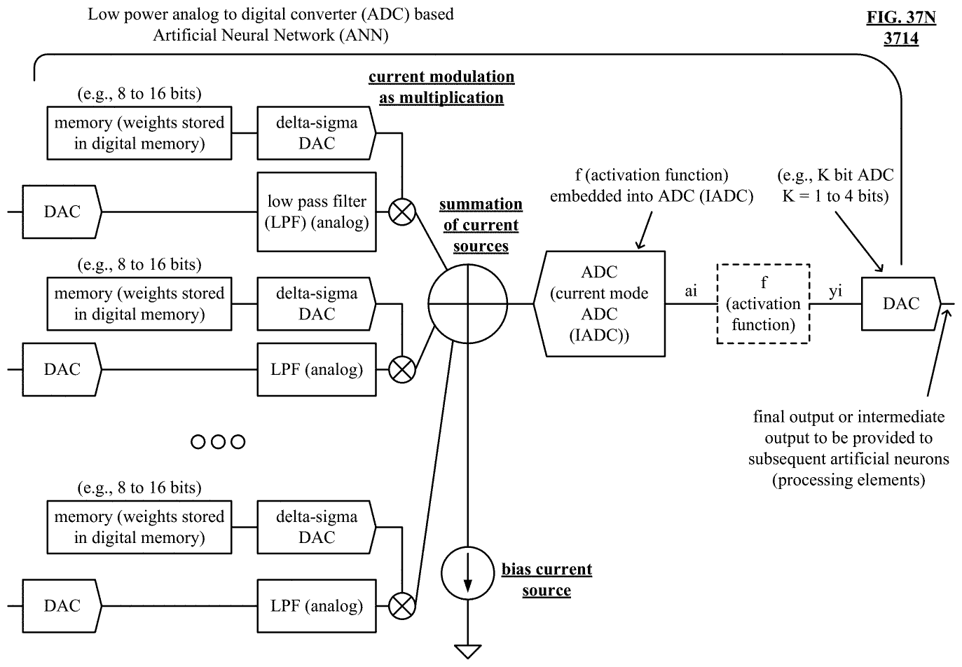

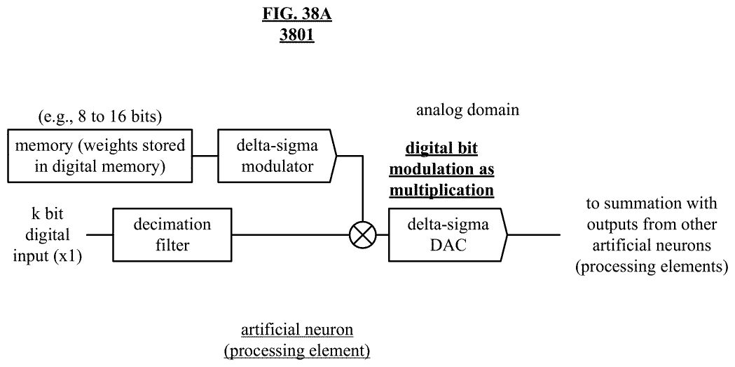

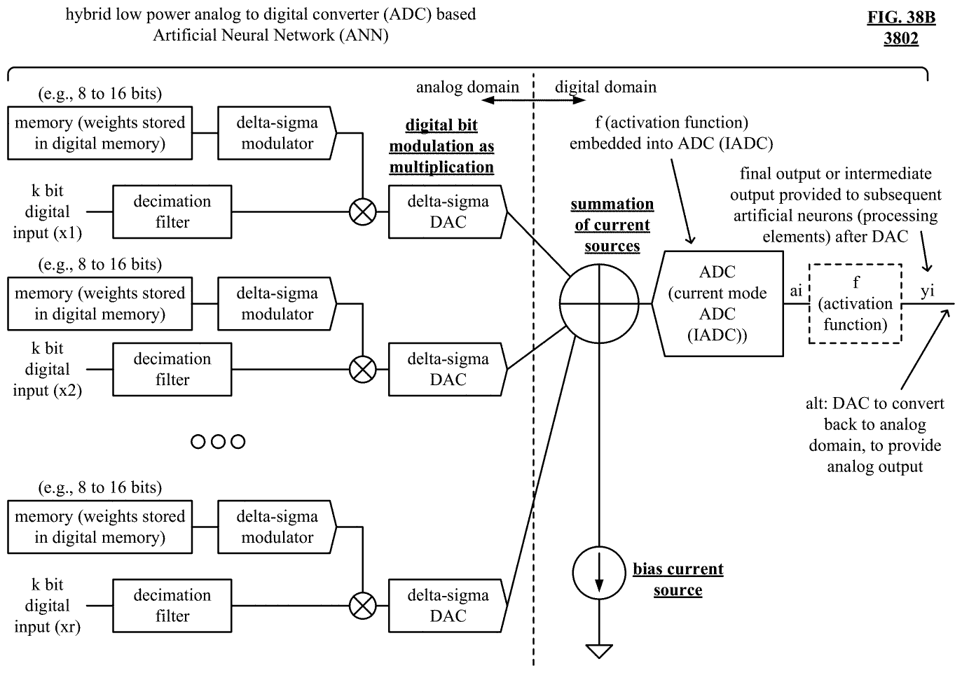

FIG. 37A is a schematic block diagram showing an embodiment 3701 of a biological model of a structure of neurons operative within neural network processing in accordance with the present disclosure. This diagram shows a model that is based on how the human brain works in terms of processing, making decisions, coming to conclusions, etc. with respect to the connections between neurons within the human brain. For example, a human brain includes a significant number (e.g., billions, trillions, etc.) of neurons connected together. These neurons are connected to one another via axons. A neuron, alternatively referred to as a nerve cell, operates by generating signals based on an electrochemical basis and communicates with other neurons via specialized connections called synapses. As shown in this diagram, a typical structure of a neuron includes a cell body that includes a nucleus, dendrites, synapses, and an axon. The dendrites are branching input structures of the neuron, and the axon is a branching output structure of the neuron. The axons connect to dendrites of other neurons via synapses. Electrochemical signals are received via the dendrites (branching input structures of the neuron), travel through the cell body, and based on processing performed within the cell body, and output electrochemical signal is transmitted down the axon to other neurons.

The dendrites extend from the cell body (e.g., a few micrometers from the cell body). The axon extends from the cell body (e.g., sometimes as up to 1 m in a human or some other animal). In an example of operation and implementation, a neuron typically receives signals via the dendrites that extend from the cell body and sends out signals via the axon. Signals transmitted via the axon of one neuron are received by a dendrite of another neuron. In addition, the synapses of the neuron may connect the axon of the neuron to another axon or may connect a dendrite to another dendrite. The signaling that is transmitted between neurons are electrochemical, including both an electrical component and a chemical component. Based on a voltage gradient across the membrane of the neuron, the neuron is operative to generate an electrochemical pulse, sometimes referred to as an action potential. This electrochemical pulse travels along the axon and interacts with connections with synapses of other neurons. Note that these electrochemical signals may operate to increase or decrease the voltage that reaches the cell body of another neuron.

Note that there may be instances in which the neuron does not generate an output signal based on inputs received by it. For example, a neuron will only transmit an electrochemical signal (e.g., will fire) based on the input signals that it receives exceeding a particular threshold in a particular period of time (e.g., exceed a certain amount/threshold in a short time period). Note also that the synapses that connect the axons to dendrites may vary in strength. For example, good synapse connections are operative to allow a larger signal to propagate than poor synapse connections. Note also that synapses may be excitatory (e.g., to stimulate) or inhibitory (e.g., to restrict). For example, the output of a neuron may be operative either to stimulate or to restrict the operation of another neuron.

This model of the structure of a neuron is inspired based on the biology of the human brain, which has been studied extensively by scientists for many years. Based on this model, an artificial neuron (processing element) is constructed in an effort to perform the decision-making operations as performed within the human brain. Artificial Intelligence (AI) systems operate based on Artificial Neural Network (ANN) processing that is performed by different respective artificial neurons (processing elements) within an Artificial Neural Network (ANN) to generate one or more outputs.

FIG. 37B is a schematic block diagram showing an embodiment 3702 of a model of an artificial neuron (processing element) operative within Artificial Neural Network (ANN) processing in accordance with the present disclosure. This diagram shows a number of connections that are provided to a summation block. Note that the respective connections that are provided to the summation block may each have a respective weight, shown as w1 w2, and so on. As inputs are provided via these respective weighted connections, they are summed together within the summation block. Then, in some implementations, an activation function, shown as f(net), operates on the resulting summation. Note that one example of an activation function, f(net), is an identify function that does not modify the resulting summation. In other examples, the activation function, f(net), is some function ge a non-linear function) that does modify the resulting summation.

For example, in an effort to model decision-making made by the human brain based on the electrochemical signaling that is performed between neurons, such as based on the previous diagram, not only are the respective inputs that are provided to the summation block respectively weighted, but after the summation operation, an activation function is applied to the summation results. Note that decision-making that is performed within the human brain is not always linear. The use of an appropriate activation function is operative to modify the results of the summation operation as needed in accordance with Artificial Neural Network (ANN) processing. For example, considering decision-making as performed by a person, there may be instances in which a particular conclusion, though arrived at logically and based on accurate data inputs, is nonetheless not ultimately selected based on one or more considerations.

The use of an activation function provides for further refinement of the decision-making process in accordance with Artificial Neural Network (ANN) processing and arriving at a conclusion/output. In addition, note that while some activation functions operate to perform one or more non-linear operations on the summation result, another activation function may alternatively be implemented that does not perform any operation on the summation results and simply passes the summation results as the output. That is to say, certain implementations of an artificial neuron/processing element may be implemented without an activation function. However, in certain applications, the use of an activation function is operative further to direct the decision-making process in accordance with Artificial Neural Network (ANN) processing.

FIG. 37C is a schematic block diagram showing an embodiment 3703 of a set of artificial neurons (processing elements) artificial neuron and weighted connections with adjustable strengths operative within Artificial Neural Network (ANN) processing in accordance with the present disclosure. This diagram shows a number of inputs provided at an input layer, shown as x1 x2, and so on. Each of the respective inputs is connected to the respective artificial neurons/processing elements within a hidden layer via respective weighted connections. Note that the weights of the connections between the inputs of the input layer and the artificial neuron/processing elements of the hidden layer may be adapted/changed based on any number of considerations (e.g., change over time based on prior decision-making, change over time based on different operational conditions, changed over time based on different environmental conditions, changed over time based on processing resource availability, etc.).

Each of the respective artificial neurons/processing elements is configured to receive weighted inputs from the input layer via the weighted connections and to perform the summation operation and application of an activation function as described in the prior diagram to generate a respective output that is provided via a connection to an output layer. Note that while this diagram shows one output within the output layer, more than one output may be included within the output layer. Each of the respective artificial neurons/processing elements is configured to perform processing based on the weighted inputs that it receives. Note that different respective artificial neuron/processing elements may be configured to receive differently weighted inputs and also to apply different activation functions to the summation results generated based on the weighted inputs that it receives.

Generally speaking, an Artificial Neural Network (ANN) includes a set of inputs, hidden artificial neurons (processing elements) that operate based on those inputs that may be weighted, and produces one or more outputs based on the processing as performed by the hidden artificial neurons (processing elements) within the ANN.

Such Artificial Neural Network (ANN) processing may be applied to a variety of different applications including pattern recognition, machine learning, classification, decision-making, etc. An ANN is operative to provide human-like problem solving characteristics using physical elements and hardware components. In addition, note that Artificial Intelligence (AI) as provided using one or more Artificial Neural Networks (ANNs) may be employed in a variety of different applications including image processing, speech processing, video processing, etc.

FIG. 37D is a schematic block diagram showing another embodiment 3704 of a model of an artificial neuron (processing element) operative within Artificial Neural Network (ANN) processing in accordance with the present disclosure. This diagram also shows a number of inputs, x1 x2, and so on that are provided via weighted connections (w(i,1) w(i,2), and so on) to a summation block. Note that the summation block may also include an offset or bias, b1, that is added to or subtracted from the weighted inputs that are received by the summation block. The output of the summation block, ai, is provided to an activation function block to produce the output, yi, of the artificial neuron (processing element).

An artificial neuron (processing element) as shown in this diagram, which may be implemented within an Artificial Neural Network (ANN), may be viewed as corresponding to a neuron within a biological application (e.g., within the human brain). The artificial neuron (processing element) is a computational note with one or more numerical data inputs. The data inputs are weighted via the weighted connections (w(i,1) w(i,2), and so on) and are provided to the summation block. After undergoing appropriate summation, optionally including an offset or bias, b1, that is added to or subtracted to the summation result, and after applying the activation function (e.g., a non-linear function that is applied to the summation result), the output, yi, is broadcast to an output layer. Alternatively, the output, yi, is broadcast to one or more other artificial neurons (processing elements) within the Artificial Neural Network (ANN). For example, consider that multiple respective hidden layers are implemented within the ANN, then the output of one artificial neuron (processing element) is provided to one or more other artificial neurons (processing elements).

In an example of operation and implementation, each neuron performs the linear combination of its weighted inputs to generate the summation result. When employed, an offset or bias, b1, is operative to modify the summation result. Also, when employed, the activation function is operative further to modify the summation result.

A hybrid analog/digital Artificial Neural Network (ANN) processor based on such an artificial neuron (processing element) can limit the non-idealities and temperature drift in the analog components. Such an artificial neuron (processing element) provides for lower power consumption making it ideal for mobile and portable devices. In addition, such an artificial neuron (processing element) includes a much smaller die area/implementation area than the digital multiplication and summation used within prior art Artificial Neural Networks (ANNs) by using a very low power analog to digital converter (ADC) (e.g., current mode ADC). In addition, note that each artificial neuron (processing element) within an Artificial Neural Network (ANN) includes an analog to digital converter (ADC) and a digital to analog converter (DAC). Overall, within the ANN, this constitutes a massive array of ADCs and DACs. However, by implementing a hybrid analog/digital Artificial Neural Network (ANN) processor based on such an artificial neuron (processing element), a significant reduction in power and a much smaller footprint is achieved compared to prior art approaches.

Certain embodiments of an Artificial Neural Network (ANN) in accordance with this disclosure operate by performing summation in the analog domain (e.g., summing to were more analog current signals together). In addition, certain embodiments operate by performing multiplication in the analog domain (e.g., using a delta-sigma DAC to steer the analog current thereby effectively performing a multiplication of an analog current signal). In addition, certain embodiments of a ADC (e.g., a low power ADC, a current mode ADC (IADC)) are appropriately implemented such that the activation function of the artificial neuron (processing element) is inherent to the ADC. Such a hybrid analog/digital Artificial Neural Network (ANN) processor is significantly more insensitive to analog and non-idealities and temperature drift than prior art approaches.

FIG. 37E is a schematic block diagram showing the embodiment 3705 of the previous diagram with labeling that corresponds functional blocks with physical elements and hardware components within an artificial neuron (processing element) operative within Artificial Neural Network (ANN) processing in accordance with the present disclosure. This diagram shows the correspondence between various physical elements of hardware components to the functional blocks operations of the artificial neuron (processing element).

The inputs, x1 x2, and so on, are shown as being provided as analog current sources. That is, each of the respective inputs is a respective corresponding analog current source. The weighting of the analog current sources via the respective weighted connections that are provided to the summation block is performed based on multiplication that is performed using a delta-sigma digital to analog converter (DAC). The summation of the current sources within the summation block is performed by connecting the weighted connections from the analog current sources to a common node. Note that the activation function itself may be embedded within one or more of the physical elements and/or hardware components of the artificial neuron (processing element). For example, considering and implementation of an artificial neuron (processing element) that includes an analog to digital converter (ADC) and/or digital to analog converter (DAC), the operation of the activation function may be implemented within one or more of these components of the artificial neuron (processing element).

Also, in some examples, note that a bias current source is added or subtracted from the summation of the current sources within the summation block (e.g., the bias current sources added or subtracted to the analog current sources that are added together at the common node to which they are connected.

FIG. 37F is a schematic block diagram showing various embodiments 3706 of activation functions operative within Artificial Neural Network (ANN) processing in accordance with the present disclosure. This diagram shows different respective activation functions that may be used. Note that more than one activation function may be applied to the summation result that is generated within an artificial neuron (processing element). For example, a first activation function may be applied to the summation result to generate a first modified summation result, and a second activation function may be applied to the first modified summation result to generate a second summation result. Depending on a particular application, any number of different activation functions may be applied to a summation result is generated within an artificial neuron (processing element).

This diagram shows activation functions that include an identity function, a step function, a bipolar function, a sigmoid function, a bipolar sigmoid function, a hyperbolic tangent function, a hard hyperbolic tangent function, an absolute function, and the cosine function. Note that these particular activation functions do not comprise an exhaustive list of possible activation functions, and various other activation functions may be used as desired in particular applications.

FIG. 37G is a schematic block diagram showing an embodiment 3707 of a model of an Artificial Neural Network (ANN) processing in accordance with the present disclosure. This diagram shows inputs, x1 x2, and so on, provided via an input layer. The inputs are connected to artificial neurons (processing elements) via weighted connections such that each respective input is appropriately weighted as is provided to the artificial neurons (processing elements). This particular diagram shows more than one layer of artificial neurons (processing elements) such that a first set of artificial neurons (processing elements) is configured to generate intermediate results that are passed to a second set of artificial neurons (processing elements) for further processing. The outputs from the second set of artificial neurons (processing elements) are provided to and output layer that includes one or more final outputs.

Note that different Artificial Neural Networks (ANNs) may include different numbers of hidden layers composed of different respective sets of artificial neurons (processing elements). Also, note that the connections between the different respective sets of artificial neurons (processing elements) may also be implemented to include weighted connections, such that the intermediate results that are passed from a first set of artificial neurons (processing elements) to a second set of artificial neurons (processing elements) may be weighted. Note that when a connection has a weighting factor of zero (0), then that particular weighting factor of zero (0), as applied to an input or an intermediate result, effectively eliminates that particular input or intermediate result from being part of the calculation of a subsequent artificial neuron (processing element). Also, note that when a connection has a weighting factor of one (1), then that particular weighting factor of one (1), as applied to an input or an intermediate result, passes that particular input or intermediate results without modification.

It can be seen that the computational complexity of the Artificial Neural Network (ANN) increases based on the number of artificial neurons (processing elements). For example, consider that each artificial neuron (processing element) has N multiplications, capital, N summations, and a non-linear activation function. An ANN that includes N=10,000 artificial neurons (processing elements) in each layer must process 10,000² multiplications and summations. Such large numbers of digital multiplication requires significant digital computational resources. For example, when implemented using an application specific integrated circuit (ASIC), such a device will inherently include a very large implementation area to perform such large amounts of computations. Considering the complexity of the human brain, a human brain may include up to 10⁹ to 10¹¹ neurons. Implementing an Artificial Neural Network (ANN) having a significantly smaller number of artificial neurons (processing elements) (e.g., 10² 10³ or 10⁴ or more) can nonetheless become significantly complex.

This disclosure presents, among other things, various novel approaches by which the computational operations within an Artificial Neural Network (ANN) may be performed while consuming significantly less power the prior art approaches and also requiring significantly less implementation area to perform such large amounts of computations. For example, implementing certain mathematical operations within the analog and digital domains, including using a very low power analog to digital converter (ADC) (e.g., current mode ADC (IADC)) to sample the summation of analog current sources and generating a digital signal therefrom, significantly reduces power consumption, complexity, implementation area, etc. within an Artificial Neural Network (ANN) in accordance with this disclosure.

For example, certain prior art approaches to implementing an Artificial Neural Network (ANN) are mostly software-based. These approaches use extensive computing resources, digital computers, and/or field programmable gate arrays (FPGAs) to process the significant number of multiplications, some nations, and nonlinear activation functions. These prior art approaches are highly powered consumptive. For example, the significant number of multipliers and summations consume a significant amount of power. In addition, each artificial neuron (processing element) is a multiplier when sending information to another artificial neuron (processing element). This multiplication operation often requires very high power using prior art approaches. Certain Artificial Neural Networks (ANNs) that are implemented using a fully analog processor can have relatively lower power consumption but can still have some major disadvantages.

For example, a fully analog processor may have a significantly large implementation area. In addition, non-idealities in temperature drift in the analog components can generate in accuracy when performing computations. This disclosure presents, among other things, a hybrid analog/digital Artificial Neural Network (ANN) that includes both digital and analog components and that selectively performs certain computations within the analog domain and the digital domain. For example, by performing multiplication and addition in the analog domain, a significant reduction in power may be achieved when compared to prior art approaches. However, analog components can be more susceptible to changes with temperature, environment, etc. or may not work at all at certain temperatures. A 100% analog Artificial Neural Network (ANN) is not ideal within certain applications since, although a 100% analog ANN can be low-power consumptive, such a 100% analog ANN can have certain disadvantages including large area, non-idealities in temperature drift can adversely affect the accuracy of analog components, etc. However, a 100% digital ANN is also not ideal within certain applications since a 100% digital ANN consumes such a significant amount of power. Such a hybrid analog/digital Artificial Neural Network (ANN) in accordance with this disclosure consumes significantly less power than prior art ANNs and also has a much smaller implementation area.

Such a hybrid analog/digital Artificial Neural Network (ANN) that consumes such reduced amount of power and also has a much smaller footprint than prior art ANNs provides opportunity to implement Artificial Intelligence (AI) within areas that previously were difficult if not impossible to service using AI. For example, such a low power consumptive and small footprint Artificial Neural Network (ANN) may be implemented within edge computing devices. For example, mobile devices, handheld devices, portable devices, sensors, biomedical devices, smart phones, cell phones, etc. are just some examples of devices and applications that prior art Artificial Neural Networks (ANNs) are not well suited to service. However, a low power consumptive and small footprint Artificial Neural Network (ANN) in accordance with this disclosure may be implemented within such edge computing devices. In addition, the hybrid analog/digital nature of such an Artificial Neural Network (ANN) in accordance with this disclosure significantly reduce or eliminate any adverse effect of any non-idealities and temperature drift in the analog components by appropriately implementing certain operations and components within the digital domain.

FIG. 37H is a schematic block diagram showing another embodiment 3708 of a model of an Artificial Neural Network (ANN) processing in accordance with the present disclosure. This diagram provides yet another example with multiple hidden layers composed of different respective sets of artificial neurons (processing elements).

In general, a neural network model that is used to implement an Artificial Neural Network (ANN) includes a number of inputs (e.g., x0, x1, x2, and as desired up to xm), a number of neurons (e.g., hidden nodes, such as represented by multiple layers such as neurons h11, h12, and as desired up to h1a in layer 1 and then optionally to include neurons h21, and as desired up to h2b in layer 2, and neurons h11, h12, and as desired up to h1a in layer 1 and so on and then optionally to include neurons h21, h32, and as desired up to h3c in layer 3 and so on and optionally to include neurons h21, and as desired up to hnd in layer n, such that m, a, b, c, n, d, are all positive integers), and number of outputs (e.g., y0, y1, and as desired up to yp such that p is a positive integer). Note also that neural network model may also include one or more biases (e.g., an h12 bias hb12 that biases the neuron h12, a y1 bias yb1 that biases the output y1, as some possible examples). Note that the respective hidden nodes may be viewed as artificial neurons (processing elements) within the Artificial Neural Network (ANN).

In general, a neural network model that is used to implement an Artificial Neural Network (ANN) considers inputs that connect via connections between the inputs and neurons (e.g., hidden nodes that are composed of artificial neurons (processing elements)) that may also interconnect with other neurons (and layers) that connect via other connections to outputs. The inputs are known and the outputs are observed/known. The respective connections between the inputs, neurons (e.g., artificial neurons (processing elements)), and outputs, etc. have respective weights that scale the output from a given node that is provided to another node. As an example, a corresponding weight scales the output from neuron h11 in layer 1 that is provided to neuron h2b in layer 2 and corresponds to the connection between neuron h11 in layer 1 to the neuron h2b in layer 2. Analogously, another corresponding weight scales the output from input x2 that is provided to neuron h12 in layer 1 and corresponds to the connection between input x2 to the neuron h12 in layer 1. As the neural network model that is used to implement an Artificial Neural Network (ANN) initiates, the respective weights corresponding to the may be initialized the weights to predetermined values and then updated as the neural network model that is used to implement an Artificial Neural Network (ANN) observes the outputs and adapts the weights so as better to model the actual performance of the model.

In general, the weights are initialized to some values (e.g., all equal to begin in one specific embodiment, each having different respective values in another specific embodiment, etc.). Then, the inputs are provided to the neural network model, and the outputs are measured/observed, and over time and over different respective sets of samples of both the inputs are provided and outputs are measured/observed, and adjustment of the respective the different respective weights that scale the outputs provide from node to node among the connections between the inputs, hidden neurons, and outputs over time until the neural network model acceptably models or emulates the behavior of the application or system to which the Artificial Neural Network (ANN) is applied (e.g., substantially, approximately, etc. within some acceptable degree such as based on any desired industry-accepted tolerance for its corresponding term and/or relativity between items, such an industry-accepted tolerance ranges from less than one percent to fifty percent, etc.). The determination of the weights within the neural network model may be made based on backpropagation.

With respect to performing backpropagation, one approach is to use a partial derivative (e.g., ∂C/∂w) of a cost function, C, with respect to any weight with (or bias) in the neural network model. The expression of the partial derivative (e.g., ∂C/∂w) of the cost function, C, provides a means to determine how much the output or cost, C, changes as the weights and/or biases are changed. Being a partial derivative, the term in directed to or limited to the particular influence of the respective weight associated therewith while (ideally) removing the effects of other influences in the neural network model. In general, back propagation is process in which the error values (e.g., different between the actual outputs that are measured/observed and those produced by the neural network model) are fed back into the system backwards starting from the outputs and backwards to any prior layers and eventually to the inputs of the neural network model. As the neural network model is being trained/is learning, each respective neuron includes an associated error value that substantially represents its respective contribution to the original output.

Also, a loss function may be viewed as an output of the neural network model as compared to a desired output or in the case of modeling actual behaviors, with measured/observed output. In general, the backpropagation process uses the respective error values associated with the respective neurons in the neural network model to calculate the gradient or partial derivative (e.g., ∂C/∂w) of the cost function, C, with respect to the weights in the neural network model. Over time, as more and more samples of the inputs are provided and more and more samples of the outputs are measured/observed, as the respective values of the weights within the neural network model are updated, adjusted, refined, etc., the neural network model eventually converges on a model that substantially, approximately, etc. models or emulates the actual performance of the system that such a specific example of a neural network model is implemented to model.

Also, note that the hidden neurons in the intervening one or more layers between the inputs and outputs organize themselves in a manner that the different respective neurons adapt and change as a function of the other neurons based on all of the inputs.

In general, note that the neural network model is trained and can be adjusted and re-trained over time with more and more samples of inputs and measured/observed output. In addition, note that as more and more information is provided, the neural network model can be continually updated, revised, improved, etc. so that it more accurately and effectively models the actual system that the neural network model is intended to model.

Once the neural network model is trained, then the neural network model, when modeling a system, may be used to generate predictive performance of the outputs of the neural network model (e.g., that correspond to outputs of the system) based on various values of the inputs of the neural network model (e.g., that correspond to inputs of the system) that characterize the configuration and operation of the system. In some examples, this predictive performance is then used to design and implement another system based on the learning that has been achieved based on the neural network model that models the system.

This disclosure presents, among other things, a means by which predictive performance of one or more outputs of a system may be determined based on various values of one or more inputs that characterize the configuration and operation of the system. For example, some systems can be so complex, and have such a large number of variables, that attempting to design a realistic model by merely guessing can become an infeasible task. For example, a system can be such highly complex systems with so many highly complex components, and even more complex possible interactions being possible among these many diverse and complex components that to create such an accurate model that allows for future design of an improved system can be impossible.

A neural network model that is used to implementation an Artificial Neural Network (ANN) may be trained using a technique of “back propagation”. In such a scheme, various input variables are provided to the neural network model.

Outputs, or measurements from observation of the system behavior, which the neural network model may attempt to predict are provided at the output layer.

Many samples of these input variables, and observed output measurements will be taken, from various system configurations and various workloads, with the aim at building different models to predict at least one of the measured outputs. Initially, the neural network model will produce more or less randomly guessed results, but with each sample available, the network can be repeatedly trained via back propagation, eventually leading to more accurate prediction capabilities. When the model is well trained, it can then provide estimates for system performance for as of yet, unobserved (or even theoretically deployed) system configurations. This can help greatly in the design and provisioning of resources within a system to meet certain performance goals.

FIG. 37I is a schematic block diagram showing an embodiment 3709 of an artificial neuron (processing element) operative within Artificial Neural Network (ANN) processing in accordance with the present disclosure. The artificial neuron (processing element) includes a digital to analog converter (DAC), memory, a delta-sigma DAC, a low pass filter (LPF). The output of the delta-sigma DAC is tied to the output of the LPF such that current modulation as provided from the output of the delta-sigma DAC operates as multiplication to the analog current signal that is output from the LPF. An input (e.g., a digital input signal, such as including k bits, where k is a positive integer greater than or equal to 1) is provided to the DAC on the left-hand side of the diagram. The DAC outputs a first analog current signal that is passed through the LPF. Memory stores weights (e.g., digital memory stores the weights in digital format, having a certain precision such as 8 to 16 bits for each weight). A selected weight is provided to the delta-sigma DAC that outputs a second analog current signal based on the selected weight.

The analog signals our current signals in this artificial neuron (processing element). The weights are stored in digital memory (e.g., N bits, such as 8 to 16 bits) that can be easily accessed by selecting the appropriate and desired weight. Each of the weights is modulated by a delta-sigma DAC to produce a 1 bit (or an M bit, such that M<N) digital output. The one bit digital output is used to modulate the DAC analog output current after having passed through the LPF. In operation, this is equivalent to an N-bit late that is multiplied with the DAC analog output current that has passed through the LPF.

In an example of operation and implementation, consider a delta-sigma DAC that is configured to output a bit having a value of 1 or 0. Also, consider an 8-bit level for the weight, such that the weights that are stored in the digital memory are 8 bits each, such that a maximum value would be 255 (i.e., 11111111), and the minimum value would be 0 (i.e., 00000000). To get any number between 0 and 255, the delta-sigma DAC is configured to toggle between the output values of 1 and 0 at a very high rate, yet such that the average value output from the delta-sigma DAC would correspond to that desired number between 0 and 255. In a specific example, consider that the delta-sigma DAC is configured to output a numerical value of 128. In such a specific example, the delta-sigma DAC would toggle to output a value of 0 during 50% of the time and would toggle to output a value of 1 during 50% of the time, such that the output of the delta-sigma DAC would be half time on an half time off, and the resultant output provided from the delta-sigma DAC would then correspond to the numerical value of 128. In one specific example, the maximum value output of 255 (i.e., 11111111) is used to correspond to a maximum scaling factor of 1.0 (i.e., full scale), and the minimum value output of 0 (i.e., 00000000) is used to correspond to a minimum scaling factor of 0.0. Note that when scaling factors or weights ranging between 0.0 and 1.0 are desired, the output from the delta-sigma DAC may be viewed as being normalized based on the maximum output value/full-scale, such that the maximum output value corresponds to a weight of 1.0.

This provides a very efficient and low power way to perform multiplication in the analog domain. Typically, within an Artificial Neural Network (ANN), the weights range between 0.0 and 1.0. Typically, a maximum scaling factor 1.0 is used within ANNs. Note that by setting a scaling factor to 0.0, a particular artificial neuron (processing element) will have no effect on the output or a subsequent artificial neuron (processing element). The output from the artificial neuron (processing element) is provided to a summation block with outputs from other artificial neurons (processing elements). Summing the analog electric current signals that are output from the respective artificial neurons (processing elements) is performed by connecting the outputs of those artificial neurons (processing elements) together at a common node. Also, with respect to that summation block, note that a bias current source may be implemented to provide some DC offset to the summation of the current sources in the summation block that is implemented by connecting the outputs of those artificial neurons (processing elements) together at the common node. That is to say, a bias current source may inject an additional analog current signal to that common node thereby operating to provide a DC offset.

This diagram shows an implementation of an artificial neuron (processing element) that is operative within an Artificial Neural Network (ANN) that includes a hybrid implementation of digital and analog components, performing certain operations within the analog to digital domains, respectively. Such an artificial neuron (processing element) consumes less power and has a smaller implementation area than prior art approaches.

FIG. 37J is a schematic block diagram showing an embodiment 3710 of a sigma-delta digital to analog converter (DAC) operative within Artificial Neural Network (ANN) processing in accordance with the present disclosure. This diagram shows a digital input signal being provided to a delta-sigma driver (e.g., a 1 bit delta-sigma DAC) that outputs an analog signal based on that digital input signal. This implementation of a delta-sigma DAC can operate as described above such that the delta-sigma DAC is configured to toggle between the output values of 1 and 0 at a very high rate so as to achieve any desired numerical value output based on the digital input signal. In an example of operation and implementation, consider an 8-bit level for the weight, such that the weights that are stored in the digital memory are 8 bits each, such that a maximum value would be 255 (i.e., 11111111), and the minimum value would be 0 (i.e., 00000000). To get any number between 0 and 255, the delta-sigma DAC is configured to toggle between the output values of 1 and 0 at a very high rate, yet such that the average value output from the delta-sigma DAC would correspond to that desired number between 0 and 255.

FIG. 37K is a schematic block diagram showing an embodiment 3711 of a sigma-delta analog to digital converter (ADC) operative within Artificial Neural Network (ANN) processing in accordance with the present disclosure. Delta-sigma modulation is operative to convert an input signal (e.g., an analog input signal, or alternatively signal corresponding to a weight selected from the memory) into a pulse frequency, or pulse density, which can be understood as pulse-density modulation (PDM). The ultimate output from the delta-sigma ADC is a digital output signal. A delta-sigma ADC may be viewed as including a voltage to frequency converter portion and a frequency counting portion.

A delta-sigma or other pulse-density or pulse-frequency modulator generates a pulse stream in which the frequency of the pulses in the stream is proportional to the input signal. Consider an analog input voltage signal, v, then the frequency of the pulses in the stream, f, is equal to the analog input voltage signal, v, times some constant that corresponds to the particular implementation. A feedback loop monitors the integral of the analog input voltage signal, v, and when the integral has incremented by a particular amount, a delta, which is indicated by the interval waveform crossing the threshold, T, it subtracts the delta from the integral of the analog input voltage signal, v, so that the combined waveform sawtooths between the threshold, T, and T−delta. As such, f=k×v. A counter sums the number of pulses that occur in a predetermined time period, P, so that the sum of those pulses is P×f=k×P×v.

Referring to the diagram, and referring specifically to the voltage to frequency converter portion of the delta-sigma ADC, an input signal is provided to a difference node that determines the difference between the input signal and the feedback path coming from and impulse generator. A stream of delta impulses generated at each threshold crossing is output from the impulse generator, and the difference between that stream of delta impulses and the input signal is fed to an integrator. This difference is then integrated within the integrator to produce a signal that is compared to a threshold within a comparator. When the signal output from the integrator falls below the threshold, the comparator triggers the operation of the impulse generator to produce a fixed-strength impulse that is then fed back such that the difference between the fixed-strength impulse and the input signal is again made, and that difference is provided to the integrator.

Referring to the frequency counting portion of the delta-sigma ADC, the signal output from the comparator is provided to a counter that performs summation of the pulses that occur in a particular summing interval. At the end of the summing interval, the output from the counter is provided to a buffer that subsequently outputs a digital output signal. The buffer may be viewed as providing a sequence of digital output values corresponding to quantization's of the input signal levels during the respective summing intervals.

FIG. 37L is a schematic block diagram showing an embodiment 3712 of a first-order sigma-delta analog to digital converter (ADC) operative within Artificial Neural Network (ANN) processing in accordance with the present disclosure. This diagram shows an input signal that is provided to a difference node that also receives an output from a feedback path from a 1 bit DAC. The difference between the input signal and the output from the feedback path from the 1 bit DAC is provided to an integrator, and the output from the integrator is provided to a quantizer/latched comparator that is configured to generate a one bit data stream that is provided as an input to the 1 bit DAC and also to a digital filter that subsequently outputs a digital output signal.

FIG. 37M is a schematic block diagram showing an embodiment 3713 of a second-order sigma-delta analog to digital converter (ADC) operative within Artificial Neural Network (ANN) processing in accordance with the present disclosure. This diagram is similar to the previous diagram in certain ways and includes another difference node and integrator thereby providing second-order operation. The two respective difference nodes that precede the two respective integrators receive the output from the feedback path from the 1 bit DAC. A second-order sigma-delta ADC typically will provide more conditionally stable operation then a first order ADC.

FIG. 37N is a schematic block diagram showing an embodiment 3714 of an Artificial Neural Network (ANN) processing in accordance with the present disclosure. This diagram shows a number of artificial neurons (processing elements) (e.g., of FIG. 37I) that provide their respective analog output current signals to a common node that performs the summation of those current sources. In certain examples, with respect to that summation block, note that a bias current source (shown at the bottom middle of the diagram) may be implemented to provide some DC offset to the summation of the current sources in the summation block that is implemented by connecting the outputs of those artificial neurons (processing elements) together at the common node. As can be seen, a bias current source may inject an additional analog current signal to that common node thereby operating to provide a DC offset.

In certain examples, note that the bias current source may be implemented as a fixed/constant-valued current source. In other examples, note that the bias current source may be implemented as a variable/configurable current source providing flexibility to adjust the value of a bias current signal output from the bias current source based on any one or more considerations (e.g., based on environmental conditions, based on historical operation, adaptation of the particular Artificial Neural Network (ANN) processing being performed, etc.). This flexibility in design may also be made with respect to other examples, embodiments, diagrams, etc. that includes such a bias current source.

A current mode ADC (IADC) is configured to receive the summed current from the respective artificial neurons (processing elements), and optionally including an additional analog current signal from the bias current source, and to generate an output signal, ai, that may subsequently be processed by an activation function to generate an output, yi. Note that the activation function may alternatively be embedded within the IADC such that the inherent operation of the IADC also performs the processing that corresponds to the activation function. The output, either ai (e.g., based on the activation function being embedded within the IADC) or yi (e.g., based on the activation function being implemented separately from the IADC), is provided to a digital to analog converter (DAC). The DAC is configured to provide a final output or an intermediate output that may be provided to subsequent artificial neurons (processing elements). In an implementation to provide an analog final output or intermediate output signal, the DAC on the right-hand side of the diagram can be bypassed or not implemented such that the output, either ai (e.g., based on the activation function being embedded within the IADC) or yi (e.g., based on the activation function being implemented separately from the IADC), is provided as the final output or the intermediate output signal in analog form coming from the IADC or a separately implemented activation functional block.

This diagram shows one particular embodiment 3714 that includes a hybrid implementation using the digital and analog components and performing certain operations in accordance with Artificial Neural Network (ANN) processing within the analog and digital domains. The respective artificial neurons (processing elements) within the Artificial Neural Network (ANN) also include a hybrid implementations of digital and analog components, performing certain operations within the analog to digital domains, respectively. This embodiment 3714 provides a significant reduction in power consumption compared to prior art approaches. In addition, this embodiment 3714 includes a much smaller implementation area than prior art approaches.

FIG. 38A is a schematic block diagram showing another embodiment 3801 of an artificial neuron (processing element) operative within Artificial Neural Network (ANN) processing in accordance with the present disclosure. This diagram is a different implementation of an artificial neuron (processing element) than shown in FIG. 37I. and this diagram, memory stores weights (e.g., N-bits each, such as N being 8 to 16 bits) similarly as in FIG. 37I, yet a selective weight is provided to a delta-sigma modulator that is configured to produce a first digital output signal that is 1-bit digital output signal (or an M-bit digital output signal, such that M<N) that is used to modulate a second digital output signal from a decimation filter that has processed a k-bit digital input signal, shown as x1 in this diagram. Note that N, M, and k are all positive integers.

In operation, a decimation filter is operably coupled and configured to process a digital input signal (x1) to generate the second digital output signal having a lower sampling rate and a higher resolution than the digital input signal (x1). In addition, the decimation filters operably coupled and configured to filter out quantization noise that may exist within the k-bit digital input signal that is provided to the decimation filter and to ensure that any such noise is filtered out before performing multiplication with the first digital output signal provided from the delta-sigma modulator (e.g., a 1-bit digital output signal (or an M-bit digital output signal, such that M<N)).

This second digital output signal from the decimation filter is then modulated by the first digital output signal provided from the delta-sigma modulator (e.g., a 1-bit digital output signal (or an M-bit digital output signal, such that M<N)). The modulation of the second digital output signal provided from the decimation filter by the first digital output signal that is output from the delta-sigma modulator (e.g., a 1-bit digital output signal (or an M-bit digital output signal, such that M<N)) is equivalent to an N-bit weight digital signal multiplied with a k-bit digital input signal.

After this multiplication operation, a third digital output signal is provided as an input to a delta-sigma DAC. The delta-sigma DAC is configured to operate as described above including toggling between output values of 1 and 0 at a very high rate so as to achieve any desired numerical value output based on the digital input signal that it receives, which is the third digital output signal based on the N-bit weight digital signal being multiplied with a k-bit digital input signal.

Similar to other implementations, the output from the artificial neuron (processing element) is provided to a summation block with outputs from other artificial neurons (processing elements). Summing the analog electric current signals that are output from the respective artificial neurons (processing elements) is performed by connecting the outputs of those artificial neurons (processing elements) together at a common node. Also, with respect to that summation block, note that a bias current source may be implemented to provide some DC offset to the summation of the current sources in the summation block that is implemented by connecting the outputs of those artificial neurons (processing elements) together at the common node. That is to say, a bias current source may inject an additional analog current signal to that common node thereby operating to provide a DC offset.

In this diagram, a very efficient implementation to perform multiplication in the analog domain is performed, then the addition/summation of the output currents from respective artificial neurons (processing elements) is also performed in the analog domain. This very efficient implementation provides a significant improvement in performance (e.g., lower power consumption, smaller implementation are, etc.) over prior art approaches including those that may be implemented using a significant amount of digital processing resources, such as using digital computers, field programmable gate arrays (FPGAs), etc. to process multiplications and summations and perform non-linear activation functions.

This diagram shows yet another implementation of an artificial neuron (processing element) that is operative within an Artificial Neural Network (ANN) that includes a hybrid implementations of digital and analog components, performing certain operations within the analog to digital domains, respectively. Such an artificial neuron (processing element) consumes less power and has a smaller implementation area than prior art approaches.

In an example of operation and implementation, an Artificial Neural Network (ANN) processing system includes artificial neurons (processing elements) configured to generate a output analog current signals and an analog to digital converter (ADC). An artificial neuron (processing element) includes a digital to analog converter (DAC), an low pass filter (LPF), a delta-sigma DAC, and a multiplier. The DAC is configured to generate a first analog current signal based on a first digital input signal. The LPF is operably coupled to the DAC and configured to process the first analog current signal to generate a first filtered analog current signal. The delta-sigma DAC configured to generate an M-bit current signal based on a digital weight value. The M-bit current signal toggles between a value of 1 and a value of 0 based on the digital weight value such that an average value of the M-bit current signal over a predetermined period of time corresponds to the digital weight value. M is a positive integer greater than or equal to 1. The multiplier is configured to generate a first output current source signal based on the first filtered analog current signal and the M-bit current signal and to provide the first output current source signal to a common node that is operably coupled to at least one other of the artificial neurons (processing elements) and that receives the output analog current signals.

The ADC of the ANN processing system is operably coupled to the common node via a single line and configured to generate a digital output signal based on an input voltage of the ADC. The digital output signal is representative of a summation of the output analog current signals at the common node. The input voltage of the ADC is based on charging of a capacitor of the ADC by the output analog current signals and a digital to analog converter (DAC) output current from the ADC.

In certain examples, the ANN processing system also includes another DAC that is operably coupled to the ADC and configured to generate an analog output signal based on the digital output signal. In some examples, the analog output signal includes an intermediate signal that is provided to one or more other artificial neurons (processing elements) within the ANN processing system.

Also, some implementations of the ANN processing system also include a bias current source that is operably coupled to the common node and configured to provide a bias current to the output analog current signals. The digital output signal is representative of a summation of the output analog current signals and the bias current at the common node.

Also, some variants of the ADC include a built-in activation function such that the ADC is further configured to generate the digital output signal based on the output analog current signals based on the built-in activation function. Examples of the built-in activation function corresponds to an identify activation function, a step activation function, a bipolar activation function, a hard hyperbolic tangent activation function, a Rectified Linear Unit (ReLU) activation function, or a Leaky Rectified Linear Unit (ReLU) activation function.

An example of another artificial neuron (processing element) of the ANN processing system includes another DAC configured to generate a second analog current signal based on a second digital input signal, another LPF is operably coupled to the another DAC and configured to process the second analog current signal to generate a second filtered analog current signal, and another delta-sigma DAC is configured to generate another M-bit current signal based on another digital weight value such that the another M-bit current signal toggles between a value of 1 and a value of 0 based on the digital weight value such that an average value of the another M-bit current signal over a predetermined period of time corresponds to the another digital weight value. M is a positive integer greater than or equal to 1. Also, another multiplier is configured to generate a second output current source signal based on the second filtered analog current signal and the another M-bit current and to provide the second output current source signal to the common node that receives the output analog current signals.

In certain examples, the ADC includes the capacitor, a comparator, a digital circuit, memory, one or more processing modules, and an N-bit digital to analog converter (DAC). The capacitor is operably coupled to the common node and configured to produce the input voltage based on charging by the output analog current signals and the DAC output current. The comparator operably is coupled and configured to receive the input voltage via a first input of the comparator, receive a reference voltage via a second input of the comparator, and compare the input voltage to the reference voltage to generate a comparator output signal. The digital circuit is operably coupled and configured to process the comparator output signal to generate a first digital output signal that is representative of a difference between the input voltage and the reference voltage.

The memory that stores operational instructions, and the one or more processing modules is operably coupled to the digital circuit and the memory and configured to execute the operational instructions to process the first digital output signal to generate a second digital output signal that is representative of the difference between the input voltage and the reference voltage. The second digital output signal includes a higher resolution than the first digital output signal. The N-bit digital to analog converter (DAC) that is operably coupled to the one or more processing modules and configured to generate the DAC output current based on the second digital output signal. N is a positive integer. The DAC output current tracks the output analog current signals, and the input voltage tracks the reference voltage.

In certain examples, the comparator includes a sigma-delta comparator, and the digital circuit includes a clocked flip flop. In other examples, a digital comparator includes both the comparator and the digital circuit. The digital comparator is operably coupled and configured to receive the input voltage via a first input of the comparator, receive the reference voltage via a second input of the comparator, and compare the input voltage to the reference voltage to generate the first digital output signal that is representative of the difference between the input voltage and the reference voltage.

Also, some implementations include a decimation filter coupled to the one or more processing modules and configured to process the second digital output signal to generate another digital output signal having a lower sampling rate and a higher resolution than the second digital output signal.

Another implementation of the ADC includes the capacitor, M-bit analog to digital converter (ADC), memory, one or more processing modules, and an N-bit digital to analog converter (DAC). The capacitor is operably coupled to the common node and configured to produce the input voltage based on charging by the output analog current signals and the DAC output current. The M-bit analog to digital converter (ADC) is operably coupled and configured to receive the input voltage, receive a reference voltage, and compare the input voltage to the reference voltage and generate a first digital output signal that is representative of a difference between the input voltage and the reference voltage.

The memory that stores operational instructions, and the one or more processing modules is operably coupled to the M-bit ADC and the memory and configured to execute the operational instructions to process the first digital output signal to generate a second digital output signal that is representative of the difference between the input voltage and the reference voltage. The second digital output signal includes a higher resolution than the first digital output signal.

The N-bit digital to analog converter (DAC) is operably coupled to the one or more processing modules configured to generate the DAC output current based on the second digital output signal, the DAC output current tracks the output analog current signals, and the input voltage tracks the reference voltage. N is a first positive integer, M is a second positive integer greater than or equal to 1, and N is greater than M.

Some implementations also include a decimation filter coupled to the one or more processing modules and configured to process the second digital output signal to generate another digital output signal having a lower sampling rate and a higher resolution than the second digital output signal.

In another example of operation and implementation, an Artificial Neural Network (ANN) processing system includes artificial neurons (processing elements), a bias current source, an analog to digital converter (ADC), and an output DAC.

The artificial neurons (processing elements) configured to generate output analog current signals. An artificial neuron (processing element) of the artificial neurons (processing elements) includes a DAC, an LPF, a delta-sigma DAC, and a multiplier. The digital to analog converter (DAC) is configured to generate a first analog current signal based on a first digital input signal. The LPF is operably coupled to the DAC and configured to process the first analog current signal to generate a first filtered analog current signal. The a delta-sigma DAC is configured to generate an M-bit current signal based on a digital weight value. The M-bit current signal toggles between a value of 1 and a value of 0 based on the digital weight value such that an average value of the M-bit current signal over a predetermined period of time corresponds to the digital weight value. M is a positive integer greater than or equal to 1. The multiplier is configured to generate a first output current source signal based on the first filtered analog current signal and the M-bit current signal and to provide the first output current source signal to a common node that is operably coupled to at least one other of the artificial neurons (processing elements) and that receives the output analog current signals.

The bias current source is operably coupled to the common node and configured to provide a bias current to the output analog current signals. The analog to digital converter (ADC) of the ANN processing system is operably coupled to the common node via a single line and configured to generate a digital output signal based on an input voltage of the ADC. The digital output signal is representative of a summation of the output analog current signals and the bias current at the common node, and wherein the input voltage of the ADC is based on charging of a capacitor of the ADC by the output analog current signals and a digital to analog converter (DAC) output current from the ADC. The ADC includes a built-in activation function and is further configured to generate the digital output signal based on the output analog current signals based on the built-in activation function. The ANN processing system also includes another (output) DAC that is operably coupled to the ADC and configured to generate an analog output signal based on the digital output signal.

FIG. 38B is a schematic block diagram showing an embodiment 3802 of an Artificial Neural Network (ANN) processing in accordance with the present disclosure. This diagram shows the implementation of a number of artificial neurons (processing elements) of the previous diagram implemented within an architecture that is configured to perform Artificial Neural Network (ANN) processing.

This diagram shows a number of artificial neurons (processing elements) (e.g., of FIG. 38A) that provide their respective analog output current signals to a common node that performs the summation of those current sources. If desired, with respect to that summation block, note that a bias current source may be implemented to provide some DC offset to the summation of the current sources in the summation block that is implemented by connecting the outputs of those artificial neurons (processing elements) together at the common node. As can be seen, a bias current source may inject an additional analog current signal to that common node thereby operating to provide a DC offset.

A current mode ADC (IADC) is configured to receive the summed current from the respective artificial neurons (processing elements), and optionally including an additional analog current signal from the bias current source, and to generate an output signal, ai, that may subsequently be processed by an activation function to generate an output, yi. Note that the activation function may alternatively be embedded within the IADC such that the inherent operation of the IADC also performs the processing that corresponds to the activation function. The output is then either ai (e.g., based on the activation function being embedded within the IADC) or yi (e.g., based on the activation function being implemented separately from the IADC).

In certain examples, note that either ai (e.g., based on the activation function being embedded within the IADC) or yi (e.g., based on the activation function being implemented separately from the IADC) is provided to a digital to analog converter (DAC) to convert back to the analog domain from the digital domain if desired or required in certain applications. For example, a DAC may be implemented on the right-hand side of the diagram to process either ai or yi to provide a final output or an intermediate output in analog format that may be provided to subsequent artificial neurons (processing elements). However, note that certain implementations operate based on providing a final or an intermediate output in digital format that is provided to subsequent artificial neurons (processing elements). For example, on the left-hand side of the diagram, respective digital inputs (e.g., k bit digital input signals, x1 x2, and so on) are provided to the respective decimation filters associated with the artificial neurons (processing elements) that subsequently produce and provide respective analog output current signals to the summation block (e.g., common node) that operates to provide input to the IADC.

The output signal ai (e.g., based on the activation function being embedded within the IADC) or yi (e.g., based on the activation function being implemented separately from the IADC) is then provided as a final output or intermediate output signal and in digital format on the right-hand side of the diagram.

Alternatively, in an implementation configured to provide a final output or intermediate output signal in analog format, the DAC on the right-hand side of the diagram can be bypassed or not implemented such that the output, either ai (e.g., based on the activation function being embedded within the IADC) or yi (e.g., based on the activation function being implemented separately from the IADC), is provided as the final output or the intermediate output signal in analog form coming from the IADC or a separately implemented activation functional block.

In this diagram, a very simple multiplication is performed in the digital domain, then the addition/summation of the output currents from respective artificial neurons (processing elements) is performed in the analog domain. This very efficient implementation also provides a significant improvement in performance (e.g., lower power consumption, smaller implementation are, etc.) over prior art approaches including those that may be implemented using a significant amount of digital processing resources, such as using digital computers, field programmable gate arrays (FPGAs), etc. to process multiplications and summations and perform non-linear activation functions. Though some operations are performed in the digital domain within this particular implementation, it still provides a significant improvement in performance (e.g., lower power consumption, smaller implementation are, etc.) over prior art approaches.

This diagram shows yet another particular embodiment 3802 that includes a hybrid implementation using the digital and analog components and performing certain operations in accordance with Artificial Neural Network (ANN) processing within the analog and digital domains. The respective artificial neurons (processing elements) within the Artificial Neural Network (ANN) also include a hybrid implementations of digital and analog components, performing certain operations within the analog to digital domains, respectively. This embodiment 3802 provides a significant reduction in power consumption compared to prior art approaches. In addition, this embodiment 3802 includes a much smaller implementation area than prior art approaches.

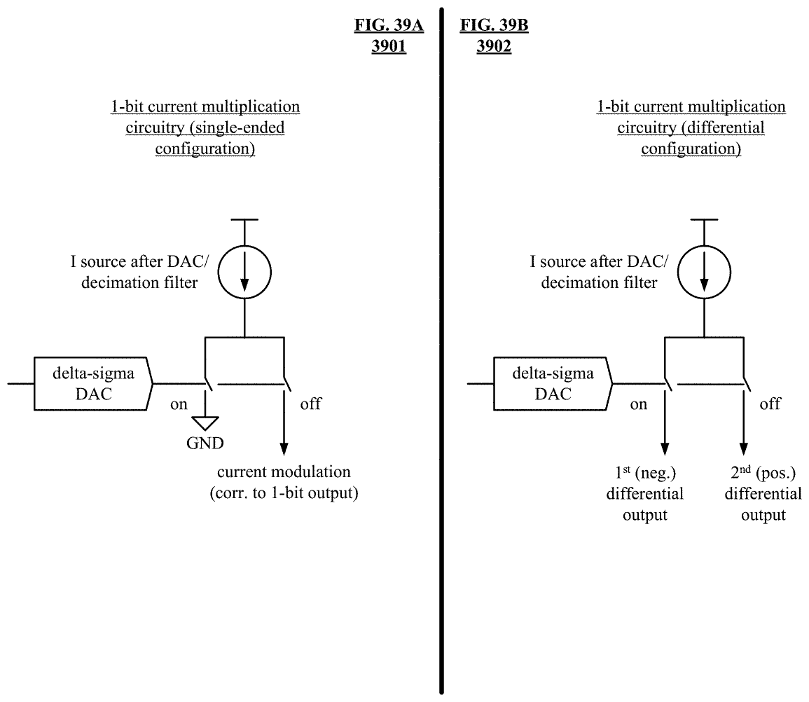

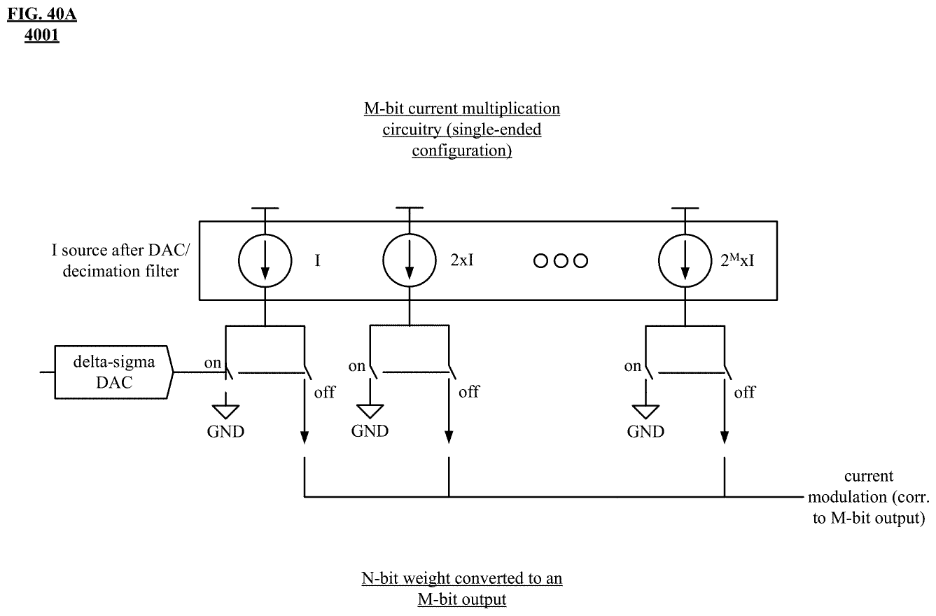

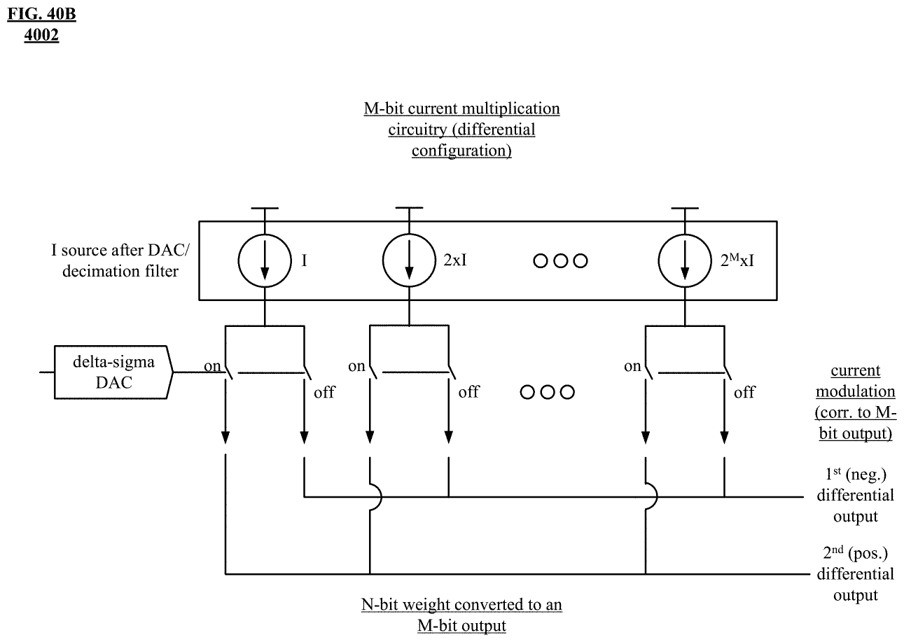

FIG. 39A is a schematic block diagram showing an embodiment 3901 of 1-bit multiplication circuitry having a single-ended configuration operative within Artificial Neural Network (ANN) processing in accordance with the present disclosure. A current source provides an output signal that is provided via two respective paths that coupled to two respective switches. In certain examples, note that this current source may be viewed as being the current source after a digital to analog converter (DAC) (e.g., within the artificial neuron (processing element) of FIG. 37I) or a decimation filter (e.g., within the artificial neuron (processing element) of FIG. 38A).

One of the switches is connected to ground, and the other switch is configured to provide an output current modulation signal, in a single-ended configuration, corresponding to a 1-bit output signal. The two switches are controlled based on an output signal from a delta-sigma DAC. A delta-sigma DAC is implemented to provide a very high resolution to control the switching of the two switches. In an example of operation and implementation, when one of the switches is on/closed, then the other of the switches is off/open. For example, consider a delta-sigma DAC that operates based on an x-bit input signal, such as having x=16 bits, then this will give 2¹⁶ or approximately 65,000 different levels (e.g., corresponding to a 16 bit resolution) by which the output current modulation signal may be generated.

In an example of operation and implementation such as within an artificial neuron (processing element), an N-bit weight (e.g., such as selected from stored in a memory, where the weight may be from 8 to 16 bits) is converted to a 1-bit digital signal that is configured to modulate the current source after a DAC (e.g., within the artificial neuron (processing element) of FIG. 37I) or a decimation filter (e.g., within the artificial neuron (processing element) of FIG. 38A). This implementation provides a very high accuracy and high resolution approach in comparison to prior art approaches to generate the 1-bit digital signal that is configured to modulate the current source after a DAC or a decimation filter, depending on the particular implementation of an artificial neuron (processing element). In addition, this implementation operates by consuming less power than prior art approaches as multiplication is done by steering the current from the current source (e.g., after the DAC or decimation filter, depending on the particular implementation of an artificial neuron (processing element)). Note also that the switches may be implemented in a variety of ways, including using one or more of a P-type metal-oxide-semiconductor field-effect transistor (MOSFET) (PMOS) and/or N-type metal-oxide-semiconductor field-effect transistor (MOSFET) (NMOS). For example, the switch control signal from the delta-sigma DAC may be provided to a gate of a PMOS and/or NMOS to facilitate operation of a switch.

FIG. 39B is a schematic block diagram showing an embodiment 3902 of 1-bit multiplication circuitry having a differential configuration operative within Artificial Neural Network (ANN) processing in accordance with the present disclosure. This diagram is similar to the previous diagram except showing a differential configuration. Instead of the output of one of the switches being grounded, it is configured to operate as one of the two differential outputs. The outputs of the two switches operate as first and second (e.g., negative and positive) differential output components of a differential output signal. Similarly, as described above with respect to the single-ended configuration, in an example of operation and implementation, when one of the switches is on/closed, then the other of the switches is off/open.

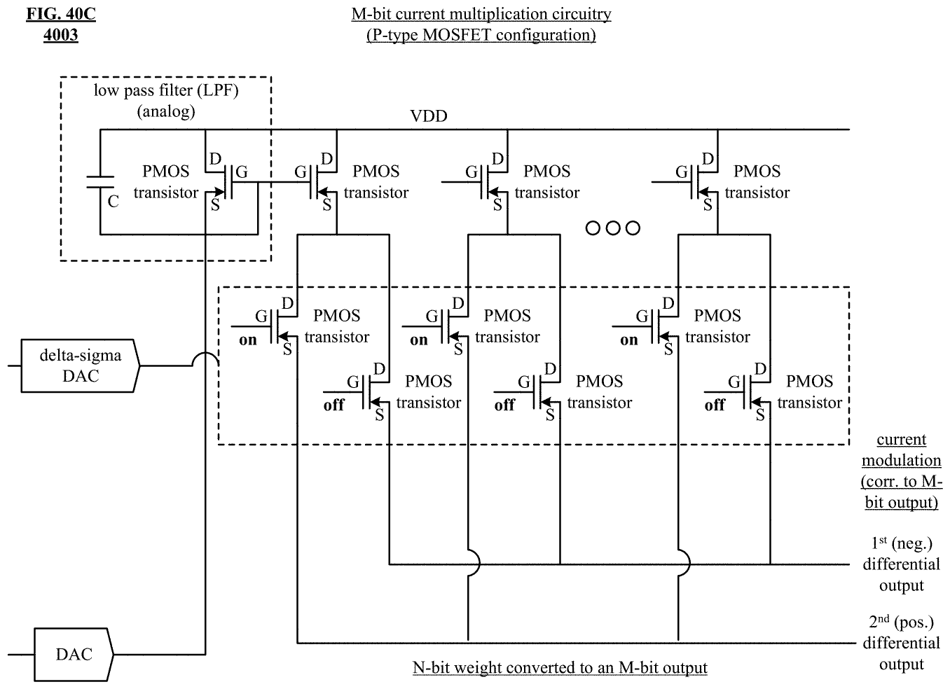

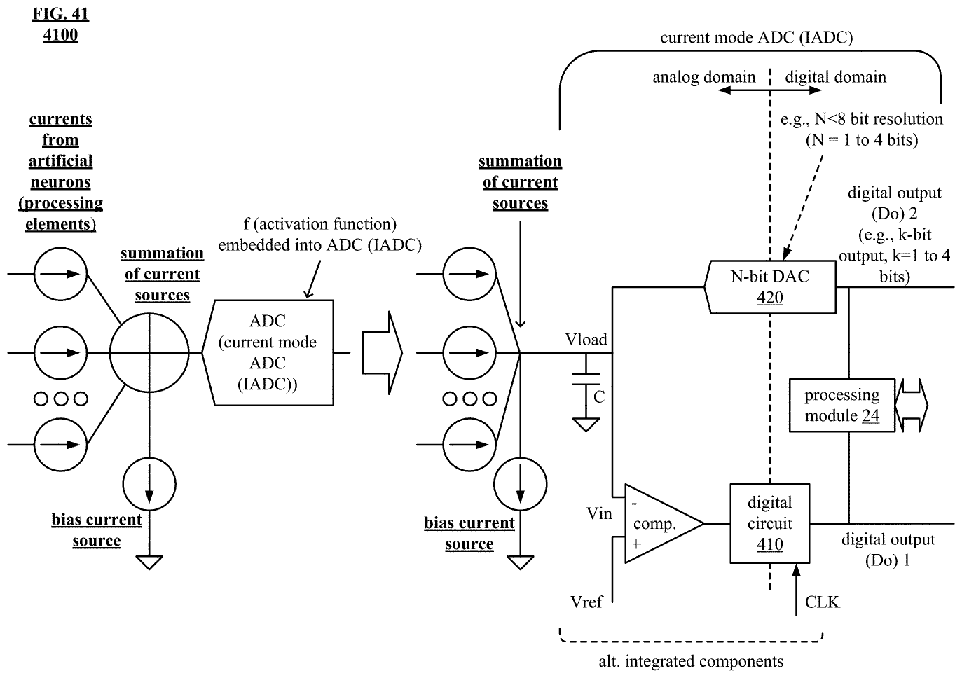

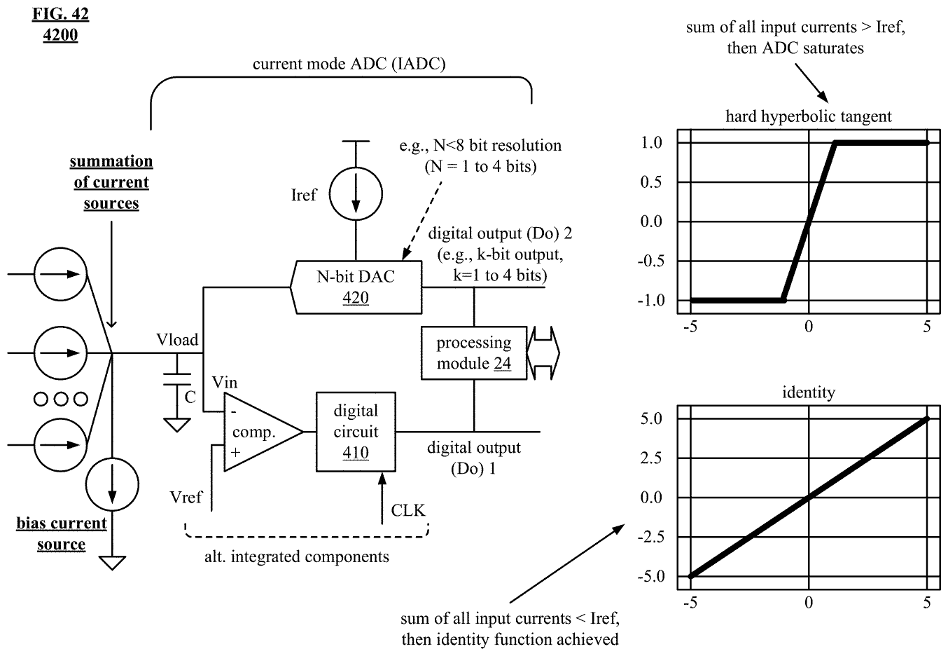

FIG. 40A is a schematic block diagram showing an embodiment 4001 of M-bit multiplication circuitry based on a single-ended configuration operative within Artificial Neural Network (ANN) processing in accordance with the present disclosure. This diagram has similarity to the 1-bit current multiplication circuitry of FIG. 39A, yet includes a number of respective current sources that operate together to facilitate M-bit current multiplication. The maximum output from each of the respective current sources, from left to right, increases such each successive current source located to the right is configured to provide double the output current compared to the current source located to its left (e.g., consider the current of the leftmost current supply to be I, then the current supply to the right of it is configured to output a current of 2×I, and so on up to 2^{M}×I). Note that the respective current sources may be viewed as operating cooperatively to provide different respective current signals that, when combined, are configured to generate an M-bit digital output signal that is configured to modulate the current source after a DAC (e.g., within the artificial neuron (processing element) of FIG. 37I) or a decimation filter (e.g., within the artificial neuron (processing element) of FIG. 38A).

In this diagram, looking at the outputs from each of the respective switches that are serviced by the respective current sources, one of the switches is connected to ground, and the other switch is configured to provide an output current modulation signal, in a single-ended configuration, corresponding to a 1-bit output signal. In combination, the outputs from each of these respective 1-bit output signals operate to provide an M-bit digital output signal that is configured to modulate the current source after a DAC or a decimation filter.

Looking at each of the respective pairs of switches that coupled to the respective current sources, one of the switches is connected to ground, and the other switch is configured to provide an output current modulation signal, in a single-ended configuration, corresponding to a 1-bit output signal. The two switches are controlled based on an output signal from a delta-sigma DAC. A delta-sigma DAC is implemented to provide a very high resolution to control the switching of the two switches. In an example of operation and implementation, when one of the switches is on/closed, then the other of the switches is off/open. This is the case for each of the respective pairs of switches that are coupled to the respective current sources. In certain examples, note that a single delta-sigma DAC is configured to service and control the operation of each of the respective pairs of switches that are coupled to the respective current sources. For example, consider a delta-sigma DAC that operates based on an x-bit input signal, such as having x=16 bits, then this will give 2¹⁶ or approximately 65,000 different levels (e.g., corresponding to a 16 bit resolution) by which the output current modulation signal may be generated.

In an example of operation and implementation such as within an artificial neuron (processing element), an N-bit weight (e.g., such as selected from stored in a memory, where the weight may be from 8 to 16 bits) is converted to a M-bit digital signal that is configured to modulate the current source after a DAC (e.g., within the artificial neuron (processing element) of FIG. 37I) or a decimation filter (e.g., within the artificial neuron (processing element) of FIG. 38A). This implementation provides a very high accuracy and high resolution approach in comparison to prior art approaches to generate the M-bit digital signal (e.g., M=4 such that the M-bit signal is a 4-bit signal) that is configured to modulate the current source after a DAC or a decimation filter, depending on the particular implementation of an artificial neuron (processing element). Generally speaking, note that M may be any positive integer, and M<N in certain examples.

In addition, this implementation also operates by consuming less power than prior art approaches as multiplication is done by steering the current from the current source (e.g., after the DAC or decimation filter, depending on the particular implementation of an artificial neuron (processing element)). Note also that the switches may be implemented in a variety of ways, including using one or more of a P-type metal-oxide-semiconductor field-effect transistor (MOSFET) (PMOS) and/or N-type metal-oxide-semiconductor field-effect transistor (MOSFET) (NMOS). For example, the switch control signal from the delta-sigma DAC may be provided to a gate of a PMOS and/or NMOS to facilitate operation of a switch.

FIG. 40B is a schematic block diagram showing an embodiment 4002 of M-bit multiplication circuitry based on a differential configuration operative within Artificial Neural Network (ANN) processing in accordance with the present disclosure. This diagram is similar to the previous diagram except showing a differential configuration. Instead of the output of one of the switches of each of the respective pairs of switches that are coupled to the respective current sources being grounded, it is configured to operate as one of the two differential outputs. The outputs of the two switches of each of the respective pairs of switches that are coupled to the respective current sources operate as first and second (e.g., negative and positive) differential output components of a differential output signal. Similarly, as described above with respect to the single-ended configuration, in an example of operation and implementation, when one of the switches of a pair of switches that is coupled to a respective current source is on/closed, then the other of the switches is off/open.

FIG. 40C is a schematic block diagram showing an embodiment 4003 of M-bit multiplication circuitry based on a P-type metal-oxide-semiconductor field-effect transistor (MOSFET) configuration operative within Artificial Neural Network (ANN) processing in accordance with the present disclosure. In this diagram, the switches are replaced by P-type metal-oxide-semiconductor field-effect transistors (MOSFETs) (PMOSs). The control signal for the switches is provided from a delta-sigma DAC (e.g., similarly as in the previous diagrams). Specifically, the control signal is provided to the gates of the PMOSs.

In addition, this diagram shows a DAC on the lower left-hand portion of the diagram that provides a signal to an analog low pass filter (LPF). This particular implementation of performing multiplication is readily adapted to the artificial neuron (processing element) of the FIG. 37I (and also included in FIG. 37N) that includes a DAC that provides a signal to an LPF that subsequently undergoes current modulation as multiplication based on an output signal from a delta-sigma DAC.

The LPF is implemented using a PMOS and a capacitor that is connected between the drain and source of the PMOS of the LPF. In addition, note that gate and source of the PMOS of the LPF are connected. The drain of the PMOS of the LPF is connected to a power supply (e.g., VDD). A number of other PMOSs respectively serve as current sources whose outputs are provided to the respective pairs of PMOSs that operate as switches to facilitate the generation of the current modulation signal corresponding to an M-bit output signal in differential format.

In addition, note that this limitation could be modified to operate to provide a single-ended configuration. Consider that the source of one of the PMOSs within each of the respective pairs of PMOSs that serve as the switches is grounded, and the source of the other of the PMOSs within each of the respective pairs of PMOSs that serve as the switches is configured to provide a current modulation signal corresponding to an M-bit output signal in single-ended format.

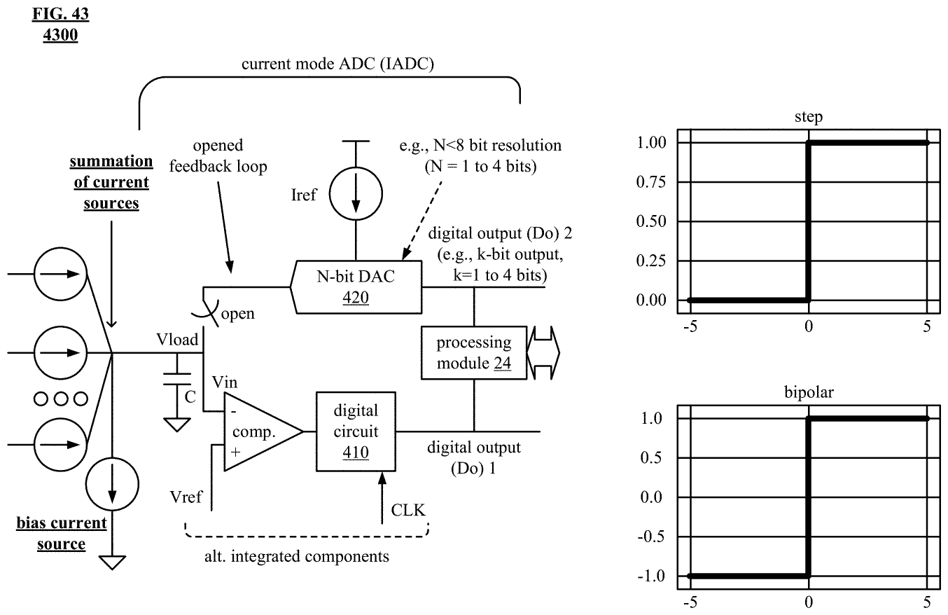

FIG. 41 is a schematic block diagram showing an embodiment 4100 of analog current summation circuitry and analog to digital converter (ADC) circuitry operative within Artificial Neural Network (ANN) processing in accordance with the present disclosure. On the left-hand side of the diagram shows current signals provided from multiple artificial neuron (processing element). These current sources are all connected to a common node to facilitate the summation of the current sources. As in other diagrams, a bias current source may optionally be implemented to provide an additional DC offset of the summation of the current sources. The summation of these current sources is provided to a current mode ADC (IADC).

The right-hand side of the diagram shows the IADC in greater detail. This implementation of an IADC is similar to that which is shown in many other diagrams herein. For example, the IADC includes a capacitor that is connected to one of the input terminals of a comparator and is configured to generate an input voltage signal, Vin, based on the charging of that capacitor by the summation of current sources. The other input terminal of the comparator receives a reference voltage signal, Vref. The comparator provides an output signal to a digital circuit 410 that is clocked by a clock signal, CLK. In alternative implementations, the comparator in the digital circuit may be implemented in a variety of ways including those described with reference to FIG. 5A. The output from the digital circuit 410, or an alternative implementations such as one of those described with reference to FIG. 5A, is configured to generate a first digital output signal, Do 1. One or more processing modules 24 is configured to process the first digital output signal, Do 1, to generate a second digital output signal, Do 2. In some examples, the second digital output signal, Do 2, includes an k-bit digital output signal such that k=1 to 4 bits. In addition, an N-bit DAC 420 is configured to provide an analog signal based on the second digital output signal, Do 2, that is injected into the node to which the capacitor and one of the inputs of the comparator are connected (i.e., the common node to which the current sources are connected and at which the summation of the current sources is performed).

Note that alternative implementations of an IADC (e.g., as described herein, or as described within various patent applications or patents that are claimed priority to and/or incorporated by reference herein) may be implemented instead of the particular implementation.

With respect to implementing the summation operation such as may be implemented within an artificial neuron (processing element) to facilitate Artificial Neural Network (ANN) processing, the summation of the current sources is effectuated by connecting the output of the currents from the respective artificial neurons (processing elements) to a common node. Note that either the respective digital output signals Do 1 or Do 2 may be selected as desired in particular implementations. Generally speaking, note that such an architecture is configured to perform analog current summation and analog to digital converter (ADC) processing in any of variety of applications. With respect to implementing a particular portion of an artificial neuron (processing element) such as may be used to facilitate ANN processing, note that such an architecture that is configured to perform analog current summation and ADC processing provides significant improvement over prior art approaches. By operating using analog current signals, summation is effectuated by connecting the current sources to a common node. The digital sampling of the summation of the analog current signals using an IADC as described herein that operates based on lower power, higher efficiency, and is operative to provide a high-resolution over prior art approaches.

Certain of the following diagrams show various embodiments by which an activation function may be embedded within the operation of a current mode analog to digital converter (ADC) (IADC) and its associated circuitry. For example, by modifying the configuration of such an IADC and its associated circuitry, the processing of various activation functions may be inherent to the operation of such an IADC and its associated circuitry. In addition, one of the diagram shows a configurable IADC that, depending on its configuration at a particular time, can operate based on different respective activation functions at different times. As such, within such implementations of an IADC and its associated circuitry appropriately, the need for a separately implemented activation functional blocker circuitry is obviated. For example, with minimal modification, minimal additional hardware, an IADC and its associated circuitry can be modified to perform a number of activation functions and maybe used in accordance with Artificial Neural Network (ANN) processing.

FIG. 42 is a schematic block diagram showing an embodiment 4200 of current mode analog to digital converter (ADC) (IADC) and associated circuitry that is configured to perform an identity activation function or a hard hyperbolic tangent activation function within Artificial Neural Network (ANN) processing in accordance with the present disclosure. This diagram includes a reference current signal, Iref, is provided from a current source as a full-scale current signal for comparison with the sum of all of the currents at the common node at which the summation of current sources is performed.

In certain examples, note that the current source may be implemented as a fixed/constant-valued current source. In other examples, note that the current source may be implemented as a variable/configurable current source providing flexibility to adjust the value of the reference current signal, Iref, based on any one or more considerations (e.g., switching between an identity activation function or a hard hyperbolic tangent activation function, based on environmental conditions, based on historical operation, adaptation of the particular Artificial Neural Network (ANN) processing being performed, etc.). This flexibility in design may also be made with respect to other examples, embodiments, diagrams, etc. that includes such current source configured to provide the reference current signal, Iref.

For example, the IADC inherently provides for the function of an identity activation function by default, such that the mapping of the analog input signal that is provided at the common node that serves as the input to the IADC is made to a digital output signal of the IADC (e.g., Do 1 or Do 2).

Again, the current source that provides the reference current signal, Iref, is set as a full-scale current. To effectuate the operation of a hard hyperbolic tangent activation function, based on the sum of all the currents that are summed together at the common node being larger than the full-scale current, Iref, then the IADC output saturates at a maximum digital value. In such an instance, the IADC operates based on a hard hyperbolic tangent activation function. Note that the slope of the middle portion of the hard hyperbolic tangent activation function may be modified based on the setting of the reference current signal, Iref, that is provided from the current source. For example, increasing the reference current signal, Iref, will lessen the slope of the middle portion of the hard hyperbolic tangent activation function. Conversely, decreasing the reference current signal, Iref, will increase the slope of the middle portion of the hard hyperbolic tangent activation function. For example, the point at which the IADC saturates can be adjusted based on the adjustment of the reference current signal, Iref, thereby facilitating configurability of the hard hyperbolic tangent activation function that is effectuated within the IADC.

As long as the sum of all of the currents that undergo summation at the common node of the IADC at which summation of current sources is performed remains smaller than the reference current signal, Iref, the IADC will effectuate an identity activation function.

In certain examples, the one or more processing modules 24 or another one or more processing modules is configured to monitor and track the sum of all of the input currents at the common node of the IADC and adaptively to adjust to the reference current signal, Iref, so as to effectuate either the function of an identity activation function or the function of a hard hyperbolic tangent activation function.

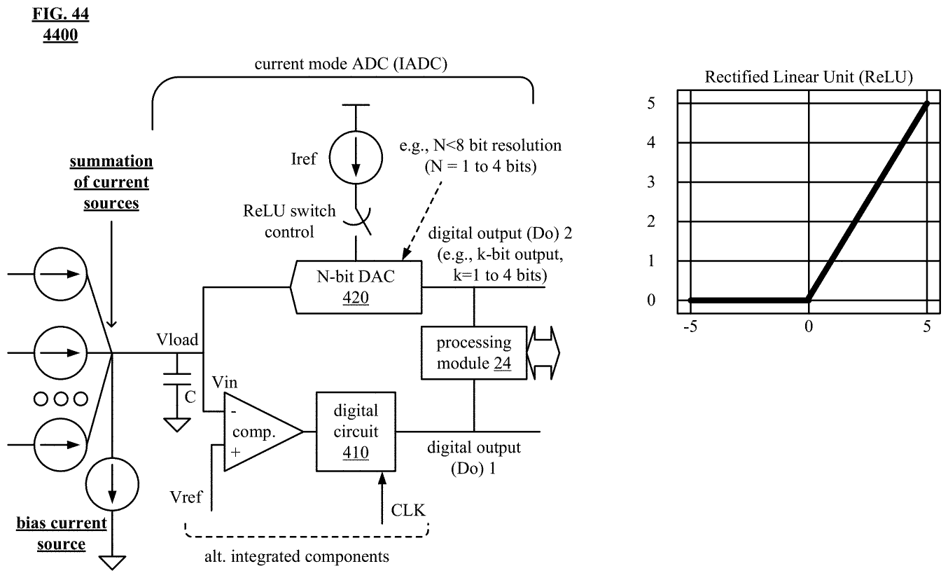

FIG. 43 is a schematic block diagram showing an embodiment 4300 of current mode analog to digital converter (ADC) (IADC) and associated circuitry that is configured to perform an step activation function or a bipolar activation function within Artificial Neural Network (ANN) processing in accordance with the present disclosure.

This diagram includes a switch within the feedback loop from the N-bit DAC 420 to the common node to which the capacitor is connected and at which the summation of current sources is performed. The operation of this switch may be controlled by the one or more processing modules 24 or one or more other processing modules. The switch is configured to be opened to facilitate the step or bipolar activation function within the IADC. In addition, note that a reference current signal, Iref, can provided from a current source as a full-scale current signal for comparison with the sum of all of the currents at the common node at which the summation of current sources is performed. For example, this reference current signal, Iref, is functional when the switch within the feedback loop from the N-bit DAC 420 to the common node is closed, such as when effectuating operation of an identity activation function or a hard hyperbolic tangent activation function.

If the feedback loop from the N-bit DAC 420 to the common node is open, based on control of the switch to and open position, then the comparator and the digital circuit 410 will operate as a step or bipolar activation function. Alternatively, the comparator and the digital circuit 410 may be implemented in a different manner such as in accordance with any of the various options of FIG. 5A, and those components will similarly operate as a step or bipolar activation function.

The offset of the function, whether it is a step activation function or a bipolar activation function, is based on the value to which the bias current source is set. In an example of operation and implementation, if the bias current source is set to zero (0), then the function will be effectuated as a bipolar activation function. Specifically, a positive current signal at the common node of the IADC that charges the capacitor connected to one of the inputs of the comparator will generate a voltage at that terminal, Vin, that is larger than the reference voltage signal, Vref, and a digital output signal of a value of one (1) will be provided from the digital circuit 410 (or from another implementation that performs the functionality of the comparator and the digital circuit 410, such as based on FIG. 5A).

In another example of operation and implementation, a negative current signal at the common node of the IADC that charges the capacitor connected to one of the inputs of the comparator will generate a voltage of zero (0) volts at that terminal of the comparator, Vin, based on the capacitor being discharged due to the negative current signal, and this voltage at that terminal of the comparator, Vin, will be less than the reference voltage signal, Vref, and a digital output signal of a value of zero (0) will be provided from the digital circuit 410 (or from another implementation that performs the functionality of the comparator and the digital circuit 410, such as based on FIG. 5A).

Note that if the bias current source is set to any particular positive or negative value, then a step activation function is effectuated by the IADC, and the particular current level at which the bias current source is set will govern the particular characteristics of the step activation function.

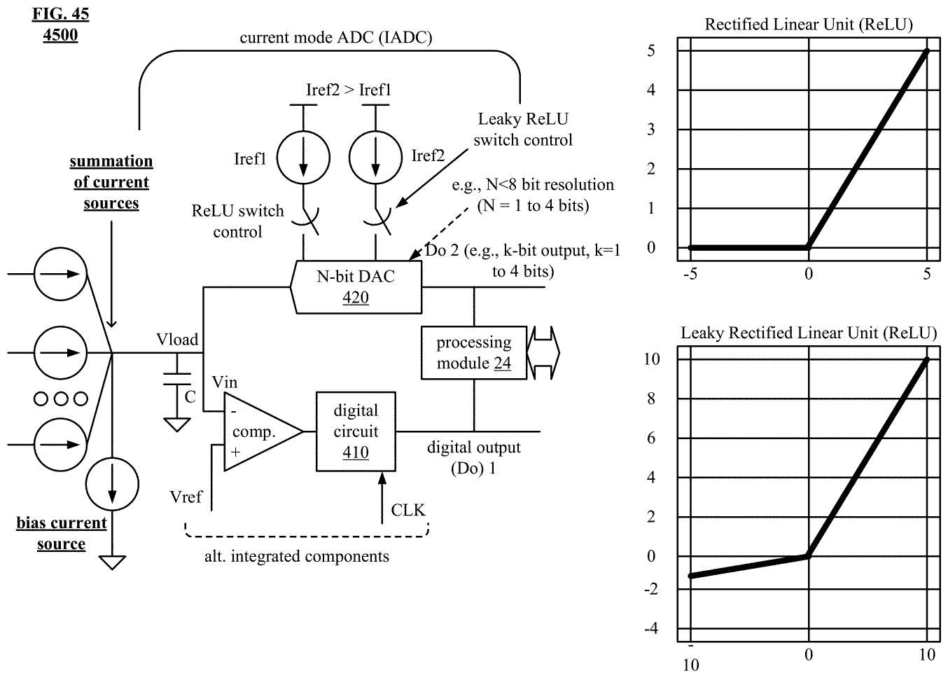

FIG. 44 is a schematic block diagram showing an embodiment 4400 of current mode analog to digital converter (ADC) (IADC) and associated circuitry that is configured to perform a Rectified Linear Unit (ReLU) activation function within Artificial Neural Network (ANN) processing in accordance with the present disclosure.

A reference current signal, Iref, is provided from a current source as a full-scale current signal for comparison with the sum of all of the currents at the common node at which the summation of current sources is performed. This diagram also includes a switch between the output of this current source and the N-bit DAC 420 (i.e., the N-bit DAC 420 that provides an output signal to the common node to which the capacitor is connected and at which the summation of current sources is performed). The operation of this switch may be controlled by the one or more processing modules 24 or one or more other processing modules. The switch is configured to be opened to facilitate the ReLU activation function within the IADC. For example, when the switch is closed, the ReLU activation function is effectuated within the IADC. Alternatively, in an IADC in which the ReLU activation function is always desired to be performed, the switch is not needed such that the reference current signal, Iref, is always provided to be used by the N-bit DAC 420.

The ReLU activation function is a function that is used widely in variety of applications including Artificial Intelligence (AI), image processing, etc. The ReLU activation function makes the training of an Artificial Neural Network (ANN) much easier thereby simplifying the complexity of the ANN and also by reducing the required computational resources needed within such an ANN.

In an example of operation and implementation, if the summation of all of the current sources at the common node of the IADC is negative, then the capacitor connected to the common node of the IADC and also to the input of the comparator and the output of the N-bit DAC 420 will discharge thereby generating a voltage of zero (0) volts for Vin at the input of the comparator, and that voltage, Vin, will be less than the reference voltage signal, Vref, and a digital output signal of a value of zero (0) will be provided from the digital circuit 410 (or from another implementation that performs the functionality of the comparator and the digital circuit 410, such as based on FIG. 5A). In certain examples, this operation is achieved in the IADC by setting the bias current source to a value so that the IADC saturates based on zero input current. This is similar to the hard hyperbolic tangent activation function with setting the analog input bias current to shift the IADC lower bound to correspond to that of a zero (0) input current.

Generally speaking, when the summation of the current sources at the common node of the IADC is zero (0) or positive, then the bias current source offset is set in such a way that when the input current is a positive current, the operation of the IADC follows a linear function (e.g., the right-hand portion of the ReLU activation function). However, when the summation of the current sources at the common node of the IADC is negative, then the operation of the IADC follows an output of zero (0) or be clamped at the bottom to zero (0) (e.g., the left-hand portion of the ReLU activation function), as the IADC is configured so as not to have a negative input current provided to it based on the discharging of the capacitor that is connected to the common node of the IADC and also to the input of the comparator and the output of the N-bit DAC 420.

In an example of operation and implementation, consider and input range of the IADC to vary between −10 μA and +10 μA. By setting the bias current source to be +10 μA, then the IADC will detect at the common node of the IADC a signal varying between zero (0) and +20 μA. Then, the reference current signal, Iref, maybe set +20 μA, or an even higher value, so that the summation of the current sources at the common node of the IADC is always positive, and within the range from zero (0) and +20 μA. When the summation of the current sources at the common node of the IADC is zero (0) (e.g., based on the bias current source to be +10 μA), then the IADC will follow an output of zero (0) or be clamped at the bottom to zero (0) (e.g., the left-hand portion of the ReLU activation function).

FIG. 45 is a schematic block diagram showing an embodiment 4500 of current mode analog to digital converter (ADC) (IADC) and associated circuitry that is configured to perform a Leaky Rectified Linear Unit (ReLU) activation function within Artificial Neural Network (ANN) processing in accordance with the present disclosure.

Two reference current signals, Iref1 and Iref2, are provided from two respective current sources as two full-scale current signals for comparison with the sum of all of the currents at the common node at which the summation of current sources is performed. This diagram also includes two respective switched between the outputs of these two current source and the N-bit DAC 420 that provides an output signal to the common node to which the capacitor is connected and at which the summation of current sources is performed. The operation of these switches may be controlled by the one or more processing modules 24 or one or more other processing modules. The switches are configured to be opened to facilitate the Leaky ReLU activation function within the IADC. For example, based on Nice selective operation of the switches servicing the two respective current sources, the Leaky ReLU activation function is effectuated within the IADC.

In an example of operation and implementation, the two reference current signals, Iref1 and Iref2, that are provided from the two respective current sources are such that the second reference current signal from the second current source is larger than the first reference current signal from the first current source (i.e., Iref2>Iref1). When the summation of the current sources at the common node of the IADC is positive, the first reference current signal, Iref1, is used, and the corresponding switch between the current source providing the first reference current signal, Iref1, is closed and the other switch is opened. Alternatively, when the summation of the current sources at the common node of the IADC is negative, the second reference current signal, Iref2, is used, and the corresponding switch between the current source providing the second reference current signal, Iref2, is closed and the other switch is opened. Since the second reference current signal, Iref2, is much larger than the first reference current signal, Iref1, the slope of that portion of the Leaky ReLU activation function is shallower (e.g., the left-hand portion of the ReLU activation function).

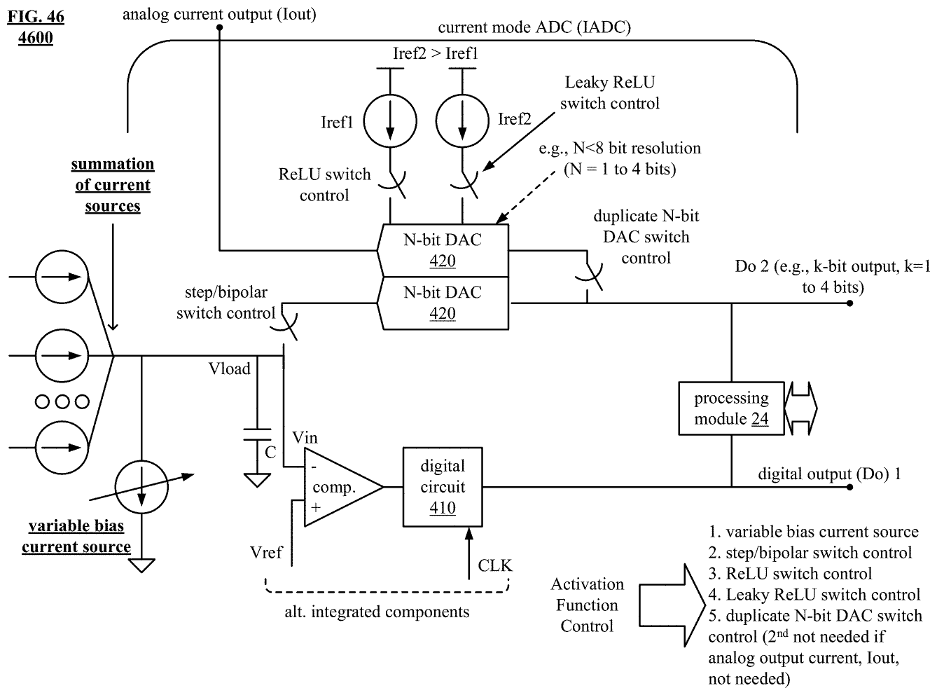

FIG. 46 is a schematic block diagram showing an embodiment 4600 of configurable current mode analog to digital converter (ADC) (IADC) and associated circuitry that is configured to perform a variety of activation functions within Artificial Neural Network (ANN) processing in accordance with the present disclosure.

This diagram, from certain perspectives, includes various features of some of the other implementations thereby facilitating configurability to perform different respective activation functions. There are various switches that are controlled by the one or more processing modules 24 or another one or more processing modules. Such activation function control is provided to select which particular activation function is to be effectuated by the IADC. Examples of activation function control include control of a variable bias current source (e.g., such as provided to an N-bit DAC), a variable bias current source (e.g., such as provided to a summation block/node that receives current sources and sums them), a step/bipolar switch control, a ReLU switch control, a Leaky ReLU switch control, and control of a switch that selectively provides input to a duplicate N-bit DAC that is configured to generate an analog output current, Tout, as may be used in certain implementations of an Artificial Neural Network (ANN) that operate based on receiving analog input signals at respective artificial neurons (processing elements) (e.g., FIG. 37I and FIG. 37N).

In an example of operation and implementation, the respective switches included within this particular configurable IADC may be selectively opened or closed, as may be appropriate, to facilitate the appropriate configurability to effectuate a number of different respective activation functions. For example, based on the input activation function control to effectuate one particular activation function, the appropriate configuration of the configurable IADC is made to achieve that particular activation function.

Appropriate operation in accordance with various activation functions such as identity, step, bipolar, hyperbolic tangent, hard hyperbolic tangent, ReLU, Leaky ReLU may be achieved by appropriately controlling the switches regarding the feedback loop from the N-bit DAC 420 two the common node to which the capacitor is connected and at which the summation of the current sources is made, the appropriate selection of the first reference current signal, Iref1, the second reference current signal, Iref2, the particular DC offset of the variable bias current source, as well as the switch provided to the input of the duplicate N-bit DAC that is configured to provide analog output current, Tout, as may be used in certain implementations of an Artificial Neural Network (ANN) that operate based on receiving analog input signals at respective artificial neurons (processing elements) (e.g., FIG. 37I and FIG. 37N). Note that either of the digital output signals, Do 1 or Do 2, may be used in certain implementations of an Artificial Neural Network (ANN) that operate based on receiving digital input signals at respective artificial neurons (processing elements) (e.g., FIG. 38A and FIG. 38B).

It is noted that terminologies as may be used herein such as bit stream, stream, signal sequence, etc. (or their equivalents) have been used interchangeably to describe digital information whose content corresponds to any of a number of desired types (e.g., data, video, speech, text, graphics, audio, etc. any of which may generally be referred to as ‘data’).

As may be used herein, the terms “substantially” and “approximately” provide an industry-accepted tolerance for its corresponding term and/or relativity between items. For some industries, an industry-accepted tolerance is less than one percent and, for other industries, the industry-accepted tolerance is 10 percent or more. Other examples of industry-accepted tolerance range from less than one percent to fifty percent. Industry-accepted tolerances correspond to, but are not limited to, component values, integrated circuit process variations, temperature variations, rise and fall times, thermal noise, dimensions, signaling errors, dropped packets, temperatures, pressures, material compositions, and/or performance metrics. Within an industry, tolerance variances of accepted tolerances may be more or less than a percentage level (e.g., dimension tolerance of less than +/−1%). Some relativity between items may range from a difference of less than a percentage level to a few percent. Other relativity between items may range from a difference of a few percent to magnitude of differences.

As may also be used herein, the term(s) “configured to”, “operably coupled to”, “coupled to”, and/or “coupling” includes direct coupling between items and/or indirect coupling between items via an intervening item (e.g., an item includes, but is not limited to, a component, an element, a circuit, and/or a module) where, for an example of indirect coupling, the intervening item does not modify the information of a signal but may adjust its current level, voltage level, and/or power level. As may further be used herein, inferred coupling (i.e., where one element is coupled to another element by inference) includes direct and indirect coupling between two items in the same manner as “coupled to”.

As may even further be used herein, the term “configured to”, “operable to”, “coupled to”, or “operably coupled to” indicates that an item includes one or more of power connections, input(s), output(s), etc., to perform, when activated, one or more its corresponding functions and may further include inferred coupling to one or more other items. As may still further be used herein, the term “associated with”, includes direct and/or indirect coupling of separate items and/or one item being embedded within another item.

As may be used herein, the term “compares favorably”, indicates that a comparison between two or more items, signals, etc., provides a desired relationship. For example, when the desired relationship is that signal 1 has a greater magnitude than signal 2, a favorable comparison may be achieved when the magnitude of signal 1 is greater than that of signal 2 or when the magnitude of signal 2 is less than that of signal 1. As may be used herein, the term “compares unfavorably”, indicates that a comparison between two or more items, signals, etc., fails to provide the desired relationship.

As may be used herein, one or more claims may include, in a specific form of this generic form, the phrase “at least one of a, b, and c” or of this generic form “at least one of a, b, or c”, with more or less elements than “a”, “b”, and “c”. In either phrasing, the phrases are to be interpreted identically. In particular, “at least one of a, b, and c” is equivalent to “at least one of a, b, or c” and shall mean a, b, and/or c. As an example, it means: “a” only, “b” only, “c” only, “a” and “b”, “a” and “c”, “b” and “c”, and/or “a”, “b”, and “c”.

As may also be used herein, the terms “processing module”, “processing circuit”, “processor”, “processing circuitry”, and/or “processing unit” may be a single processing device or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on hard coding of the circuitry and/or operational instructions. The processing module, module, processing circuit, processing circuitry, and/or processing unit may be, or further include, memory and/or an integrated memory element, which may be a single memory device, a plurality of memory devices, and/or embedded circuitry of another processing module, module, processing circuit, processing circuitry, and/or processing unit. Such a memory device may be a read-only memory, random access memory, volatile memory, non-volatile memory, static memory, dynamic memory, flash memory, cache memory, and/or any device that stores digital information. Note that if the processing module, module, processing circuit, processing circuitry, and/or processing unit includes more than one processing device, the processing devices may be centrally located (e.g., directly coupled together via a wired and/or wireless bus structure) or may be distributedly located (e.g., cloud computing via indirect coupling via a local area network and/or a wide area network). Further note that if the processing module, module, processing circuit, processing circuitry and/or processing unit implements one or more of its functions via a state machine, analog circuitry, digital circuitry, and/or logic circuitry, the memory and/or memory element storing the corresponding operational instructions may be embedded within, or external to, the circuitry comprising the state machine, analog circuitry, digital circuitry, and/or logic circuitry. Still further note that, the memory element may store, and the processing module, module, processing circuit, processing circuitry and/or processing unit executes, hard coded and/or operational instructions corresponding to at least some of the steps and/or functions illustrated in one or more of the Figures. Such a memory device or memory element can be included in an article of manufacture.

One or more embodiments have been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claims. Further, the boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality.

To the extent used, the flow diagram block boundaries and sequence could have been defined otherwise and still perform the certain significant functionality. Such alternate definitions of both functional building blocks and flow diagram blocks and sequences are thus within the scope and spirit of the claims. One of average skill in the art will also recognize that the functional building blocks, and other illustrative blocks, modules and components herein, can be implemented as illustrated or by discrete components, application specific integrated circuits, processors executing appropriate software and the like or any combination thereof.

In addition, a flow diagram may include a “start” and/or “continue” indication. The “start” and “continue” indications reflect that the steps presented can optionally be incorporated in or otherwise used in conjunction with one or more other routines. In addition, a flow diagram may include an “end” and/or “continue” indication. The “end” and/or “continue” indications reflect that the steps presented can end as described and shown or optionally be incorporated in or otherwise used in conjunction with one or more other routines. In this context, “start” indicates the beginning of the first step presented and may be preceded by other activities not specifically shown. Further, the “continue” indication reflects that the steps presented may be performed multiple times and/or may be succeeded by other activities not specifically shown. Further, while a flow diagram indicates a particular ordering of steps, other orderings are likewise possible provided that the principles of causality are maintained.

The one or more embodiments are used herein to illustrate one or more aspects, one or more features, one or more concepts, and/or one or more examples. A physical embodiment of an apparatus, an article of manufacture, a machine, and/or of a process may include one or more of the aspects, features, concepts, examples, etc. described with reference to one or more of the embodiments discussed herein. Further, from figure to figure, the embodiments may incorporate the same or similarly named functions, steps, modules, etc. that may use the same or different reference numbers and, as such, the functions, steps, modules, etc. may be the same or similar functions, steps, modules, etc. or different ones.

Unless specifically stated to the contra, signals to, from, and/or between elements in a figure of any of the figures presented herein may be analog or digital, continuous time or discrete time, and single-ended or differential. For instance, if a signal path is shown as a single-ended path, it also represents a differential signal path. Similarly, if a signal path is shown as a differential path, it also represents a single-ended signal path. While one or more particular architectures are described herein, other architectures can likewise be implemented that use one or more data buses not expressly shown, direct connectivity between elements, and/or indirect coupling between other elements as recognized by one of average skill in the art.

The term “module” is used in the description of one or more of the embodiments. A module implements one or more functions via a device such as a processor or other processing device or other hardware that may include or operate in association with a memory that stores operational instructions. A module may operate independently and/or in conjunction with software and/or firmware. As also used herein, a module may contain one or more sub-modules, each of which may be one or more modules.

As may further be used herein, a computer readable memory includes one or more memory elements. A memory element may be a separate memory device, multiple memory devices, or a set of memory locations within a memory device. Such a memory device may be a read-only memory, random access memory, volatile memory, non-volatile memory, static memory, dynamic memory, flash memory, cache memory, and/or any device that stores digital information. The memory device may be in a form a solid-state memory, a hard drive memory, cloud memory, thumb drive, server memory, computing device memory, and/or other physical medium for storing digital information.

While particular combinations of various functions and features of the one or more embodiments have been expressly described herein, other combinations of these features and functions are likewise possible. The present disclosure is not limited by the particular examples disclosed herein and expressly incorporates these other combinations.

What is claimed is:

1. An Artificial Neural Network (ANN) processing system, the system comprising:
a plurality of artificial neurons (processing elements) configured to generate a plurality of output analog current signals, wherein an artificial neuron (processing element) of the plurality of artificial neurons (processing elements) includes:
a digital to analog converter (DAC) configured to generate a first analog current signal based on a first digital input signal;
a low pass filter (LPF) operably coupled to the DAC and configured to process the first analog current signal to generate a first filtered analog current signal;
a delta-sigma DAC configured to generate an M-bit current signal based on a digital weight value, wherein the M-bit current signal toggles between a value of 1 and a value of 0 based on the digital weight value such that an average value of the M-bit current signal over a predetermined period of time corresponds to the digital weight value, wherein M is a positive integer greater than or equal to 1; and
a multiplier configured to generate a first output current source signal based on the first filtered analog current signal and the M-bit current signal and to provide the first output current source signal to a common node that is operably coupled to at least one other of the plurality of artificial neurons (processing elements) and that receives the plurality of output analog current signals; and
an analog to digital converter (ADC) operably coupled to the common node via a single line and configured to generate a digital output signal based on an input voltage of the ADC, wherein the digital output signal is representative of a summation of the plurality of output analog current signals at the common node, and wherein the input voltage of the ADC is based on charging of a capacitor of the ADC by the plurality of output analog current signals and a digital to analog converter (DAC) output current from the ADC.

2. The system of claim 1 further comprising:
another DAC operably coupled to the ADC and configured to generate an analog output signal based on the digital output signal.

3. The system of claim 2, wherein the analog output signal includes an intermediate signal that is provided to one or more other artificial neurons (processing elements) within the ANN processing system.

4. The system of claim 1 further comprising:
a bias current source operably coupled to the common node and configured to provide a bias current to the plurality of output analog current signals, wherein the digital output signal is representative of a summation of the plurality of output analog current signals and the bias current at the common node.

5. The system of claim 1, wherein the ADC includes a built-in activation function and is further configured to generate the digital output signal based on the plurality of output analog current signals based on the built-in activation function.

6. The system of claim 5, wherein the built-in activation function corresponds to an identify activation function, a step activation function, a bipolar activation function, a hard hyperbolic tangent activation function, a Rectified Linear Unit (ReLU) activation function, or a Leaky Rectified Linear Unit (ReLU) activation function.

7. The system of claim 1, wherein another artificial neuron (processing element) of the plurality of artificial neurons (processing elements) comprising:
another DAC configured to generate a second analog current signal based on a second digital input signal;
another LPF operably coupled to the another DAC and configured to process the second analog current signal to generate a second filtered analog current signal;
another delta-sigma DAC configured to generate another M-bit current signal based on another digital weight value, wherein the another M-bit current signal toggles between a value of 1 and a value of 0 based on the digital weight value such that an average value of the another M-bit current signal over a predetermined period of time corresponds to the another digital weight value, wherein M is a positive integer greater than or equal to 1; and
another multiplier configured to generate a second output current source signal based on the second filtered analog current signal and the another M-bit current and to provide the second output current source signal to the common node that receives the plurality of output analog current signals.

8. The system of claim 1, wherein the ADC further comprising:
the capacitor operably coupled to the common node and configured to produce the input voltage based on charging by the plurality of output analog current signals and the DAC output current;
a comparator operably coupled and configured to:
receive the input voltage via a first input of the comparator;
receive a reference voltage via a second input of the comparator; and
compare the input voltage to the reference voltage to generate a comparator output signal;
a digital circuit operably coupled and configured to process the comparator output signal to generate a first digital output signal that is representative of a difference between the input voltage and the reference voltage;
memory that stores operational instructions;
one or more processing modules operably coupled to the digital circuit and the memory and configured to execute the operational instructions to process the first digital output signal to generate a second digital output signal that is representative of the difference between the input voltage and the reference voltage, wherein the second digital output signal includes a higher resolution than the first digital output signal; and
an N-bit digital to analog converter (DAC) that is operably coupled to the one or more processing modules and configured to generate the DAC output current based on the second digital output signal, wherein N is a positive integer, the DAC output current tracks the plurality of output analog current signals, and the input voltage tracks the reference voltage.

9. The system of claim 8, wherein:
the comparator includes a sigma-delta comparator; and
the digital circuit includes a clocked flip flop.

10. The system of claim 8, wherein a digital comparator includes both the comparator and the digital circuit, wherein the digital comparator operably coupled and configured to:
receive the input voltage via a first input of the comparator;
receive the reference voltage via a second input of the comparator; and
compare the input voltage to the reference voltage to generate the first digital output signal that is representative of the difference between the input voltage and the reference voltage.

11. The system of claim 8 further comprising:
a decimation filter coupled to the one or more processing modules and configured to process the second digital output signal to generate another digital output signal having a lower sampling rate and a higher resolution than the second digital output signal.

12. The system of claim 1, wherein the ADC further comprising:
the capacitor operably coupled to the common node and configured to produce the input voltage based on charging by the plurality of output analog current signals and the DAC output current;
an M-bit analog to digital converter (ADC) operably coupled and configured to:
receive the input voltage;
receive a reference voltage; and
compare the input voltage to the reference voltage and generate a first digital output signal that is representative of a difference between the input voltage and the reference voltage;
memory that stores operational instructions;
one or more processing modules operably coupled to the M-bit ADC and the memory and configured to execute the operational instructions to process the first digital output signal to generate a second digital output signal that is representative of the difference between the input voltage and the reference voltage, wherein the second digital output signal includes a higher resolution than the first digital output signal; and
an N-bit digital to analog converter (DAC) that is operably coupled to the one or more processing modules and configured to generate the DAC output current based on the second digital output signal, the DAC output current tracks the plurality of output analog current signals, and the input voltage tracks the reference voltage, wherein:
N is a first positive integer;
M is a second positive integer greater than or equal to 1; and
N is greater than M.

13. The system of claim 12 further comprising:
a decimation filter coupled to the one or more processing modules and configured to process the second digital output signal to generate another digital output signal having a lower sampling rate and a higher resolution than the second digital output signal.

14. An Artificial Neural Network (ANN) processing system, the system comprising:
a plurality of artificial neurons (processing elements) configured to generate a plurality of output analog current signals, wherein an artificial neuron (processing element) of the plurality of artificial neurons (processing elements) includes:
a digital to analog converter (DAC) configured to generate a first analog current signal based on a first digital input signal;
a low pass filter (LPF) operably coupled to the DAC and configured to process the first analog current signal to generate a first filtered analog current signal;
a delta-sigma DAC configured to generate an M-bit current signal based on a digital weight value, wherein the M-bit current signal toggles between a value of 1 and a value of 0 based on the digital weight value such that an average value of the M-bit current signal over a predetermined period of time corresponds to the digital weight value, wherein M is a positive integer greater than or equal to 1; and
a multiplier configured to generate a first output current source signal based on the first filtered analog current signal and the M-bit current signal and to provide the first output current source signal to a common node that is operably coupled to at least one other of the plurality of artificial neurons (processing elements) and that receives the plurality of output analog current signals; and
a bias current source operably coupled to the common node and configured to provide a bias current to the plurality of output analog current signals;
an analog to digital converter (ADC) operably coupled to the common node via a single line and configured to generate a digital output signal based on an input voltage of the ADC, wherein the digital output signal is representative of a summation of the plurality of output analog current signals and the bias current at the common node, and wherein the input voltage of the ADC is based on charging of a capacitor of the ADC by the plurality of output analog current signals and a digital to analog converter (DAC) output current from the ADC, and wherein the ADC includes a built-in activation function and is further configured to generate the digital output signal based on the plurality of output analog current signals based on the built-in activation function; and
another DAC operably coupled to the ADC and configured to generate an analog output signal based on the digital output signal.

15. The system of claim 14, wherein the analog output signal includes an intermediate signal that is provided to one or more other artificial neurons (processing elements) within the ANN processing system.

16. The system of claim 14, wherein the built-in activation function corresponds to an identify activation function, a step activation function, a bipolar activation function, a hard hyperbolic tangent activation function, a Rectified Linear Unit (ReLU) activation function, or a Leaky Rectified Linear Unit (ReLU) activation function.

17. The system of claim 14, wherein the ADC further comprising:
the capacitor operably coupled to the common node and configured to produce the input voltage based on charging by the plurality of output analog current signals and the DAC output current;
a comparator operably coupled and configured to:
receive the input voltage via a first input of the comparator;
receive a reference voltage via a second input of the comparator; and
compare the input voltage to the reference voltage to generate a comparator output signal;
a digital circuit operably coupled and configured to process the comparator output signal to generate a first digital output signal that is representative of a difference between the input voltage and the reference voltage;
memory that stores operational instructions;
one or more processing modules operably coupled to the digital circuit and the memory and configured to execute the operational instructions to process the first digital output signal to generate a second digital output signal that is representative of the difference between the input voltage and the reference voltage, wherein the second digital output signal includes a higher resolution than the first digital output signal; and
an N-bit digital to analog converter (DAC) that is operably coupled to the one or more processing modules and configured to generate the DAC output current based on the second digital output signal, wherein N is a positive integer, the DAC output current tracks the plurality of output analog current signals, and the input voltage tracks the reference voltage.

18. The system of claim 17, wherein:
the comparator includes a sigma-delta comparator; and
the digital circuit includes a clocked flip flop.

19. The system of claim 17, wherein a digital comparator includes both the comparator and the digital circuit, wherein the digital comparator operably coupled and configured to:
receive the input voltage via a first input of the comparator;
receive the reference voltage via a second input of the comparator; and
compare the input voltage to the reference voltage to generate the first digital output signal that is representative of the difference between the input voltage and the reference voltage.

20. The system of claim 17 further comprising:
a decimation filter coupled to the one or more processing modules and configured to process the second digital output signal to generate another digital output signal having a lower sampling rate and a higher resolution than the second digital output signal.
